(19) United States
(12) Patent Application Publication
(10) Pub. No.: US 2016/0268516 A1
(43) Pub. Date: Sep. 15, 2016

(54) ORGANIC ELECTROLUMINESCENT ELEMENT, ELECTRONIC DEVICE, LIGHT EMITTING DEVICE, AND LIGHT EMITTING MATERIAL

(71) Applicant: KONICA MINOLTA, INC., Tokyo (JP)

(72) Inventors: Tatsuo TANAKA, Fuchu-shi, Tokyo (JP); Hideo TAKA, Inagi-shi, Tokyo (JP); Hiroshi KITA, Hachioji-shi, Tokyo (JP)

(21) Appl. No.: 14/911,978

(22) PCT Filed: Aug. 14, 2014
(86) PCT No.: PCT/JP2014/071430

§ 371 Date: Feb. 12, 2016

(30) Foreign Application Priority Data
Aug. 16, 2013 (JP) 2013-169073

(51) Int. Cl. H01L 51/00; C09K 11/06; C09K 11/02

(52) U.S. Cl. CPC H01L 51/0072; C09K 11/025; C09K 11/06; H01L 51/0073; H01L 51/0052; H01L 51/0067; H01L 51/0061; H01L 51/0054; H01L 51/0056; H01L 51/0074; H01L 51/0094; H01L 51/0071; H01L 51/0065; H01L 51/0085; H01L 51/0058; H01L 51/5012

(57) ABSTRACT

An objective of the present invention is to provide: an organic electroluminescent element which has high efficiency and a long service life; and an electronic device and a light emitting device, each of which is provided with the organic electroluminescent element. Another objective of the present invention is to provide a light emitting material which has high efficiency and a long service life. An organic electroluminescent element according to the present invention comprises at least one organic layer that is interposed between a positive electrode and a negative electrode. This organic electroluminescent element is characterized in that: at least one organic layer contains a fluorescent compound and a host compound; the internal quantum efficiency by electrical excitation of the fluorescent compound is 50% or more; the half-value width of the emission band of an emission peak wavelength in the emission spectrum of the fluorescent compound at a room temperature is 100 nm or less; and the host compound has a structure represented by general formula (I).

### TECHNICAL FIELD

The present invention relates to an organic electroluminescent element and a light emitting material, and an electronic device and a light emitting device provided with that organic electroluminescent element. More specifically, it relates to an organic electroluminescent element achieving improved light emitting efficiency.

### BACKGROUND

Organic electroluminescent (hereinafter referred to as “EL”) elements (also referred to as “organic electroluminescence elements”), which are based on electroluminescence of organic materials, have already been put into practice as a new generation of light emitting systems capable of planar light emission. Organic EL elements have recently been applied to electronic displays and also to lighting devices. Thus, a demand has arisen for further development of organic EL elements.

As an emission mode of an organic EL, there are two types. One is “a phosphorescence emission type” which emits light when a triplet excited state returns to a ground state, and another one is “a fluorescence emission type” which emits light when a singlet excited state returns to a ground state.

When an electric filed is applied to an organic EL element, a hole and an electron are respectively injected from an anode and a cathode, they are recombined in a light emitting layer to produce an exciton. At this moment, a singlet exciton and a triplet exciton are formed with a ratio of 25%:75%. Therefore, it is known that a phosphorescence emission type using a triplet exciton will produce theoretically high internal quantum efficiency compared with a fluorescence emission type (for example, refer to Non-patent Document 1).

However, in order to obtain high quantum efficiency in a phosphorescence emission type, it is required to use a complex compound having a rare metal of iridium or platinum in the center metal. This may induce an industrial problem of the amount of deposit or the cost of the rare metals in the future.

On the other hand, in recent years, new techniques relevant to a fluorescence emission type have been proposed to improve emission efficiency.

For example, Patent Document 1 discloses a technique which is focused on a phenomenon wherein singlet excitons are generated by collision of two triplet excitons (it is called as Triplet-Triplet Annihilation (TTA), or Triplet-Triplet Fusion (TTF)), and which improves the emission efficiency of a fluorescent element by allowing the TTA phenomenon to occur effectively. Although this technique can increase power efficiency of a fluorescence emission material (hereafter, it is called as a fluorescent emission material or fluorescent material) from two to three times larger than the power efficiency of a conventional fluorescent material, the emission efficiency in TTA is not as high as that of the aforementioned phosphorescent material due to a theoretical limitation, because the rate of conversion of the excited triplet energy level to the excited singlet energy level will remain to about 40%.

Recent studies by Adachi at al. have disclosed a fluorescent material that employs a thermally activated delayed fluorescent mechanism (hereinafter also referred to as “TADF”). It is reported that it can be applied to an organic EL element (for example, refer to Non-patent Documents 2 to 7 and Patent Document 2).

As illustrated in FIG. 1, the TADF mechanism is a light emitting mechanism making use of a compound having a difference between singlet excited energy level and triplet excited energy level (ΔEst) smaller than that in a common fluorescent material (i.e., ΔEst (TADF) is smaller than ΔEst (F) in FIG. 1), and this small energy difference allows to occur a reverse intersystem crossing from the triplet exciton to the singlet exciton. Namely, by the fact of having a small ΔEst, triplet excitons generated at a probability of 75% upon electrical excitation, which would otherwise fail to contribute to light emission, are transferred to the singlet excited state by heat energy during operation of the organic EL element. Fluorescence occurs by radiation deactivation (also referred to as “radiation transition” or “radiative deactivation”) during transfer from the singlet excited state to the ground state. By making use of this delayed fluorescence caused by the TADF mechanism, it is believed that, theoretically, it is possible to achieve an internal quantum efficiency of 100% in fluorescence emission.

However, when a fluorescent compound which emits fluorescence by making use of the TADA mechanism has a large emission region in the UV region, it may produce energy transfer from the fluorescent compound to the host compound, and this energy transfer will not contribute to an emission of the organic EL element. This will cause a problem of decreasing emission efficiency.

### PRIOR ART DOCUMENT

### Patent Document

Patent Document 1: WO 2012/133188

Patent Document 2: WO 2013/081088

### Non-Patent Document

Non-patent Document 1: “Syoumei ni Muketa Rinkou Yuki EL Gizyutu no Kaihatsu (Development of phosphorescent organic EL technology for lighting)”, Oyo Butsuri (Applied Physics), Vol. 80, Nov. 4, 2011

Non-patent Document 2: H. Uoyama, et al., Nature, 2012, 492, 234-238

Non-patent Document L 3: S. Y. Lee, et al., Applied Physics Letters, 2012, 101, 093306-093309

Non-patent Document 4: Q. Zhang, et al., J. Am. Chem. Soc., 2012, 134, 14706-14709

Non-patent Document 5: T. Nakagawa, et al., Chem. Commun., 2012, 48, 9580-9582

Non-patent Document 6: A. Endo, et al., Adv. Mater., 2009, 21, 4802-4806

Non-patent Document 7: Proceedings of Organic EL Symposium of Japan 10th Meeting, pp. 11-12, 2010

### SUMMARY OF THE INVENTION

### Problems to be Solved by the Invention

The present invention has been made in view of the above-described problems and situation. An object of the present invention is to provide an organic electroluminescent element achieving high emission efficiency with a long lifetime, and to provide an electronic device and a light emitting device provided with the organic electroluminescent element. Further, an object of the present invention is to provide a light emitting material achieving high emission efficiency with a long lifetime.

### Means to Solve the Problems

The present inventors have investigated the cause of the above-described problems in order to solve the problems. The present invention has been achieved based on the finding of effectively controlling an energy transfer from a host compound to a fluorescent compound by focusing on a half bandwidth in an emission band of an emission maximum wavelength of a fluorescent compound.

That is, the above-described problems of the present invention are solved by the following embodiments.
1. An organic electroluminescent element comprising at least one organic layer interposed between an anode and a cathode,

wherein the at least one organic layer contains a fluorescent compound and a host compound;

the fluorescent compound has an internal quantum efficiency of 50% or more by electrical excitation;

the fluorescent compound has a half bandwidth of 100 nm or less in an emission band of an emission maximum wavelength in an emission spectrum of the fluorescent compound at a room temperature; and

the host compound contains a structure represented by Formula (I).

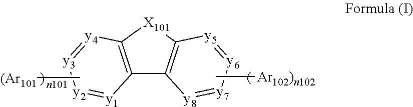

In Formula (I), X₁₀₁ represents NR₁₀₁, an oxygen atom, a sulfur atom, CR₁₀₂R₁₀₃, or SiR₁₀₂R₁₀₃; y₁ to y₈ each represent CR₁₀₄ or a nitrogen atom; R₁₀₁ to R₁₀₄ each represent a hydrogen atom or a substituent, provided that R₁₀₁ to R₁₀₄ each may be bonded together to form a ring; Ar₁₀₁ and to Ar₁₀₂ each represent an aromatic ring, provided that each may be the same or different with each other; and n101 and n102 each represent an integer of 0 to 4, provided that when R₁₀₁ represents a hydrogen atom, n101 represents an integer of 1 to 4.
2. An organic electroluminescent element described in the Item 1,

wherein the host compound containing a structure represented by Formula (I) contains a structure represented by Formula (II).

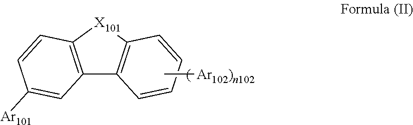

In Formula (II), X₁₀₁ represents NR₁₀₁, an oxygen atom, a sulfur atom, CR₁₀₂R₁₀₃, or SiR₁₀₂R₁₀₃; R₁₀₁ to R₁₀₃ each represent a hydrogen atom or a substituent, provided that R₁₀₁ to R₁₀₃ each may be bonded together to form a ring; Ar₁₀₁ and Ar₁₀₂ each represent an aromatic ring, provided that each may be the same or different with each other; and n101 and n102 each represent an integer of 0 to 4.
3. An organic electroluminescent element described in the Items 1 or 2,

wherein the host compound contains a carbazole structure.
4. An organic electroluminescent element described in any one of the Items 1 to 3,

the at least one organic layer is a light emitting layer.
5. An electronic device provided with an organic electroluminescent element described in any one of the Items 1 to 4.
6. A light emitting device provided with an organic electroluminescent element described in any one of the Items 1 to 4.
7. A light emitting material comprising a fluorescent compound and a host compound,

wherein the fluorescent compound has an internal quantum efficiency of 50% or more by electrical excitation;

the fluorescent compound has a half bandwidth of 100 nm or less in an emission band of an emission maximum wavelength in an emission spectrum of the fluorescent compound at a room temperature; and

the host compound contains a structure represented by Formula (I).

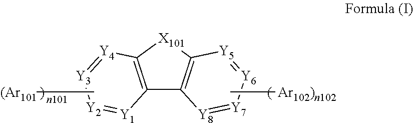

In Formula (I), X₁₀₁ represents NR₁₀₁, an oxygen atom, a sulfur atom, CR₁₀₂R₁₀₃, or SiR₁₀₂R₁₀₃; y₁ to y₈ each represent CR₁₀₄ or a nitrogen atom; R₁₀₁ to R₁₀₄ each represent a hydrogen atom or a substituent, provided that R₁₀₁ to R₁₀₄ each may be bonded together to form a ring; Ar₁₀₁ and to Ar₁₀₂ each represent an aromatic ring, provided that each may be the same or different with each other; and n101 and n102 each represent an integer of 0 to 4, provided that when R₁₀₁ represents a hydrogen atom, n101 represents an integer of 1 to 4.
8. A light emitting material described in the Item 7,

wherein the host compound containing a structure represented by Formula (I) contains a structure represented by Formula (II).

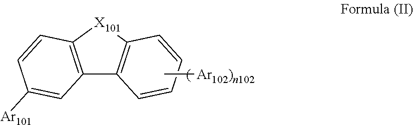

In Formula (II), X₁₀₁ represents NR₁₀₁, an oxygen atom, a sulfur atom, CR₁₀₂R₁₀₃, or SiR₁₀₂R₁₀₃; R₁₀₁ to R₁₀₃ each represent a hydrogen atom or a substituent, provided that R₁₀₁ to R₁₀₃ each may be bonded together to form a ring; Ar₁₀₁ and Ar₁₀₂ each represent an aromatic ring, provided that each may be the same or different with each other; and n101 and n102 each represent an integer of 0 to 4.

### Effects of the Invention

By the above-described embodiments of the present invention, it is possible to provide an organic electroluminescent element achieving high emission efficiency with a long lifetime, and to provide an electronic device and a light emitting device provided with the organic electroluminescent element. Further, it is possible to provide a light emitting material achieving high emission efficiency with a long lifetime.

A formation mechanism or an action mechanism of the effects of the present invention is not clearly identified, but it is supposed as follows.

For the purpose of effectively driving an organic EL element, when a fluorescent compound and a host compound are used together, the used compounds are selected on the premise that energy is transferred from the host compound to the fluorescent compound.

However, when a fluorescent compound having a large emission region in the UV region is used, it may occur energy transfer from the fluorescent compound to the host compound, this energy transfer is normally not expected and it does not contribute to an emission of the element.

As a result of this unexpected energy transfer, an emission efficiency of an element will be decreased, and further, an amount of the host compound at an excited state, namely, in the high reactive state, will be increased. Further, this high reactive host compound at an excited state will modify the physical property of the organic layer composing the light emitting layer by the reaction with the same species or by the reaction with other quencher. This will lead to an unwanted effect such as the degradation of lifetime of the element at the end.

In the present invention, it was focused on the fact that a emission component in the UV region can be reduced by using a fluorescent compound having a half bandwidth in the specific range among the fluorescent compounds. As a result, the unexpected energy transfer from the fluorescent compound to the host compound can be inhibited, and it can be obtained an organic electroluminescent element of high efficiency with a long lifetime.

### BRIEF DESCRIPTION OF THE DRAWINGS

FIG. 1 is a pattern diagram drawing illustrating an energy diagram of a fluorescent compound and a TADF compound.

FIG. 2 is a graph indicating an example of an M plot of an electron transfer layer with an impedance spectroscopy method.

FIG. 3 is a graph indicating an example of a relationship between an ETL layer thickness and a resistance in an organic EL element.

FIG. 4 is a pattern diagram illustrating an example of an equivalent circuit model of an organic electroluminescent element.

FIG. 5 is a graph indicating an example of a relationship between resistance and voltage in each layer of an organic EL element before driving with an impedance spectroscopy method.

FIG. 6 is a graph indicating an example of a relationship between resistance and voltage in each layer of an organic EL element after degradation with an impedance spectroscopy method.

FIG. 7 is a pattern diagram illustrating an example of a display device including an organic EL element.

FIG. 8 is a pattern diagram of a display device by an active matrix mode.

FIG. 9 is a schematic view illustrating a pixel circuit.

FIG. 10 is a pattern diagram of a display device by a passive matrix mode.

FIG. 11 is a schematic view of a lighting device.

FIG. 12 is a pattern diagram of a lighting device.

### EMBODIMENTS TO CARRY OUT THE INVENTION

An organic electroluminescent element of the present invention contains at least one organic layer interposed between an anode and a cathode.

This organic electroluminescent element is characterized in that:

the at least one organic layer contains a fluorescent compound and a host compound;

the fluorescent compound has an internal quantum efficiency of 50% or more by electrical excitation;

the fluorescent compound has a half bandwidth of 100 nm or less in an emission band of an emission maximum wavelength in an emission spectrum of the fluorescent compound at a room temperature; and

the host compound contains a structure represented by Formula (I).

The above-described features are technical features commonly owned by the invention relating to the embodiments 1 to 8.

As an embodiment of the present invention, a host compound having a structure represented by the aforesaid Formula (I) is preferably has a structure represented by the aforesaid Formula (II).

Further, it is preferable that the host compound contains a carbazole structure from the viewpoint of obtaining distinguished effects of the present invention.

In the present invention, it is preferable that at least one layer among the organic layers is a light emitting layer.

When the combination of the compounds used in the light emitting layer is inappropriate, that is, when a fluorescent compound having a large half bandwidth and a common host compound are used, an unrequired host compound at an excited state will be produced by energy transfer from the fluorescent compound to the host compound. That is, by the substance derived from the unrequired host compound at an excited state, it will be induced a problem that a change rate of the film condition of the light emitting layer will be large. One of the methods to solve this problem effectively is to select a light emitting compound used in the present invention to have a half bandwidth in a predetermined region. By the use of the combination of the present invention in the light emitting layer, it can be expected to obtain a light emitting layer having a small change rate of the film condition of the light emitting layer.

An organic electroluminescent element of the present invention is suitably used for an electronic device.

By this, it can be provided with an organic layer having a small change rate of physical properties of the film. It can be expected the effect of reducing the change of condition of the device between before driving and after driving. As a result, it can be obtained a device having small color unevenness, for example.

An organic electroluminescent element of the present invention is suitably used for a light emitting device.

By this, it can be provided with an organic layer having a small change rate of physical properties of the film. It can be expected the effect of reducing the change of condition of the device between before driving and after driving. As a result, it can be obtained a light emitting device having a small change rate of emission color, for example.

The light emitting material of the present invention contains a fluorescent compound and a host compound. It is characterized in that:

the fluorescent compound has an internal quantum efficiency of 50% or more by electrical excitation;

the fluorescent compound has a half bandwidth of 100 nm or less in an emission band of an emission maximum wavelength in an emission spectrum of the fluorescent compound at a room temperature; and

the host compound contains a structure represented by Formula (I).

By being provided with these features, it can be obtained a light emitting material of high efficiency with a long lifetime.

In one embodiment of the present invention, it is preferable that a host compound having a structure represented by the aforesaid Formula (I) has a structure represented by the aforesaid Formula (II) from the viewpoint of obtaining the distinguished effects of the present invention.

The present invention and the constitution elements thereof, as well as configurations and embodiments, will be detailed in the following. In the present description, when two figures are used to indicate a range of value before and after “to”, these figures are included in the range as a lowest limit value and an upper limit value.

### <Light Emission Mode of Organic EL>

As a light emission mode of an organic EL, there are two types. One is “a phosphorescence emission type” which emits light when a triplet excited state returns to a ground state, and another one is “a fluorescence emission type” which emits light when a singlet excited state returns to a ground state.

When excitation is done by an electric field such as in the case of an organic EL element, a triplet exciton is produced with a probability of 75%, and a singlet exciton is produced with a probability of 25%. Consequently, it is possible that a phosphorescent emission has higher emission efficiency than fluorescent emission. The phosphorescent emission is an excellent mode to realize low electric consumption.

On the other hand, with respect to the fluorescent emission, it was found a method of using a TTA mechanism wherein singlet excitons are generated from two triplet excitons (it is called as Triplet-Triplet Annihilation (TTA), or Triplet-Triplet Fusion (TTF)) to improve the emission efficiency. The TTA mechanism can be achieved by the triplet excitons produced with a probability of 75%, which will normally take the route of radiationless deactivation only to produce heat. By making the triplet excitons to be produced in a high density, the TTA mechanism can be effective.

In recent years, the group of Adachi found the following phenomenon. By achieving a small energy gap between the singlet excited state and the triplet excited state, it is allowed to occur a reverse intersystem crossing from the triplet state of lower energy level to the singlet state allowed to occur. This can be done by the Joule heat produced during the emission and/or the environmental temperature in which the light emission element is placed. As a result, it may be achieved a fluorescent emission in an yield of nearly 100% (it is called as a thermally activated delayed fluorescence: TADF). And it was found a compound enabling to occur this phenomenon (refer to Non-patent Document 1, for example).

### <Phosphorescence Emission Material>

As described above, although the phosphorescence emission has theoretically an advantage of 3 times of the fluorescence emission, an energy deactivation (=phosphorescence emission) from the triplet excited state to the singlet ground state is a forbidden transition. In the same manner, the intersystem crossing from the singlet excited state to the triplet excited state is also a forbidden transition. Consequently, its rate constant is usually small. That is, since the transition takes place hardly, the lifetime of the exciton becomes long such as an order of millisecond or second. As a result, it is difficult to obtain a required emission.

However, when an emission occurs from a complex including a heavy atom of iridium or platinum, the rate constant of the above-described forbidden transition becomes larger by 3 orders be the effect of a heavy metal effect of the center metal. It is possible to obtain a phosphorescence quantum efficiency of 100% when selection of the ligand is properly done.

However, in order to obtain an ideal emission, it is required to use a rare metal such as iridium or palladium, or a noble metal such as platinum. If a large amount of these metals are used, the reserve and the price of these metal will become problem.

### <Fluorescence Emission Material>

A common fluorescence emission material is not required to be a heavy metal complex as in the case of a phosphorescence emission material. It can be applied a so-called organic compound composed of a combination of elements such as carbon, oxygen, nitrogen and hydrogen. Further, a non-metallic element such as phosphor, sulfur, and silicon may be used. And a complex of typical element such as aluminum or zinc may be used. The variation of the materials is almost without limitation.

A fluorescent compound according to the present invention and used as a fluorescence emission material is characterized in that: the fluorescent compound has an internal quantum efficiency of 50% or more by electrical excitation; and

the fluorescent compound has a half bandwidth of 100 nm or less in an emission band of an emission maximum wavelength in an emission spectrum of the fluorescent compound at a room temperature.

In a common fluorescent compound, the theoretical upper limit of the internal quantum efficiency is 25%. On the other hand, the specific fluorescent compound proposed by the group of Adachi has the theoretical upper limit of the internal quantum efficiency of 100% (refer to Non-patent Document 2). However, the known compounds based on this principle have not been sufficiently investigated due to the difficulty of synthesis. As a result, there were disclosed many examples in which compound having a large half bandwidth were used.

When a combination of compounds used in an organic layer such as a light emitting is unsuitable, that is, when a fluorescent compound having a large half bandwidth and a common host compound are used together, energy transfer from the fluorescent compound to the host compound is induced to result in generating an unrequired host compound at an excited state. Namely, by the substance derived from the unrequired host compound at an excited state, it will be induced a problem that a change rate of the film condition of the light emitting layer will be large. This problem is to be solved. Consequently, it was required to a means to correspond to the problem which was not necessary for the common fluorescent compound by focusing on the half bandwidth of the fluorescent compound.

When a fluorescent compound has an internal quantum efficiency exceeding 25%, it is classified as a fluorescent compound based on a new principle. It has been revealed that when a fluorescent compound has an internal quantum efficiency exceeding 50%, the change rate of the film condition of the light emitting layer was very large.

One of the effective methods to solve this problem is to select a compound having a half bandwidth within a specific range among the fluorescent compounds used in the present invention. After extensively investigating this range, it was found that a practically preferable compound is a fluorescent compound having a half bandwidth of 100 nm or less in an emission band of an emission maximum wavelength in an emission spectrum of the fluorescent compound at a room temperature. It was confirmed that the above-described problem was resolved, at the same time, when the used fluorescent compound has an internal quantum efficiency of 50% or more. It is theoretically preferable that the half bandwidth in an emission band of an emission maximum wavelength in an emission spectrum of the fluorescent compound at a room temperature is small. From the viewpoint of practical use, it is preferable that the half bandwidth is in the range of 30 to 100 nm.

By employing this fluorescent compound, it can effectively use the high internal quantum efficiency to the light emission of an organic electroluminescent element.

### <Delayed Fluorescent Material>

### <Excited Triplet-Triplet Annihilation (TTA) Delayed Fluorescent Material>

A light emission mode employing a delayed fluorescence appeared to solve the problem of the fluorescent material. The TTA mode originated from the collision of the compounds at a triplet state can be described in the following Scheme. That is, in the past, a part of the triplet exciton is only converted to heat. This energy of the exciton is changed to a singlet exciton via an intersystem crossing to result in contributing to the light emission. In a practical organic EL element, it was proved that an external quantum efficiency was double of the conventional fluorescent element.

T*+T*→S*+S Scheme:

(In the Scheme, T* represents a triplet exciton, S* represents a singlet exciton, and S represents a ground state molecule.)

However, as can be seen from the above-described Scheme, only one singlet exciton is generated from two triplet excitons. Consequently, theoretically, 100% internal quantum efficiency cannot be obtained based on this mode.

### <Thermally Activated Delayed Fluorescent (TADF) Material>

A TADF mode, which is another type of high efficient fluorescence emission, is a mode enabling to resolve the problem.

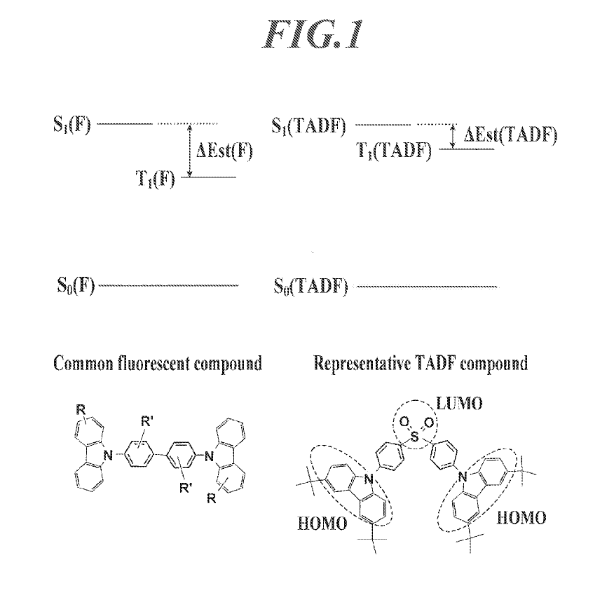

A fluorescent material has an advantage of being molecular-designed without imitation as described above. Among the molecular-designed compounds, there are specific compounds having an energy level difference (hereafter, it is indicated as ΔEst) between a triplet excited state and a singlet excited state being in very close vicinity (refer to FIG. 1).

In spite of that fact that these compounds don't contain a heavy metal atom in the molecule, there occurs a reverse intersystem crossing reaction from the triplet excited state to the singlet excited state due to the small ΔEst value. This reaction will not usually occur. Further, since the rate constant of the deactivation from the singlet excited state to the ground state (=fluorescence emission) is extremely high, the triplet state will likely return to the ground state via the singlet state while emitting fluorescence, instead of thermally deactivating (radiationless deactivation) to the ground state. As a result, in TADF mechanism, ideally, it is possible to realize fluorescence emission of 100%.

### <Molecular Designing Idea Concerning ΔEst>

A molecular designing idea to reduce the ΔEst will be described.

In order to reduce the value of ΔEst, theoretically the most effective way is to minimize the spatial overlaps of the highest occupied molecular orbital (HOMO) and the lowest unoccupied molecular orbital (LUMO).

Generally, in the electronic orbitals of the molecule, it is known that HOMO has a distribution to an electron donating position and LUMO has a distribution to an electron withdrawing position. By introducing an electron donating structure and an electron withdrawing structure in the molecule, it is possible to keep apart the positions in which HOMO and LUMO exist.

In the Non-patent Document 2, for example, by introducing an electron withdrawing structure such as a cyano group, a sulfonyl group or a triazine group, and an electron donating structure such as a carbazole group or a diphenyl amino group, LUMO and HOMO are respectively made localized.

In addition, it is also effective to minimize the molecular structure change between the ground state and the triplet excited state of the molecule. As a means to minimize the structure change, it can cite a compound having an inflexible structure. Here, inflexibility indicates the state in which freely movable portions in the molecule are not abundant such as by preventing a free rotation of the bond between the rings in the molecule, or by introducing a condensed ring having a large n-conjugate plane, for example. In particular, by making the portion participating in the light emission, it is possible to minimize the molecular structure change in the excited state.

### <Common Problem Possessed by TADF Material>

A TADF material possesses a variety of problems arisen from the aspects of the light emission mechanism and the molecular structure.

A part of common problems possessed by a TADF material will be described in the following.

In a TADF material, it is required to keep apart the portions in which HOMO and LUMO exist as much as possible in order to minimize ΔEst. For this reason, the electronic state of the molecule becomes almost near the intra molecular CT state (intramolecular charge transfer state).

When a plurality of these molecules exist, these molecules will be stabilized by making in proximity the donor portion in one molecule and the acceptor portion in other molecule. This stabilized condition is formed not only with 2 molecules, but it can be formed with 3 and 5 molecules. Consequently, there are produced a variety of stabilized conditions having a broad distribution. The shape of absorption spectrum or the emission spectrum will be broad. Further, even if a multiple molecular aggregation of 2 or more molecules does not formed, there may be formed a variety of existing conditions having different interaction directions or angles of two molecules. As a result, basically, the shape of absorption spectrum or the emission spectrum will be broad.

When the emission spectrum becomes broad, it will generate two major problems. One is a problem of decreasing the color purity of the emission color. This is not so important when it is applied to an illumination use. However, when it is used for an electronic device, the color reproduction region becomes small. And the color reproduction of pure colors will become decreased. As a result, it is difficult to apply to a commercial product.

Another problem is the shortened wavelength of the rising wavelength in the short wavelength side of the emission spectrum (it is called as “fluorescent zero-zero band”). That is, the S₁ level becomes high (becoming higher energy level of the excited singlet energy).

When the fluorescent zero-zero band becomes shortened, the phosphorescent zero-zero band derived from T₁ (being lower than S₁) will become shortened (becoming higher T₁).

Therefore, the host compound is required to have high S₁ and high T₁ in order to prevent the reverse energy transfer from the dopant.

This is a major problem. A host compound basically made of an organic compound will take plural and unstable chemical species conditions such as a cationic radical state, an anionic radical state and an excited state in an organic EL element. These chemical species can be made existed in relatively stable condition by expanding a π-conjugate system in the molecule.

However, in order to achieve high S₁ and high T₁, it is required that the n-conjugate system in the molecule has to be reduced or cut. It becomes difficult to achieve stability at the same time. As a result, the lifetime of the light emission element becomes shorten.

Further, in a TADF material without containing a heavy metal, the transition from the triplet excited state to the ground state is forbidden transition. The existing time at the triplet excited state (exciton lifetime) is extremely long such as in a order of several hundred microsecond to millisecond. Therefore, even if the T₁ energy level of the host compound is higher than that of the light emitting material, it will be increased the probability of taking place a reverse energy transfer from the triplet excited state of the light emitting material to the host compound due to the long lifetime. As a result, it is difficult to sufficiently make occur a required reverse intersystem crossing from the triplet excited state to the singlet excited state of the TADF material. Instead, there occurs an unrequired reverse energy transfer to the host compound as a major route to result in failing to obtain insufficient emission efficiency.

In order to solve the above-described problem, it is required to make sharp a shape of an emission spectrum of the TADF material, and to decrease the difference between the emission maximum wavelength and the rise of the emission spectrum. This can be achieved basically by reducing the change of the molecular structure of the singlet excited state and the triplet excited state.

Further, in order to prevent the reverse energy transfer to the host compound, it is effective to shorten the existing time of the triplet excited state of the TADF material (exciton lifetime). In order to realize this, the possible ways to solve the problem are: to minimize the molecular structure change between the ground state and the triplet excited state; and to introduce a suitable substituent or an element to loosen the forbidden transition.

The present invention includes the light emitting materials being reduced the structure change in the excited state, and the light emitting materials having a short existing time in the triplet excited state as a designing idea.

A fluorescent compound according to the present invention, and in particular, various measuring methods about the material having a small ΔEst will be described in the following.

<Example of Measurement of Thin Film Resistance with Impedance Spectroscopy Method>

An impedance spectroscopy method is a method of analysis by performing either converting or amplifying a subtle physical property change of an organic EL element. It is characterized in achieving measurement of resistance (R) and capacitance (C) with high sensitivity without destructing an organic EL element. It is commonly practiced to measure electric properties by using Z plot, M plot and ε plot for impedance spectroscopy analysis. The analysis method thereof is described in detail in pp. 423 to 425 of “Handbook of Thin film evaluation” published by Techno System, Co. Ltd, for example.

It will be described a method of obtaining resistance of a specified layer of an organic EL element by applying the impedance spectroscopy. Here, the organic EL element has a constitution of: [ITO/HIL (hole injection layer)/HTL (hole transport layer)/EML (light emitting layer)/ETL (electron transport layer)/EIL (electron injection layer)/Al].

When a resistance value of an electron transport layer (ETL) is measured, for example, there are prepared EL samples each having only a different thickness of ETL. By comparing M plot of each EL samples, it can determine the portion which corresponds to ETL in the curve of M plot.

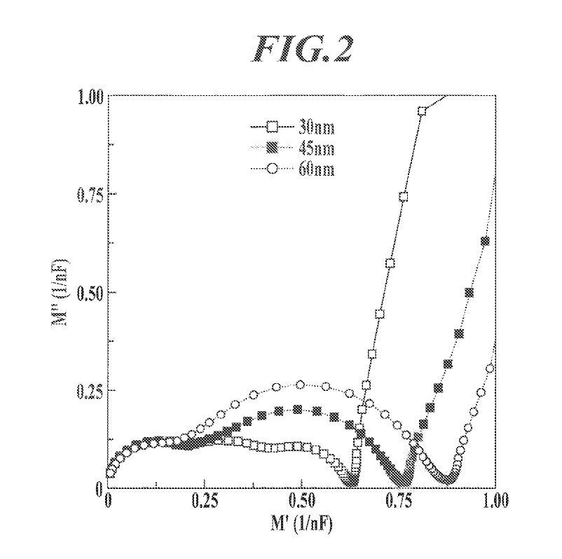

FIG. 2 is an example showing M plots of electron transport layers each having a different thickness. It shows an example of the cases having a thickness of 30, 45 and 60 nm.

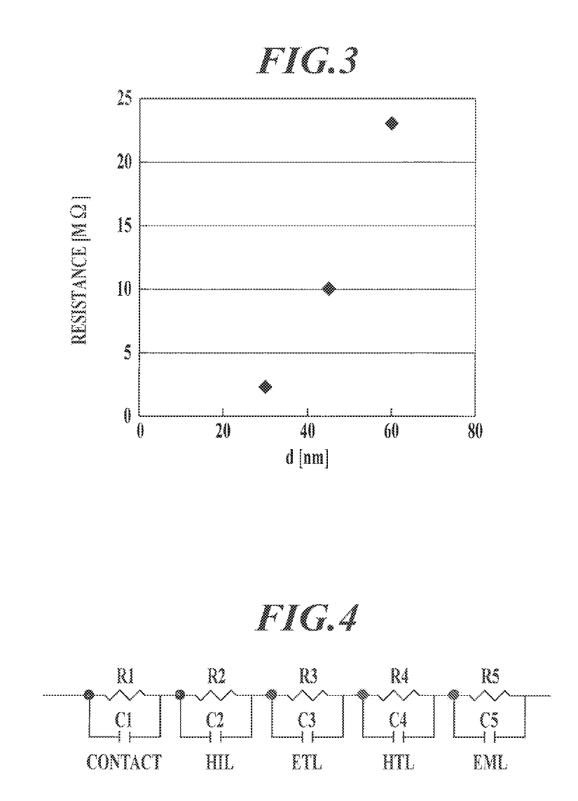

The resistance values (R) obtained from these plots are plotted with respect to the thickness of ETL in FIG. 3. Since the plots are approximately on a straight line, it can determine the resistance value of each thickness.

FIG. 3 is an example showing the relationship between the thickness of ETL and the resistance value. The resistance value of each thickness can be determined since the plots having an ETL thickness and a resistance value are approximately on a straight line as shown in FIG. 3.

An organic EL element having an element constitution of: [ITO/HIL/HTL/EML/ETL/EIL/Al] was analyzed for each layer as an example of an equivalent circuit model (FIG. 4). The results of analysis are shown in FIG. 5. FIG. 5 is an example showing a relationship between a resistance and a voltage for each layer.

FIG. 4 shows an equivalent circuit model of an organic electroluminescent element having an element constitution of: [ITO/HIL/HTL/EML/ETL/EIL/Al].

FIG. 5 is an example of analysis results of an organic electroluminescent element having an element constitution of: [ITO/HIL/HTL/EML/ETL/EIL/Al].

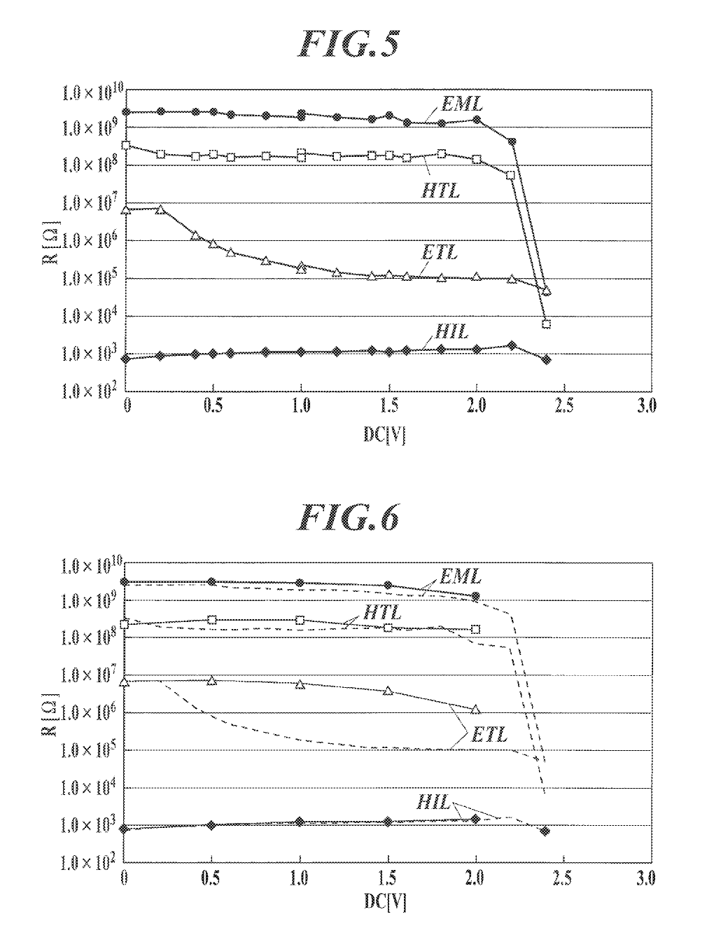

On the other hand, FIG. 6 indicates superposed measurement results obtained in the same conditions by using the same organic EL element after being deteriorated with emitting light for a prolonged time. The results at 1 V for each layer are shown in Table 1. FIG. 6 shows an example of analytical result.

TABLE 1

| | HIL (Ω) | ETL (Ω) | HTL (Ω) | HML (Ω) |
|---|---|---|---|---|
| Before driving | 1.1k | 0.2M | 0.2 G | 1.9 G |
| After deterioration | 1.2k | 5.7M | 0.3 G | 2.9 G |

It was found the following. In the deteriorated organic EL element, only the resistance value of ETL was largely increased, and it became about 30 times larger at 1 V of DC voltage.

By using the method described above, the change of resistance before and after applying current can be measured as described in Examples of the present specification.

### <Measurement of Half Bandwidth of an Emission Spectrum of Fluorescent Compound>

The measurement of a half bandwidth of an emission spectrum of a fluorescent compound can be done with Hitachi spectrofluorometer F-4000 to a fluorescent compound solution prepared by dissolving in dichloromethane. The measurement is done at room temperature, and it can be obtained a half bandwidth of an emission band of an emission maximum wavelength in an emission spectrum.

### <Calculation of Internal Quantum Efficiency (IQE) of Fluorescent Compound>

The calculation of an internal quantum efficiency of a fluorescent compound is done to a prepared organic electroluminescent element containing a fluorescent compound and by referring to the description in the following documents: A. Chutinan, K. Ishihara, T. Asano, M. Fujita, and S. Noda, “Theoretical Analysis on Light-Extraction Efficiency of Organic Light-Emitting Diodes using FDTD and Mode-Expansion Methods”, Organic Electronics, vol. 6, pp, 3-9 (2005).

Specifically, an external quantum efficiency (hereafter, it is called as EQE) can be measured when the organic EL element is driven at 5 V at a room temperature using an integrated sphere with an external quantum efficiency measuring apparatus.

Then, a mode analysis is done with an analysis software using thickness information and optical constant of the organic EL element. The ratio of the emitting light from the inside to the outside of the organic EL element, that is, the light extraction efficiency (OC) can be calculated.

An external quantum efficiency (EQE) is represented by a product of an internal quantum efficiency (IQE) and a light extraction efficiency (OC) (refer to Scheme (A)).

EQE=IQE×OC Scheme (A):

In the present invention, by applying EQE and OC, being obtained by the measurement and analysis, to Scheme (A), an internal quantum efficiency of a fluorescent compound in an organic EL element can be calculated.

### <<Constitution Layers of Organic EL Element>>

An organic EL element of the present invention is an element containing at least one organic layer interposed between an anode and a cathode. It is characterized in that: at least one organic layer contains a fluorescent compound and a carbazole derivative; the fluorescent compound has an internal quantum efficiency of 50% or more by electrical excitation; and the fluorescent compound has a half bandwidth of 100 nm or less in an emission band of an emission maximum wavelength in an emission spectrum of the fluorescent compound at a room temperature.

Each layer and the compounds incorporated therein are described in detail in the following.

Representative element constitutions used for an organic EL element of the present invention are as follows, however, the present invention is not limited to these.
(1) Anode/light emitting layer/cathode
(2) Anode/light emitting layer/electron transport layer/cathode
(3) Anode/hole transport layer/light emitting layer/cathode
(4) Anode/hole transport layer/light emitting layer/electron transport layer/cathode
(5) Anode/hole transport layer/light emitting layer/electron transport layer/electron injection layer/cathode
(6) Anode/hole injection layer/hole transport layer/light emitting layer/electron transport layer/cathode
(7) Anode/hole injection layer/hole transport layer/(electron blocking layer)/light emitting layer/(hole blocking layer)/electron transport layer/electron injection layer/cathode

Among these, the embodiment (7) is preferably used. However, the present invention is not limited to this.

The light emitting layer of the present invention is composed of one or a plurality of layers. When a plurality of layers are employed, it may be placed a non-light emitting intermediate layer between the light emitting layers.

According to necessity, it may be provided with a hole blocking layer (it is also called as a hole barrier layer) or an electron injection layer (it is also called as a cathode buffer layer) between the light emitting layer and the cathode. Further, it may be provided with an electron blocking layer (it is also called as an electron barrier layer) or an hole injection layer (it is also called as an anode buffer layer) between the light emitting layer and the anode.

An electron transport layer according to the present invention is a layer having a function of transporting an electron. An electron transport layer includes an electron injection layer, and a hole blocking layer in a broad sense. Further, an electron transport layer unit may be composed of plural layers.

A hole transport layer according to the present invention is a layer having a function of transporting a hole. A hole transport layer includes a hole injection layer, and an electron blocking layer in a broad sense. Further, a hole transport layer unit may be composed of plural layers.

In the representative element constitutions as described above, the layers eliminating an anode and a cathode are also called as “organic layers”.

### (Tandem Structure)

An organic EL element according to the present invention may be so-called a tandem structure element in which plural light emitting units each containing at least one light emitting are laminated.

A representative example of an element constitution having a tandem structure is as follows.

Anode/first light emitting unit/intermediate layer/second light emitting unit/intermediate layer/third light emitting unit/cathode.

Here, the above-described first light emitting unit, second light emitting unit, and third light emitting unit may be the same or different. It may be possible that two light emitting units are the same and the remaining one light emitting unit is different.

The plural light emitting units each may be laminated directly or they may be laminated through an intermediate layer. Examples of an intermediate layer are: an intermediate electrode, an intermediate conductive layer, a charge generating layer, an electron extraction layer, a connecting layer, and an intermediate insulating layer. Known composing materials may be used as long as it can form a layer which has a function of supplying an electron to an adjacent layer to the anode, and a hole to an adjacent layer to the cathode.

Examples of a material used in an intermediate layer are: conductive inorganic compounds such as ITO (indium tin oxide), IZO (indium zinc oxide), ZnO₂, TiN, ZrN, HfN, TiOₓ, VOₓ, CuI, InN, GaN, CuAlO₂, CuGaO₂, SrCu₂O₂, LaB₆, RuO₂, and Al; a two-layer film such as Au/Bi₂O₃; a multi-layer film such as SnO₂/Ag/SnO₂, ZnO/Ag/ZnO, Bi₂O₃/Au/Bi₂O₃, TiO₂/TiN/TiO₂, and TiO₂/ZrN/TiO₂; fullerene such as C₆₀; and a conductive organic layer such as oligothiophene, metal phthalocyanine, metal-free phthalocyanine, metal porphyrin, and metal-free porphyrin. The present invention is not limited to them.

Examples of a preferable constitution in the light emitting unit are the constitutions of the above-described (1) to (7) from which an anode and a cathode are removed. However, the present invention is not limited to them.

Examples of a tandem type organic EL element are described in: U.S. Pat. No. 6,337,492, U.S. Pat. No. 7,420,203, U.S. Pat. No. 7473923, U.S. Pat. No. 6,872,472, U.S. Pat. No. 6,107,734, U.S. Pat. No. 6,337,492, WO 2005/009087, JP-A 2006-228712, JP-A 2006-24791, JP-A 2006-49393, JP-A 2006-49394, JP-A 2006-49396, JP-A 2011-96679, JP-A 2005-340187, JP Patent 4711424, JP Patent 3496681, JP Patent 3884564, JP Patent 4213169, JP-A 2010-192719, JP-A 2009-076929, JP-A 2008-078414, JP-A 2007-059848, JP-A 2003-272860, JP-A 2003-045676, and WO 2005/094130. The constitutions of the elements and the composing materials are described in these documents, however, the present invention is not limited to them.

Each layer that constitutes an organic EL element of the present invention will be described in the following.

### <<Light Emitting Layer>>

A light emitting layer relating to the present invention is a layer which provide a place of emitting light via an exciton produce by recombination of electrons and holes injected from an electrode or an adjacent layer. The light emitting portion may be either within the light emitting layer or at an interface between the light emitting layer and an adjacent layer thereof.

A total thickness of the light emitting layer is not particularly limited. However, in view of layer homogeneity, required voltage during light emission, and stability of the emitted light color against a drive electric current, a layer thickness is preferably adjusted to be in the range of 2 nm to 5 μm, more preferably, it is in the range of 2 to 500 nm, and still most preferably, it is in the range of 5 to 200 nm.

Each light emitting layer is preferably adjusted to be in the range of 2 nm to 1 μm, more preferably, it is in the range of 2 to 200 nm, and still most preferably, it is in the range of 3 to 150 nm.

It is preferable that the light emitting layer of the present invention incorporates a light emitting dopant (a light emitting dopant compound, a dopant compound, or simply called as a dopant) and a host compound (a matrix material, a light emitting host compound, or simply called as a host).

### (1) Light Emitting Dopant

As a light emitting dopant, it is preferable to employ: a fluorescence emitting dopant (also referred to as a fluorescent dopant and a fluorescent compound) and a phosphorescence emitting dopant (also referred to as a phosphorescent dopant and a phosphorescent emitting material). In the present invention, it is preferable that at least one light emitting layer contains a fluorescence emitting dopant.

A concentration of a light emitting dopant in a light emitting layer may be arbitrarily decided based on the specific dopant employed and the required conditions of the device. A concentration of a light emitting dopant may be uniform in a thickness direction of the light emitting layer, or it may have any concentration distribution.

It may be used plural light emitting dopants according to the present invention. It may use a combination of dopants each having a different structure, or a combination of a fluorescence emitting dopant and a phosphorescence emitting dopant. Any required emission color will be obtained by this.

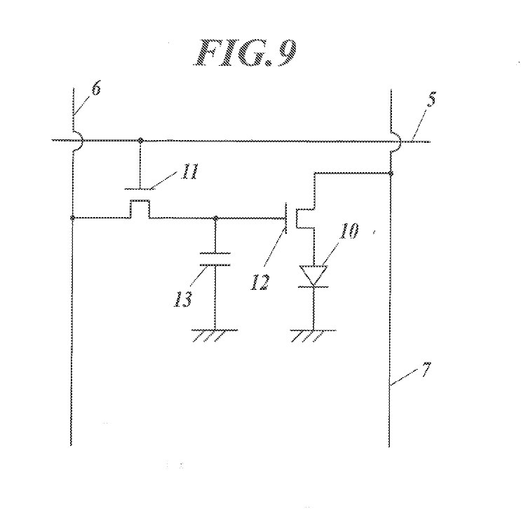

Color of light emitted by an organic EL element or a compound of the present invention is specified as follows. In FIG. 9.16 on page 108 of “Shinpen Shikisai Kagaku Handbook (New Edition Color Science Handbook)” (edited by The Color Science Association of Japan, Tokyo Daigaku Shuppan Kai, 1985), values determined via a spectroradiometric luminance meter CS-1000 (produced by Konica Minolta, Inc.) are applied to the CIE chromaticity coordinate, whereby the color is specified.

In the present invention, it is preferable that the organic EL element of the present invention exhibits white emission by incorporating one or plural light emitting layers containing plural emission dopants having different emission colors.

The combination of emission dopants producing white is not specifically limited. It may be cited, for example, combinations of: blue and orange; and blue, green and red.

It is preferable that “white” in the organic EL element of the present invention shows chromaticity in the CIE 1931 Color Specification System at 1,000 cd/m² in the region of x=0.39±0.09 and y=0.38±0.08, when measurement is done to 2-degree viewing angle front luminance via the aforesaid method.

### (1.1) Fluorescence Emitting Dopant

As a fluorescence emitting dopant (hereafter, it is also called as “a fluorescence dopant”) according to the present invention, specific examples will be described.

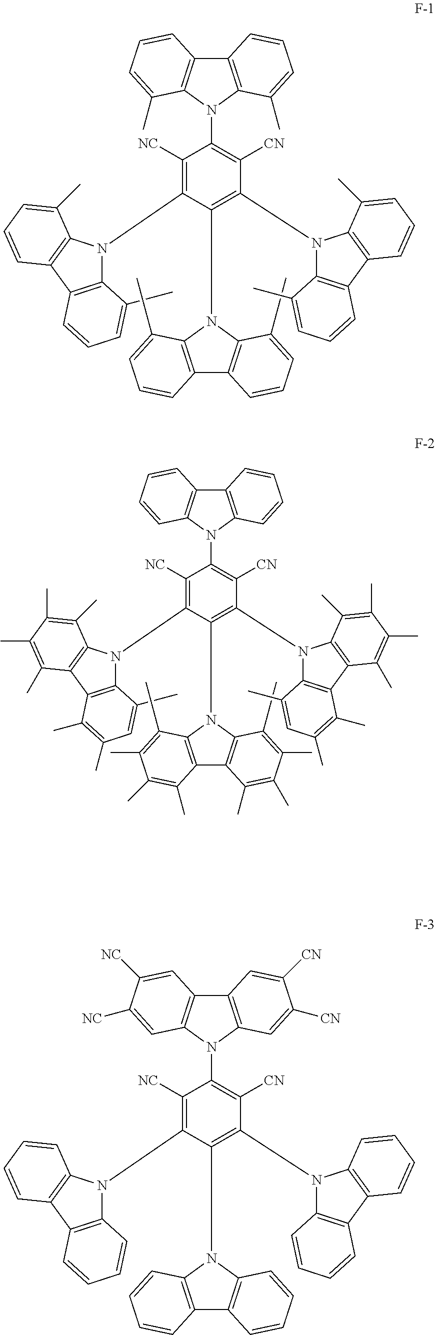

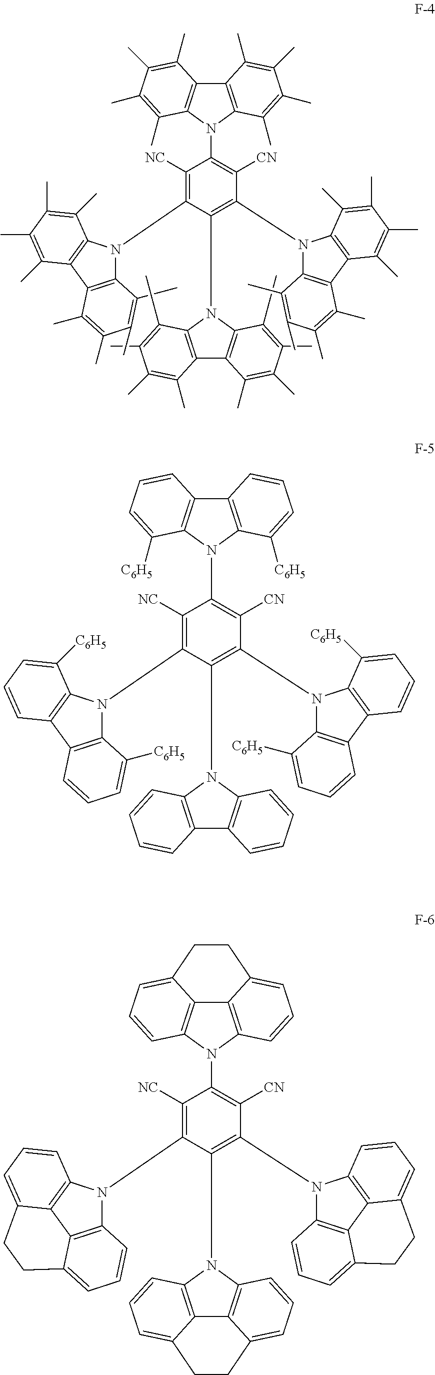

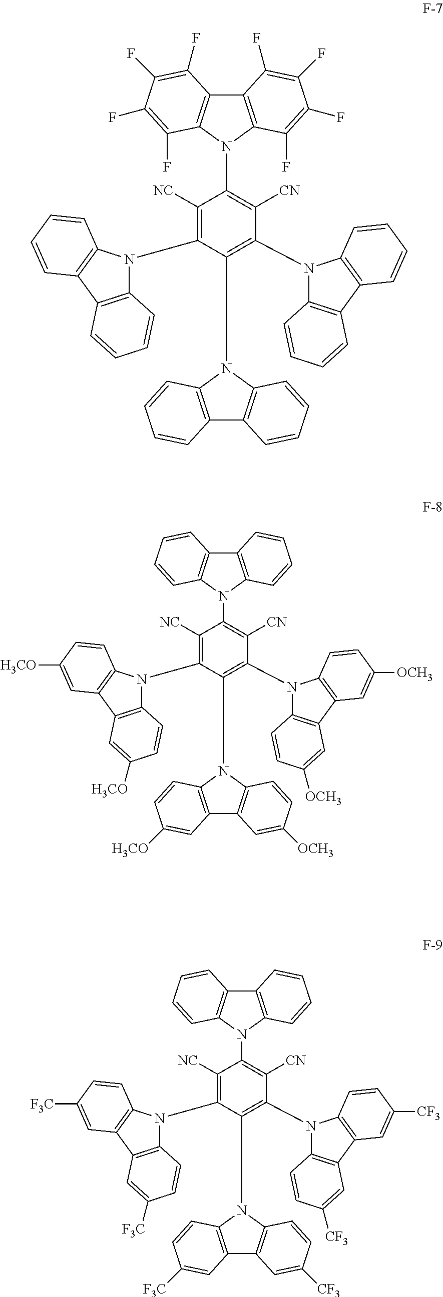 [SMILES: N#Cc1c(-n2c3ccccc3c3ccccc32)c(-n2c3ccccc3c3ccccc32)c(-n2c3ccccc3c3ccccc32)c(C#N)c1-n1c2c(F)c(F)c(F)c(F)c2c2c(F)c(F)c(F)c(F)c21 ; COc1ccc2c(c1)c1cc(OC)ccc1n2-c1c(C#N)c(-n2c3ccccc3c3ccccc32)c(C#N)c(-n2c3ccc(OC)cc3c3cc(OC)ccc32)c1-n1c2ccc(OC)cc2c2cc(OC)ccc21 ; N#Cc1c(-n2c3ccccc3c3ccccc32)c(C#N)c(-n2c3ccc(C(F)(F)F)cc3c3cc(C(F)(F)F)ccc32)c(-n2c3ccc(C(F)(F)F)cc3c3cc(C(F)(F)F)ccc32)c1-n1c2ccc(C(F)(F)F)cc2c2cc(C(F)(F)F)ccc21]

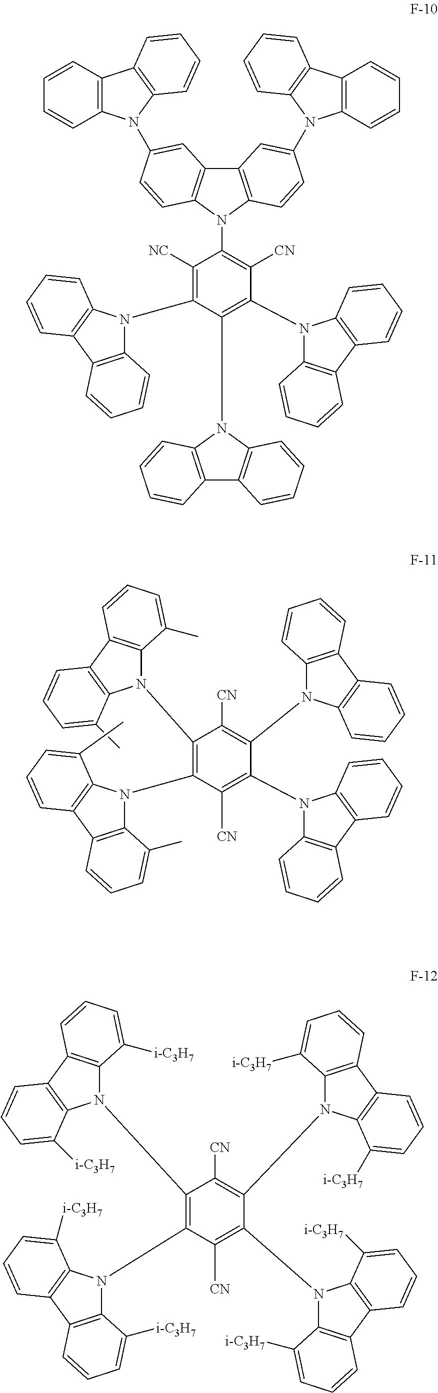

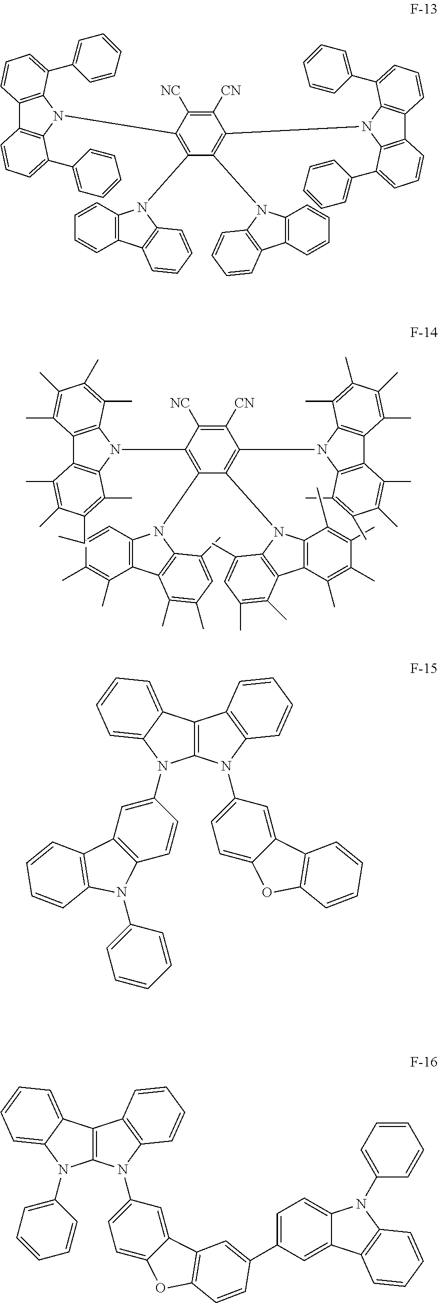

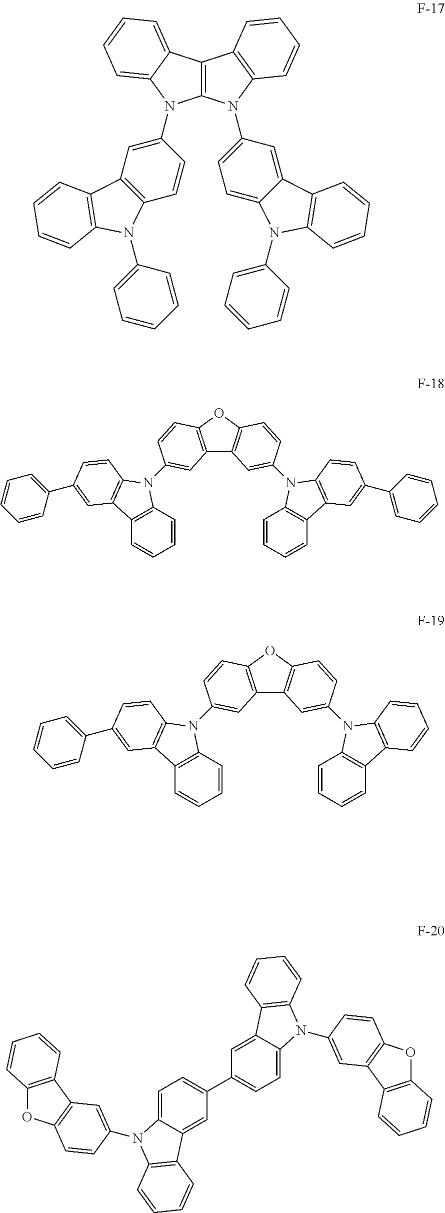 [SMILES: c1ccc(-n2c3ccccc3c3cc(-n4c5ccccc5c5c6ccccc6n(-c6ccc7c(c6)c6ccccc6n7-c6ccccc6)c54)ccc32)cc1 ; c1ccc(-c2ccc3c(c2)c2ccccc2n3-c2ccc3oc4ccc(-n5c6ccccc6c6cc(-c7ccccc7)ccc65)cc4c3c2)cc1 ; c1ccc(-c2ccc3c(c2)c2ccccc2n3-c2ccc3oc4ccc(-n5c6ccccc6c6ccccc65)cc4c3c2)cc1 ; c1ccc2c(c1)oc1ccc(-n3c4ccccc4c4cc(-c5ccc6c(c5)c5ccccc5n6-c5ccc6oc7ccccc7c6c5)ccc43)cc12]

### (1.2) Phosphorescence Emitting Dopant

A phosphorescence emitting dopant (hereafter, it is also called as “a phosphorescence dopant”) according to the present invention will be described.

The phosphorescence emitting dopant is a compound which is observed emission from an excited triplet state thereof. Specifically, it is a compound which emits phosphorescence at a room temperature (25° C.) and exhibits a phosphorescence quantum yield of at least 0.01 at 25° C. The phosphorescence quantum yield is preferably at least 0.1.

The phosphorescence quantum yield will be determined via a method described in page 398 of Bunko II of Dai 4 Han Jikken Kagaku Koza 7 (Spectroscopy II of 4th Edition Lecture of Experimental Chemistry 7) (1992, published by Maruzen Co. Ltd.). The phosphorescence quantum yield in a solution will be determined using appropriate solvents. However, it is only necessary for the phosphorescent dopant of the present invention to exhibit the above phosphorescence quantum yield (0.01 or more) using any of the appropriate solvents.

A phosphorescence dopant may be suitably selected and employed from the known materials used for a light emitting layer for an organic EL element.

Examples of a known phosphorescence dopant are compound described in the following publications.

Nature 395, 151 (1998), Appl. Phys. Lett. 78, 1622 (2001), Adv. Mater. 19, 739 (2007), Chem. Mater. 17, 3532 (2005), Adv. Mater. 17, 1059 (2005), WO 2009/100991, WO 2008/101842, WO 2003/040257, US 2006/835469, US 2006/0202194, US 2007/0087321, US 2005/0244673, Inorg. Chem. 40, 1704 (2001), Chem. Mater. 16, 2480 (2004), Adv. Mater. 16, 2003 (2004), Angew. Chem. Int. Ed. 2006, 45, 7800, Appl. Phys. Lett. 86, 153505 (2005), Chem. Lett. 34, 592 (2005), Chem. Commun. 2906 (2005), Inorg. Chem. 42, 1248 (2003), WO 2009/050290, WO 2002/015645, WO 2009/000673, US 2002/0034656, U.S. Pat. No. 7,332,232, US 2009/0108737, US 2009/0039776, U.S. Pat. No. 6,921,915, U.S. Pat. No. 6,687,266, US 2007/0190359, US 2006/0008670, US 2009/0165846, US 2008/0015355, U.S. Pat. No. 7,250,226, U.S. Pat. No. 7,396,598, US 2006/0263635, US 2003/0138657, US 2003/0152802, U.S. Pat. No. 7,090,928, Angew. Chem. Int. Ed. 47, 1 (2008), Chem. Mater. 18, 5119 (2006), Inorg. Chem. 46, 4308 (2007), Organometallics 23, 3745 (2004), Appl. Phys. Lett. 74, 1361 (1999), WO 2002/002714, WO 2006/009024, WO 2006/056418, WO 2005/019373, WO 2005/123873, WO 2005/123873, WO 2007/004380, WO 2006/082742, US 2006/0251923, US 2005/0260441, U.S. Pat. No. 7,393,599, U.S. Pat. No. 7,534,505, U.S. Pat. No. 7,445,855, US 2007/0190359, US 2008/0297033, U.S. Pat. No. 7,338,722, US 2002/0134984, and U.S. Pat. No. 7,279,704, US 2006/098120, US 2006/103874, WO 2005/076380, WO 2010/032663, WO 2008/140115, WO 2007/052431, WO 2011/134013, WO 2011/157339, WO 2010/086089, WO 2009/113646, WO 2012/020327, WO 2011/051404, WO 2011/004639, WO 2011/073149, JP-A 2012-069737, JP Application No. 2011-181303, JP-A 2009-114086, JP-A 2003-81988, JP-A 2002-302671 and JP-A 2002-363552.

Among them, preferable phosphorescence emitting dopants are organic metal complexes containing Ir as a center metal. More preferable are complexes containing at least one coordination mode selected from a metal-carbon bond, a metal-nitrogen bond, a metal-oxygen bond and a metal-sulfur bond.

### (2) Host Compound

A host compound according to the present invention is a compound which mainly plays a role of injecting or transporting a charge in a light emitting layer. In an organic EL element, an emission from the host compound itself is substantially not observed.

Among the compounds incorporated in the light emitting layer, a mass ratio of the host compound in the aforesaid layer is preferably at least 20%.

Host compounds may be used singly or may be used in combination of two or more compounds. By using plural host compounds, it is possible to adjust transfer of charge, thereby it is possible to achieve high efficiency of an organic EL element.

In the following, preferable host compounds used in the present invention will be described.

A host compound used in combination of a fluorescent compound according to the present invention is not specifically limited. From the viewpoint of a reverse energy transfer, it is preferable that the host compound has a larger excited energy than an excited singlet energy of the fluorescent compound of the present invention. It is more preferable that the host compound has a larger excited triplet energy than an excited triplet energy of the fluorescent compound of the present invention.

A host compound bears the function of transfer of the carrier and generation of an exciton in the light emitting layer. Therefore, it is preferable that the host compound can exist in all of the active species of a cation radical state, an anion radial state and an excited state, and that it will not make chemical reactions such as decomposition and addition. Further, it is preferable that the host molecule will not move in the layer with an Angstrom level when an electric current is applied.

In particular, when the jointly used light emitting dopant exhibits TADF emission, since the lifetime of the triplet excited state of the TADF material is long, it is required an appropriate design of a molecular structure to prevent the host compound from having a lower T₁ level such as: the host compound has a high T₁ energy; the host compounds will not form a low T₁ state when aggregated each other; the TADF material and the host compound will not form an exciplex; and the host compound will not form an electromer by applying an electric field.

In order to satisfying the above-described requirements, it is required that: the host compound itself has a high hopping mobility; the host compound has high hole hopping mobility; and the host compound has small structural change when it becomes a triplet excited state. As a representative host compound satisfying these requirements, preferable compounds are: a compound having a high T₁ energy and a 14 π-electron system of an extended n conjugated structure as a partial structure such as a carbazole structure, an azacarbazole structure, a dibenzofuran structure, a dibenzothiophene structure and an azadibenzofuran structure. Further, as a representative compound, it can cite compounds in which these rings take a biaryl and/or a multi-aryl structure. Here, “an aryl” indicates not only an aromatic hydrocarbon ring, but an aromatic heterocyclic ring.

It is more preferable that the compound has a carbazole structure directly combined with other aromatic heterocyclic ring having a 14 π-electron system different from the carbazole structure. It is still more preferable that the compound is a carbazole derivative having two aromatic heterocyclic rings each having a 14 π-electron system in the molecule.

A host compound according to the present invention is characterized in having a structure represented by Formula (I). The reason of this is that the compound represented by Formula (I) has a condensed ring structure and the π-electron cloud is extended. As a result, the compound has high carrier transport ability and a high glass transition temperature (Tg). Further, although a condensed aromatic ring generally has a low triplet energy (T₁), the compound represented by Formula (I) has a high triplet energy (T₁), and it is appropriately used for an emission of short wavelength (namely, having large T₁ and S₁).

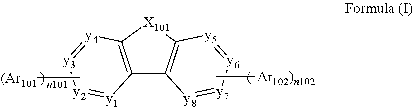

In Formula (I), X₁₀₁ represents NR₁₀₁, an oxygen atom, a sulfur atom, CR₁₀₂R₁₀₃, or SiR₁₀₂R₁₀₃; y₁ to y₈ each represent CR₁₀₄, or a nitrogen atom; R₁₀₁ to R₁₀₄ each represent a hydrogen atom or a substituent, provided that R₁₀₁ to R₁₀₄ each may be bonded together to form a ring; Ar₁₀₁ and to Ar₁₀₂ each represent an aromatic ring, provided that each may be the same or different with each other; and n101 and n102 each represent an integer of 0 to 4, provided that when R₁₀₁ represents a hydrogen atom, n101 represents an integer of 1 to 4.

In Formula (1), R₁₀₁ to R₁₀₄ represent a hydrogen atom or a substituent. Here, the substituent indicates a group which may be held as long as it does not inhibit the function of a host compound. For example, when the substituent is introduced in view of the synthetic point, that compound is within the range of the present invention, if it shows the effects of the present invention.

Examples of a substituent represented by R₁₀₁ to R₁₀₄ include: a straight or a branched alkyl group (for example, a methyl group, an ethyl group, a propyl group, an isopropyl group, a t-butyl group, a pentyl group, a hexyl group, an octyl group, a dodecyl group, a tridecyl group, a tetradecyl group, and a pentadecyl group); an alkenyl group (for example, a vinyl group, and an allyl group); an alkynyl group (for example, an ethynyl group and a propargyl group); an aromatic hydrocarbon group (also called an aromatic carbon ring group or an aryl group, for example, a group derived from a benzene ring, a biphenyl ring, a naphthalene ring, an azulene ring, an anthracene ring, a phenanthrene ring, a pyrene ring, chrysene ring, a naphthacene ring, a triphenylene ring, an o-terphenyl ring, a m-terphenyl ring, a p-terphenyl ring, an acenaphthene ring, a coronene ring, an indene ring, a fluorene ring, a fluoranthene ring, a naphthacene ring, a pentacene ring, a perylene ring, a pentaphene ring, a picene ring, a pyrene ring, a pyranthrene ring, an anthanthrene ring, or a tetralin ring); an aromatic heterocyclic group (for example, a group derived from a furan ring, a dibenzofuran ring, a thiophene ring, a dibenzothiophene ring, an oxazole ring, a pyrrole ring, a pyridine ring, a pyridazine ring, a pyrimidine ring, a pyrazine ring, a triazine ring, a benzimidazole ring, an oxadiazole ring, a triazole ring, an imidazole ring, a pyrazole ring, thiazole ring, an indole ring, an indazole ring, a benzimidazole ring, a benzothiazole ring, a benzoxazole ring, a quinoxaline ring, quinazoline ring, cinnoline ring, a quinoline ring, an isoquinoline ring, a phthalazine ring, a naphthyridine ring, a carbazole ring, a carboline ring, or a diazacarbazole ring (indicating a ring structure in which one of the carbon atoms constituting the carboline ring of the carbolinyl group is replaced with nitrogen atoms, a carboline ring and a diazacarbazole ring may be called as an azacarbazole ring); a non-aromatic hydrocarbon ring group (for example, a cyclopentyl group, and a cyclohexyl group); a non-aromatic heterocyclic ring group (for example, a pyrrolidyl group, an imidazolidyl group, a morpholyl group, and an oxazolidyl group); an alkoxy group (for example, a methoxy group, an ethoxy group, a propyloxy group, a pentyloxy group, an hexyloxy group, an octyloxy group, and a dodecyloxy group); a cycloalkoxy group (for example, a cyclopentyloxy group and a cyclohexyloxy group); an aryloxy group (for example, a phenoxy group and a naphthyloxy group); an alkylthio group (for example, a methylthio group, an ethylthio group, a propylthio group, a pentylthio group, a hexylthio group, an octylthio group, and a dodecylthio group); a cycloalkylthio group (for example, a cyclopentylthio group and a cyclohexylthio group); an arylthio group (for example, a phenylthio group and a naphthylthio group); an alkoxycarbonyl group (for example, a methyloxycarbonyl group, an ethyloxycarbonyl group, a butyloxycarbonyl group, an octyloxycarbonyl group, and a dodecyloxycarbonyl group); an aryloxycarbonyl group (for example, a phenyloxycarbonyl group and a naphthyloxycarbonyl group); a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, and a 2-pyridylaminosulfonyl group); an acyl group (for example, an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, and a pyridylcarbonyl group); an acyloxy group (for example, an acetyloxy group, an ethylcarbonyloxy group, a butylcarbonyloxy group, an octylcarbonyloxy group, a dodecylcarbonyloxy group, and a phenylcarbonyloxy group); an amido group (for example, a methylcarbonylamino group, an ethylcarbonylamino group, a dimethylcarbonylamino group, a propylcarbonylamino group, a pentylcarbonylamino group, a cyclohexylcarbonylamino group, a 2-ethyhexylcarbonylamino group, an octylcarbonylamino group, a dodecylcarbonylamino group, a phenylcarbonylamino group, and a naphthylcarbonylamino group); a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethymexylaminocarbonyl group, a dodecylaminocarbonyl group, a phenylaminocarbonyl group, a naphthylaminocarbonyl group, and a 2-pyridylaminocarbonyl group); a ureido group (for example, a methylureido group, an ethylureido group, a pentylureido group, a cyclohexylureido group, an octylureido group, a dodecylureido group, a phenylureido group, a naphthylureido group, and a 2-pyridylaminoureido group); a sulfinyl group (for example, a methylsulfinyl group, an ethylsufinyl group, a butylsulfinyl group, a cyclohexylsulfinyl group, a 2-ethylhexylsulfinyl group, a dodecylsulfinyl group, a phenylsulfinyl group, a naphthylsulfinyl group, and a 2-pyridylsulfinyl group); an alkylsulfonyl group (for example, a methylsulfonyl group, an ethylsulfonyl group, a butylsulfinyl group, a cyclohexylsulfonyl group, a 2-ethylhexylsulfonyl group, and a dodecylsulfonyl group), an arylsulfonyl group or a heteroarylsulfonyl group (for example, a phenylsulfonyl group, a naphthylsulfonyl group, and a 2-pyridylsulfonyl group); an amino group (for example, an amino group, an ethylamino group, a dimethylamino group, a butylamino group, a cyclopentylamino group, a dodecylamino group, an anilino group, a naphthylamino group, and a 2-pyridylamino group); a halogen atom (for example, a fluorine atom, a chlorine atom and a bromine atom); a fluorinated hydrocarbon group (for example, a fluoromethyl group, trifluoromethyl group, a pentafluoroethyl group and a pentafluorophenyl group); a cyano group; a nitro group; a hydroxyl group; a mercapto group; a silyl group (for example, a trimethylsilyl group, a triisopropylsilyl group, a triphenylsilyl group, and a phenyldiethylsilyl group), and a deuterium atom.

These substituents may be further substituted with the above-described substituents. Further, these substituents may be bonded together to form a ring.

With respect to y₁ to y₈ in Formula (I), it is preferable that at least three among y₁ to y₄, or at least three among y₅ to y₈ represent CR₁₀₂. More preferably, all of y₁ to y₈ represent CR₁₀₂. The structure having these features is excellent in a hole transport property and an electron transport property, and it can effectively recombine in the light emitting layer a hole and an electron injected from an anode and a cathode to result in emitting light.

In particular, it is preferable a compound having X₁₀₁ in Formula (I) of NR₁₀₁, an oxygen atom or a sulfur atom because it has a shallow LUMO energy level and excellent in an electron transport property. More preferably, a condensed ring formed with X₁₀₁ and y₁ to y₈ is a carbazole ring, an azacarbazole rig, a dibnezofuran ring, or an azadibnezofuran ring.

In view of the idea that the host compound is preferably an inflexible structure, when X₁₀₁ is NR₁₈₁, R₁₀₁ is preferably an aromatic hydrocarbon ring group or an aromatic heterocyclic ring group with n-conjugate structure among the above-described groups. Further, this R₁₀₁ may be further substituted with the substituents represented by the aforesaid R₁₀₁ to R₁₀₄.

In Formula (I), examples of an aromatic ring represented by Ar₁₀₁ or Ar₁₀₂ are an aromatic hydrocarbon ring and an aromatic heterocyclic ring. The aromatic ring may be a single ring or a condensed ring. Further, the aromatic ring may be unsubstituted or may have the same substituents represented by the aforesaid R₁₀₁ to R₁₀₄.

In the partial structure represented by Formula (I), as an aromatic heterocyclic ring represented by Ar₁₀₁ or Ar₁₀₂, it can cite the same aromatic heterocyclic rings cited as examples of the substituents represented by the aforesaid R₁₀₁ to R₁₀₄.

In view of the idea that the host compound represented by Formula (I) has a large T₁, an aromatic ring represented by Ar₁₀₁ or Ar₁₀₂ itself preferably has a high T₁. Preferable examples thereof are: a benzene ring (containing a polyphenylene structure formed with a plurality of bonded benzene rings such as biphenyl, terphenyl, and quaterphenyl), a fluorene ring, a triphenylene ring, a carbazole ring, an azacarbazole ring, a dibenzofuran ring, an azadibenzofuran ring, a dibenzothiophene ring, a dibenzothiophene ring, a pyridine ring, a pyrazine ring, an indoloindole ring, an indole ring, a benzofuran ring, a benzothiophene ring, an imidazole ring, and a triazine ring. More preferable examples thereof are: a benzene ring, a carbazole ring, an azacarbazole ring, and a dibenzofuran ring.

When Ar₁₀₁ and Ar₁₀₂ are a carbazole ring or an azacarbazole ring, it is preferable that these rings are bonded at an N position (it may be called as a position 9) or a position 3.

When Ar₁₀₁ and Ar₁₀₂ are a dibenzofuran ring, it is preferable that this ring is bonded at a position 2 or a position 4.

Apart from the above-described ideas, in view of the application of the organic EL element to an inside of a car, it is supposed that an inner temperature of a car will become high. Therefore, it is preferable that a host compound has a high Tg. In order to make a host compound represented by Formula (I) to have a high Tg, a preferable embodiment of an aromatic ring represented by Ar₁₀₁ and Ar₁₀₂ is to have respectively a condensed ring having 3 or more rings.

Examples of a condensed aromatic hydrocarbon ring having 3 or more rings are: a naphthacene, an anthracene, a tetracene ring, a pentacene ring, a hexacene ring a phenanthrene ring, a pyrene ring, a benzopyrene ring a benzoazulene ring, chrysene ring, benzochrysene ring, an acenaphthene ring, an acenaphthylene ring, a triphenylene ring, a coronene ring, a benzocoronene ring, a hexabenzocorone ring, a fluorene ring, a benzofluorene ring, a fluoranthene ring, a perylene ring, a naphthoperylene ring, a pentabenzoperylene ring, a benzoperylene ring, pentaphene ring, a picene ring, a pyranthrene ring, a coronene ring, a naphthocoronene ring, an ovalene ring, an anthraanthrene ring. In addition, these rings may further have a substituent.

Examples of a condensed aromatic heterocyclic ring having 3 or more rings are: an acridine ring, a benzoquinoline ring, a carbazole ring, a carboline ring, a phenazine ring, a phenanthridine ring, a phenanthroline ring, a carboline ring, a cycladine ring, a quindoline ring, a thepenidine ring, a quinindoline ring, triphenodithiazine ring, a triphenodioxazine ring, a phenanthrazine ring, an anthrazine ring, a perimizine ring, a diazacarbazole ring (indicating a ring structure in which one of the carbon atoms constituting the carboline ring is replaced with a nitrogen atom), a phenanthroline ring, a dibenzofuran ring, a dibenzothiophene ring, a naphthofuran ring, a naphthothiophene ring, a benzodifuran ring, a benzodithiophene ring, a naphthodifuran ring, a naphthodithiophene ring, an anthrafuran ring, an anthradifuran ring, an anthrathiophene ring, an anthradithiophene ring, a thianthrene ring, a phenoxathiine ring, and a thiophanthrene ring (a naphthothiophene ring). These rings may further have a substituent.

In Formula (I), n101 and n102 each are preferably an integer of 0 to 2. More preferably, a sum of n101 and n102 is an integer of 1 to 3. When R₁₀₁ is a hydrogen atom, and when n101 and n102 are simultaneously 0, a host compound represented by Formula (I) has a low molecular weight, and it can achieve only a low Tg. Therefore, when R₁₀₁ is a hydrogen atom, n101 represents an integer of 1 to 4.

In the present invention, particularly preferable is a host compound having both a dibenzofuran ring and a carbazole ring.

As a has compound according to the present invention, a carbazole derivative is preferably a compound having a structure represented by Formula (II). The reason of this is that this compound likely has excellent carrier transport ability.

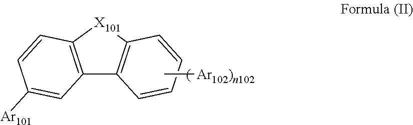

In Formula (II), X₁₀₁, Ar₁₀₁, Ar₁₀₂ and n102 each are synonymous with X₁₀₁, Ar₁₀₁, Ar₁₀₂ and n102 in Formula (I). n102 is preferably an integer of 0 to 2, and more preferably an integer of 0 or 1.

In Formula (II), a condensed ring formed with X₁₀₁ may have a substituent other than Ar₁₀₁ and Ar₁₀₂ with a condition that the substituent does not deteriorate the function of the host compound of the present invention.

Further, the compound represented by Formula (II) is preferably represented by any one of Formulas (III-1), (III-2) and (III-3).

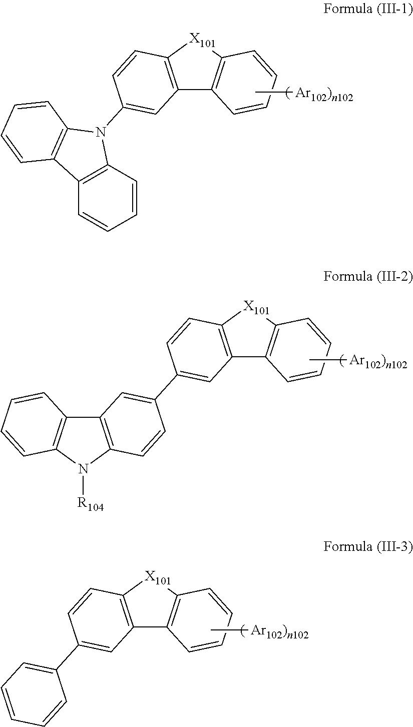

In Formulas (III-1) to (III-3), X₁₀₁, Ar₁₀₂, and n102 each are synonymous with X₁₀₁, Ar₁₀₂ and n102 in Formula (II).

In Formulas (III-1) to (III-3), a condensed ring, a carbazole ring and a benzene ring each are formed by including X₁₀₁ may be further substituted with a substituent with a condition that the substituent does not deteriorate the function of the host compound of the present invention.

Examples of compounds represented by Formulas (I), (II), and (III-1) to (III-3), which are used as a host compound of the present invention, and other compounds are indicated in the following. However, the present invention is not limited to them.

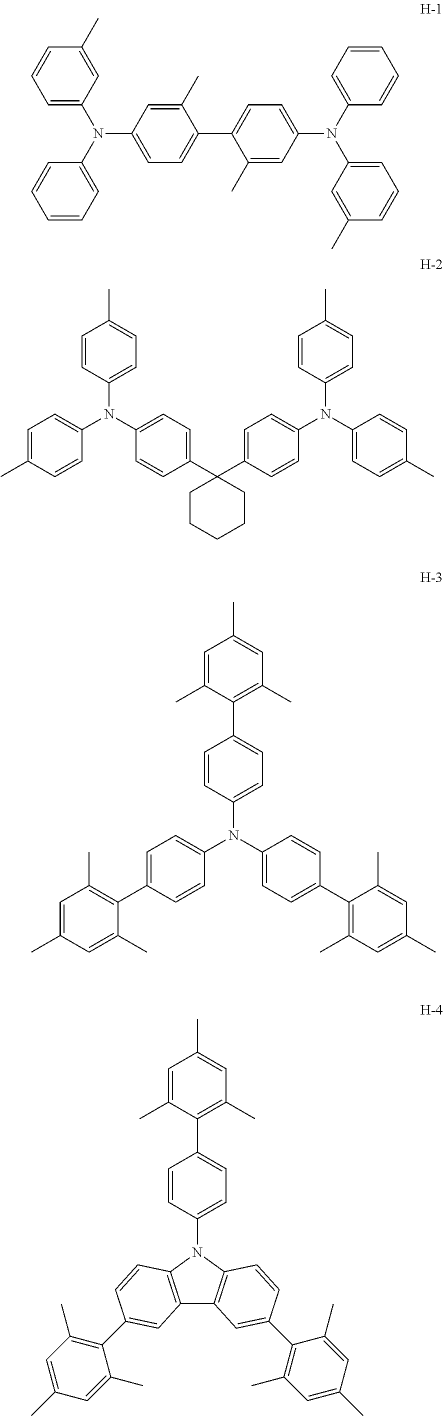

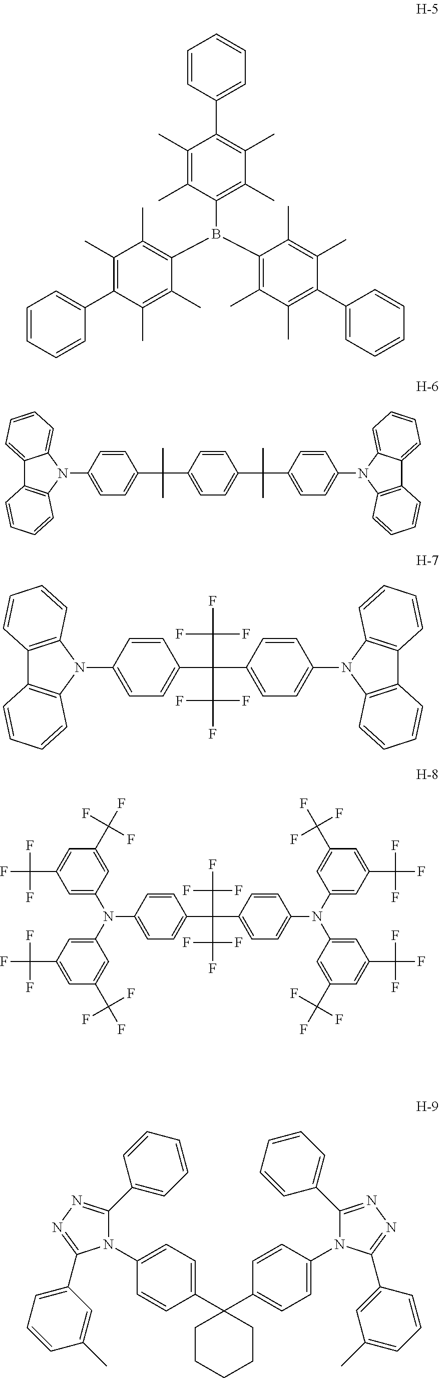

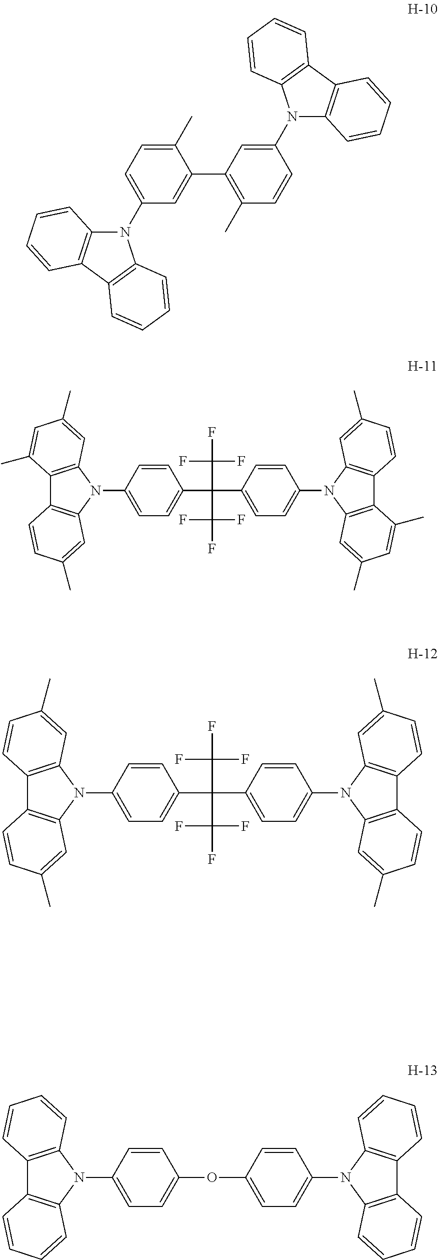

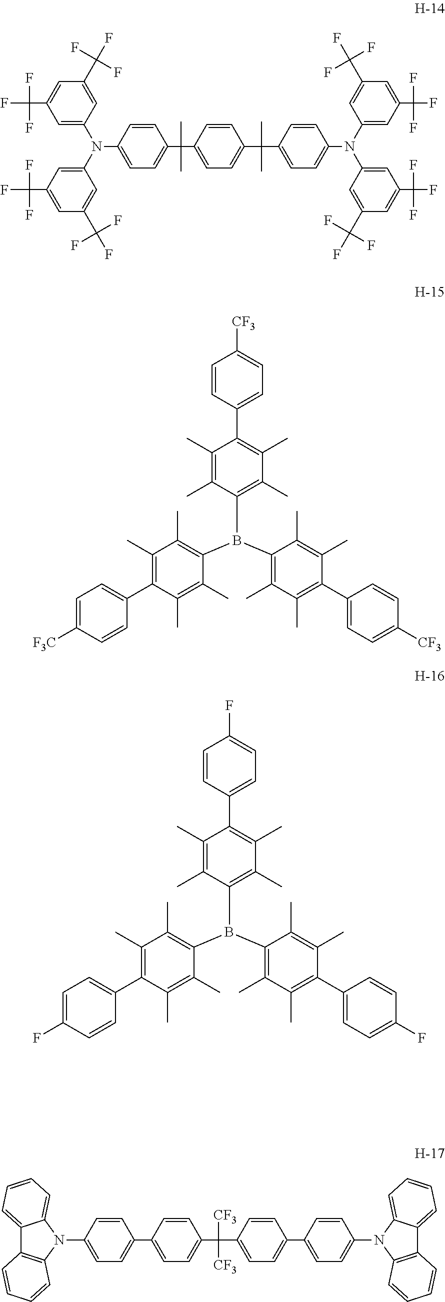 [SMILES: CC(C)(c1ccc(N(c2cc(C(F)(F)F)cc(C(F)(F)F)c2)c2cc(C(F)(F)F)cc(C(F)(F)F)c2)cc1)c1ccc(C(C)(C)c2ccc(N(c3cc(C(F)(F)F)cc(C(F)(F)F)c3)c3cc(C(F)(F)F)cc(C(F)(F)F)c3)cc2)cc1 ; Cc1c(C)c(-c2ccc(C(F)(F)F)cc2)c(C)c(C)c1B(c1c(C)c(C)c(-c2ccc(C(F)(F)F)cc2)c(C)c1C)c1c(C)c(C)c(-c2ccc(C(F)(F)F)cc2)c(C)c1C ; Cc1c(C)c(-c2ccc(F)cc2)c(C)c(C)c1B(c1c(C)c(C)c(-c2ccc(F)cc2)c(C)c1C)c1c(C)c(C)c(-c2ccc(F)cc2)c(C)c1C ; FC(F)(F)C(c1ccc(-c2ccc(-n3c4ccccc4c4ccccc43)cc2)cc1)(c1ccc(-c2ccc(-n3c4ccccc4c4ccccc43)cc2)cc1)C(F)(F)F]

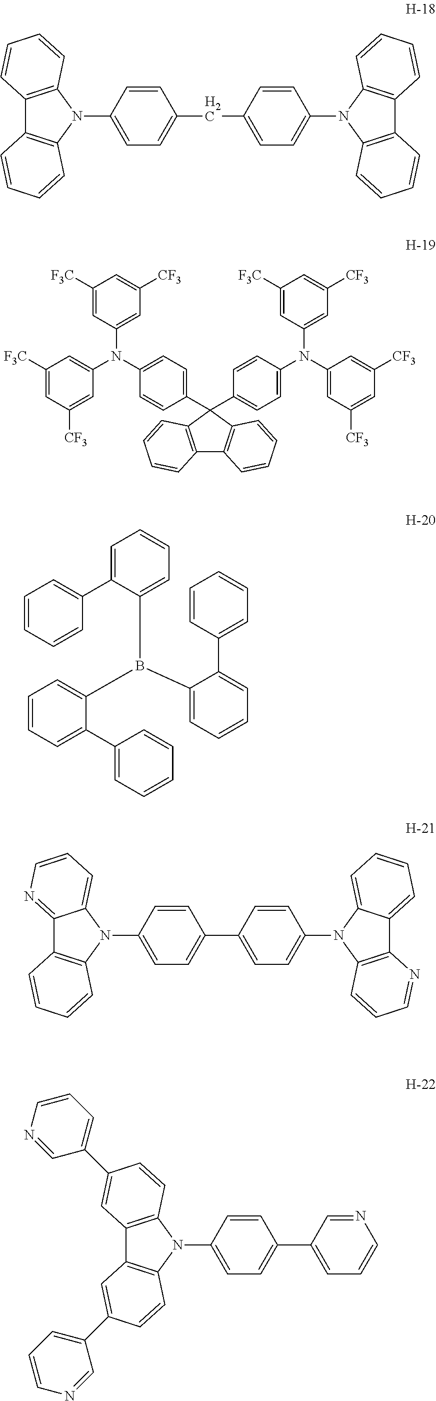 [SMILES: c1ccc2c(c1)c1ccccc1n2-c1ccc(Cc2ccc(-n3c4ccccc4c4ccccc43)cc2)cc1 ; FC(F)(F)c1cc(N(c2ccc(C3(c4ccc(N(c5cc(C(F)(F)F)cc(C(F)(F)F)c5)c5cc(C(F)(F)F)cc(C(F)(F)F)c5)cc4)c4ccccc4-c4ccccc43)cc2)c2cc(C(F)(F)F)cc(C(F)(F)F)c2)cc(C(F)(F)F)c1 ; c1ccc(-c2ccccc2B(c2ccccc2-c2ccccc2)c2ccccc2-c2ccccc2)cc1 ; c1ccc2c(c1)c1ncccc1n2-c1ccc(-c2ccc(-n3c4ccccc4c4ncccc43)cc2)cc1 ; c1cncc(-c2ccc(-n3c4ccc(-c5cccnc5)cc4c4cc(-c5cccnc5)ccc43)cc2)c1]

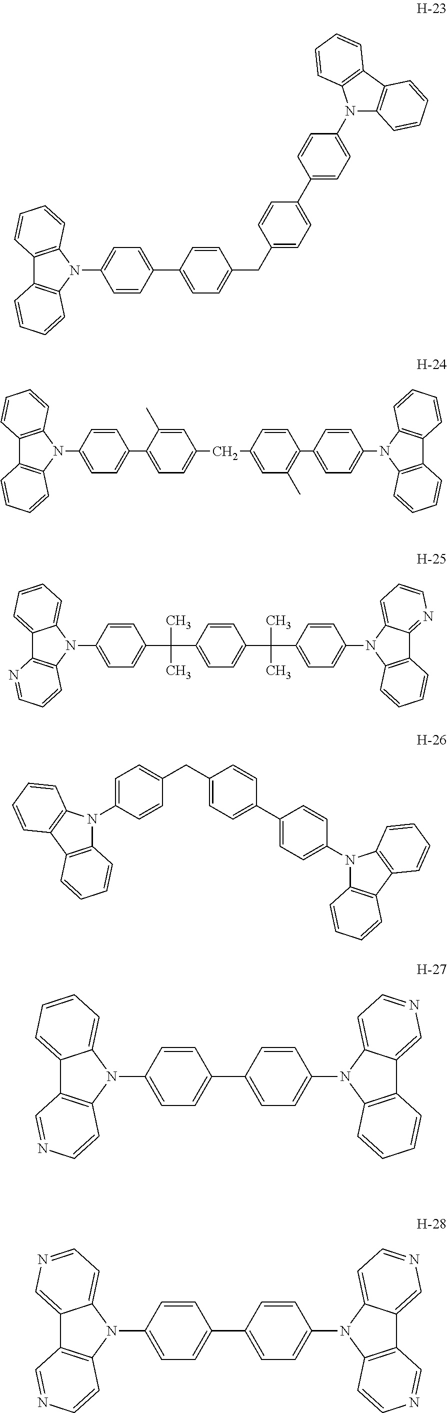 [SMILES: c1ccc2c(c1)c1ccccc1n2-c1ccc(-c2ccc(Cc3ccc(-c4ccc(-n5c6ccccc6c6ccccc65)cc4)cc3)cc2)cc1 ; Cc1cc(Cc2ccc(-c3ccc(-n4c5ccccc5c5ccccc54)cc3)c(C)c2)ccc1-c1ccc(-n2c3ccccc3c3ccccc32)cc1 ; CC(C)(c1ccc(-n2c3ccccc3c3ncccc32)cc1)c1ccc(C(C)(C)c2ccc(-n3c4ccccc4c4ncccc43)cc2)cc1 ; c1ccc2c(c1)c1ccccc1n2-c1ccc(Cc2ccc(-c3ccc(-n4c5ccccc5c5ccccc54)cc3)cc2)cc1 ; c1ccc2c(c1)c1cnccc1n2-c1ccc(-c2ccc(-n3c4ccccc4c4cnccc43)cc2)cc1 ; c1cc2c(cn1)c1cnccc1n2-c1ccc(-c2ccc(-n3c4ccncc4c4cnccc43)cc2)cc1]

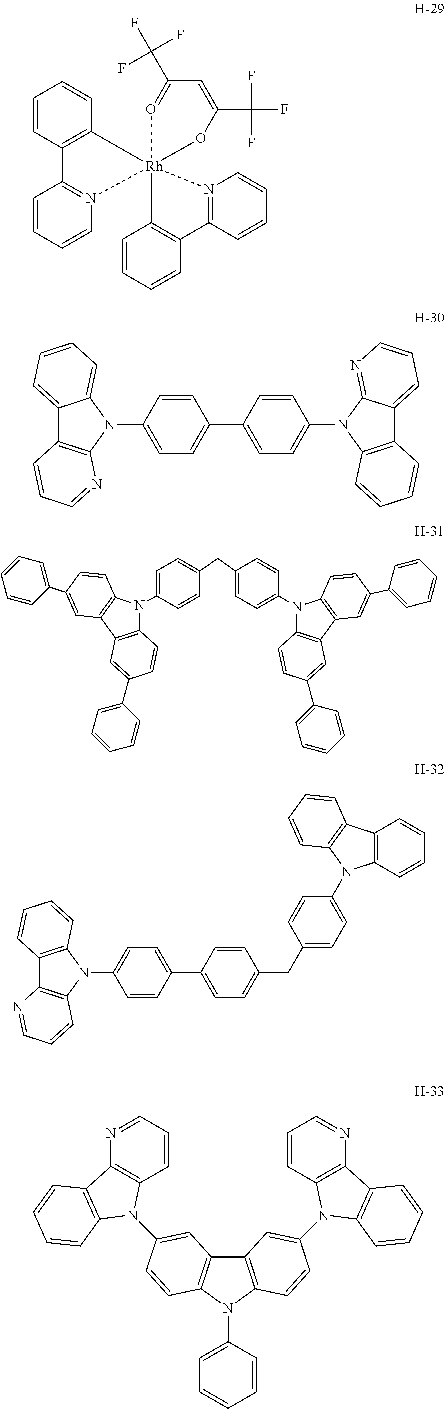

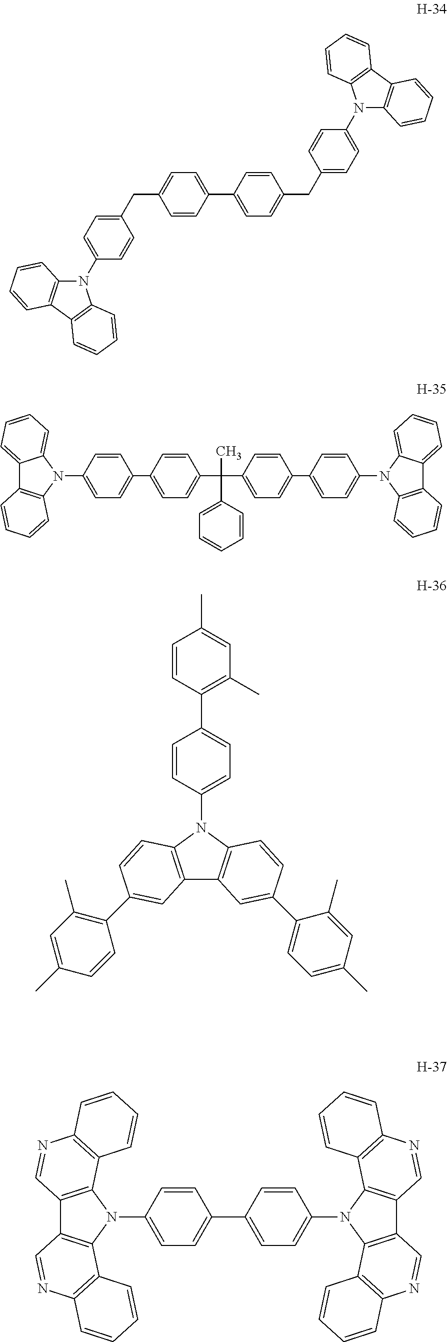

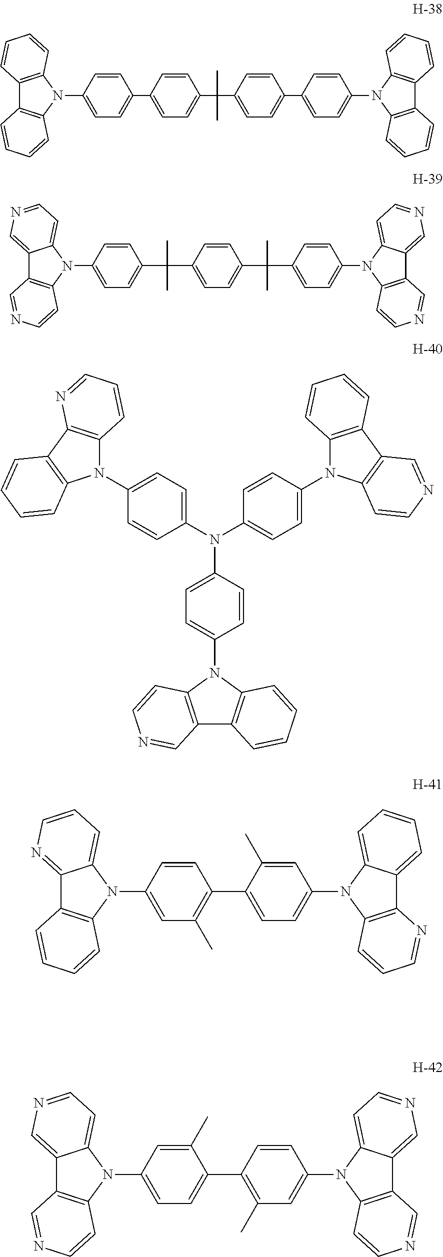 [SMILES: CC(C)(c1ccc(-c2ccc(-n3c4ccccc4c4ccccc43)cc2)cc1)c1ccc(-c2ccc(-n3c4ccccc4c4ccccc43)cc2)cc1 ; CC(C)(c1ccc(-n2c3ccncc3c3cnccc32)cc1)c1ccc(C(C)(C)c2ccc(-n3c4ccncc4c4cnccc43)cc2)cc1 ; c1ccc2c(c1)c1cnccc1n2-c1ccc(N(c2ccc(-n3c4ccccc4c4cnccc43)cc2)c2ccc(-n3c4ccccc4c4ncccc43)cc2)cc1 ; Cc1cc(-n2c3ccccc3c3ncccc32)ccc1-c1ccc(-n2c3ccccc3c3ncccc32)cc1C ; Cc1cc(-n2c3ccncc3c3cnccc32)ccc1-c1ccc(-n2c3ccncc3c3cnccc32)cc1C]

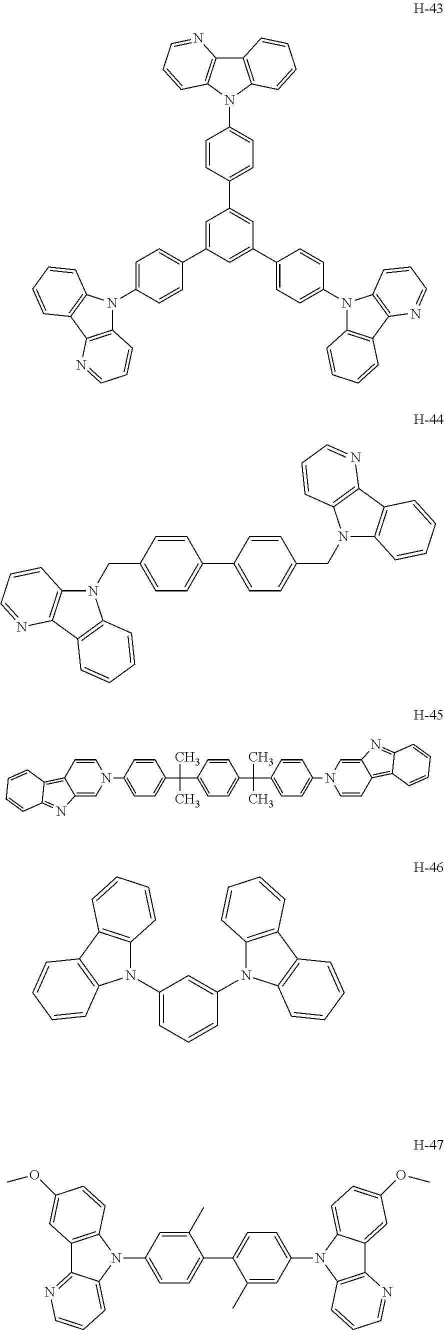

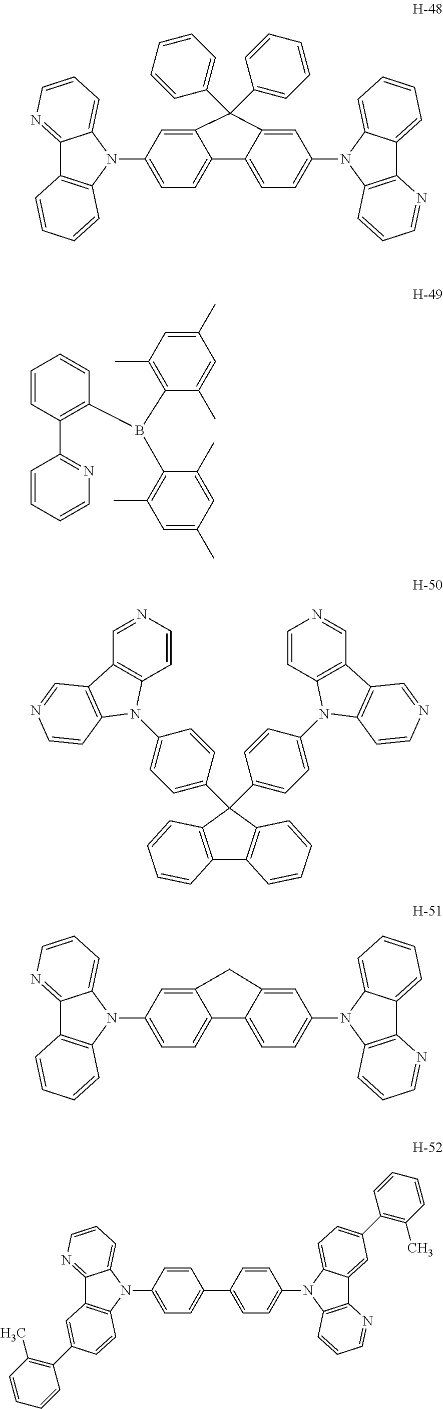 [SMILES: c1ccc(C2(c3ccccc3)c3cc(-n4c5ccccc5c5ncccc54)ccc3-c3ccc(-n4c5ccccc5c5ncccc54)cc32)cc1 ; Cc1cc(C)c(B(c2ccccc2-c2ccccn2)c2c(C)cc(C)cc2C)c(C)c1 ; c1ccc2c(c1)-c1ccccc1C2(c1ccc(-n2c3ccncc3c3cnccc32)cc1)c1ccc(-n2c3ccncc3c3cnccc32)cc1 ; c1ccc2c(c1)c1ncccc1n2-c1ccc2c(c1)Cc1cc(-n3c4ccccc4c4ncccc43)ccc1-2 ; Cc1ccccc1-c1ccc2c(c1)c1ncccc1n2-c1ccc(-c2ccc(-n3c4ccc(-c5ccccc5C)cc4c4ncccc43)cc2)cc1]

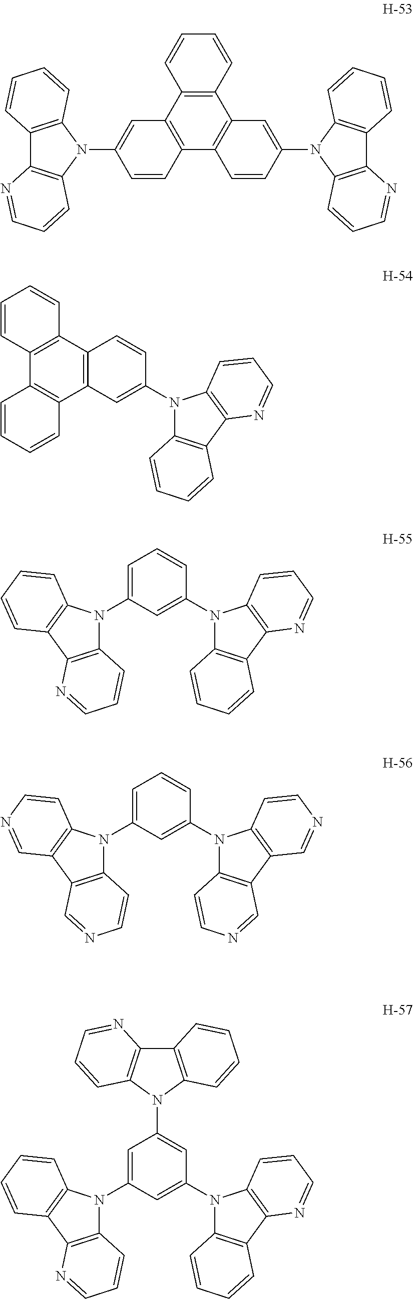 [SMILES: c1ccc2c(c1)c1cc(-n3c4ccccc4c4ncccc43)ccc1c1ccc(-n3c4ccccc4c4ncccc43)cc21 ; c1ccc2c(c1)c1ccccc1c1cc(-n3c4ccccc4c4ncccc43)ccc21 ; c1cc(-n2c3ccccc3c3ncccc32)cc(-n2c3ccccc3c3ncccc32)c1 ; c1cc(-n2c3ccncc3c3cnccc32)cc(-n2c3ccncc3c3cnccc32)c1 ; c1ccc2c(c1)c1ncccc1n2-c1cc(-n2c3ccccc3c3ncccc32)cc(-n2c3ccccc3c3ncccc32)c1]

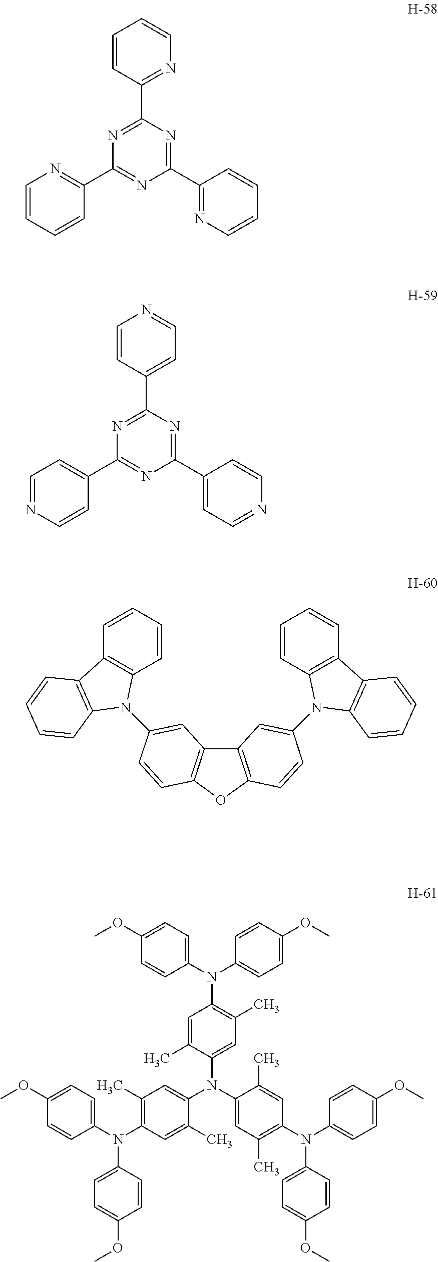

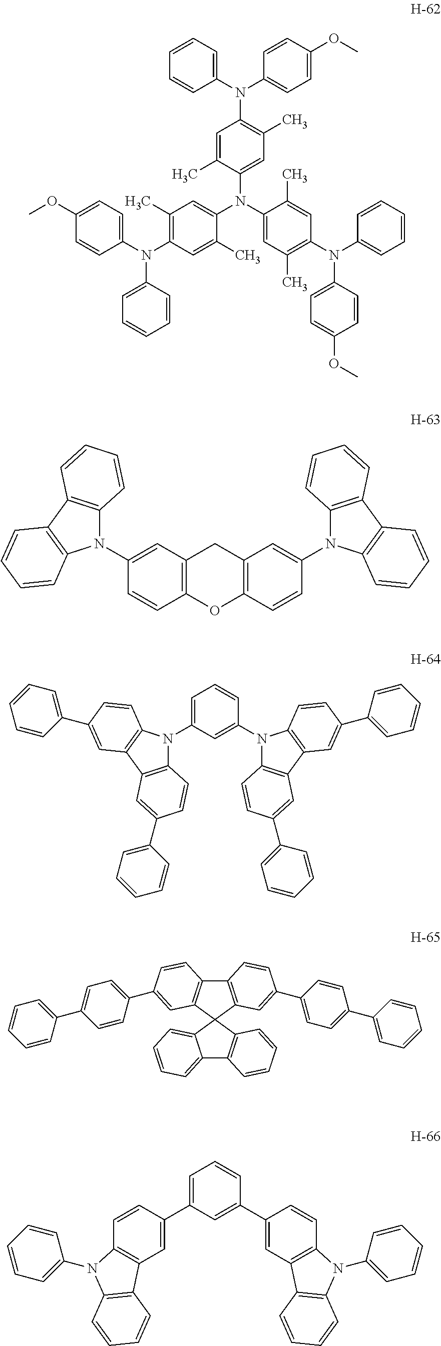

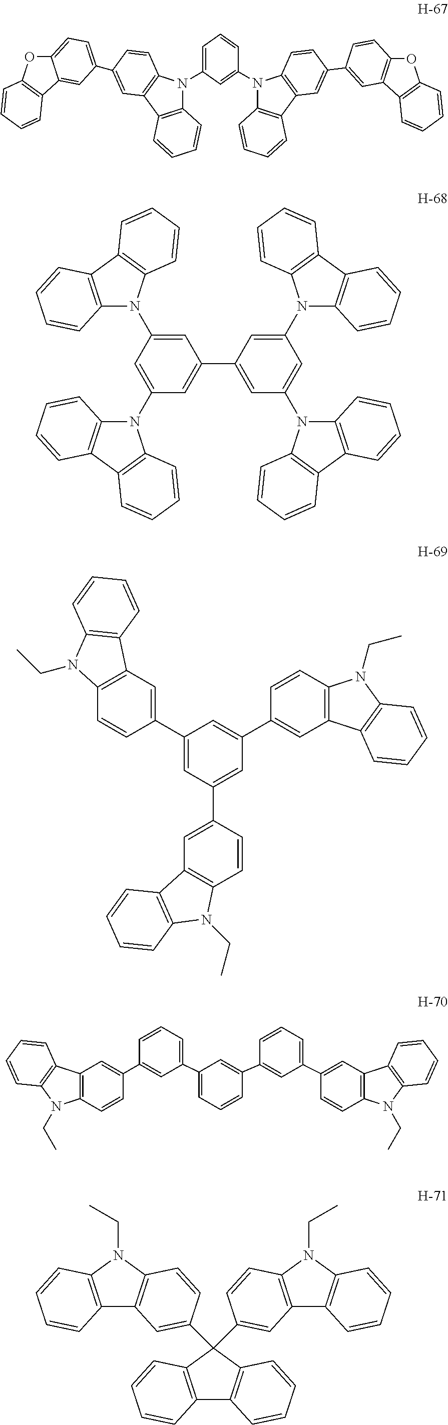 [SMILES: c1cc(-n2c3ccccc3c3cc(-c4ccc5oc6ccccc6c5c4)ccc32)cc(-n2c3ccccc3c3cc(-c4ccc5oc6ccccc6c5c4)ccc32)c1 ; c1ccc2c(c1)c1ccccc1n2-c1cc(-c2cc(-n3c4ccccc4c4ccccc43)cc(-n3c4ccccc4c4ccccc43)c2)cc(-n2c3ccccc3c3ccccc32)c1 ; CCn1c2ccccc2c2cc(-c3cc(-c4ccc5c(c4)c4ccccc4n5CC)cc(-c4ccc5c(c4)c4ccccc4n5CC)c3)ccc21 ; CCn1c2ccccc2c2cc(-c3cccc(-c4cccc(-c5cccc(-c6ccc7c(c6)c6ccccc6n7CC)c5)c4)c3)ccc21 ; CCn1c2ccccc2c2cc(C3(c4ccc5c(c4)c4ccccc4n5CC)c4ccccc4-c4ccccc43)ccc21]

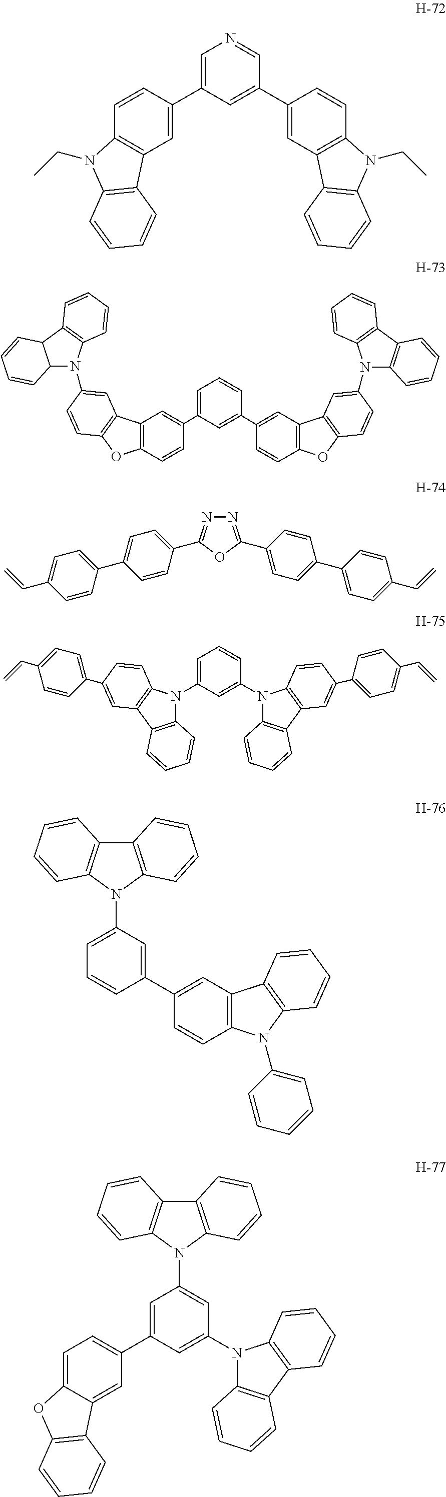

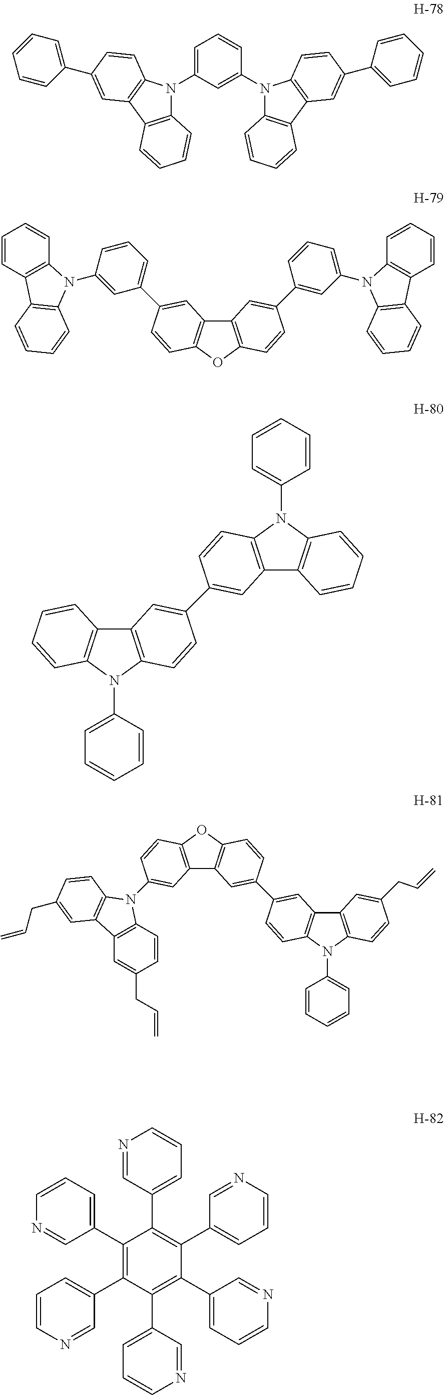 [SMILES: c1ccc(-c2ccc3c(c2)c2ccccc2n3-c2cccc(-n3c4ccccc4c4cc(-c5ccccc5)ccc43)c2)cc1 ; c1cc(-c2ccc3oc4ccc(-c5cccc(-n6c7ccccc7c7ccccc76)c5)cc4c3c2)cc(-n2c3ccccc3c3ccccc32)c1 ; c1ccc(-n2c3ccccc3c3cc(-c4ccc5c(c4)c4ccccc4n5-c4ccccc4)ccc32)cc1 ; C=CCc1ccc2c(c1)c1cc(CC=C)ccc1n2-c1ccc2oc3ccc(-c4ccc5c(c4)c4cc(CC=C)ccc4n5-c4ccccc4)cc3c2c1 ; c1cncc(-c2c(-c3cccnc3)c(-c3cccnc3)c(-c3cccnc3)c(-c3cccnc3)c2-c2cccnc2)c1]

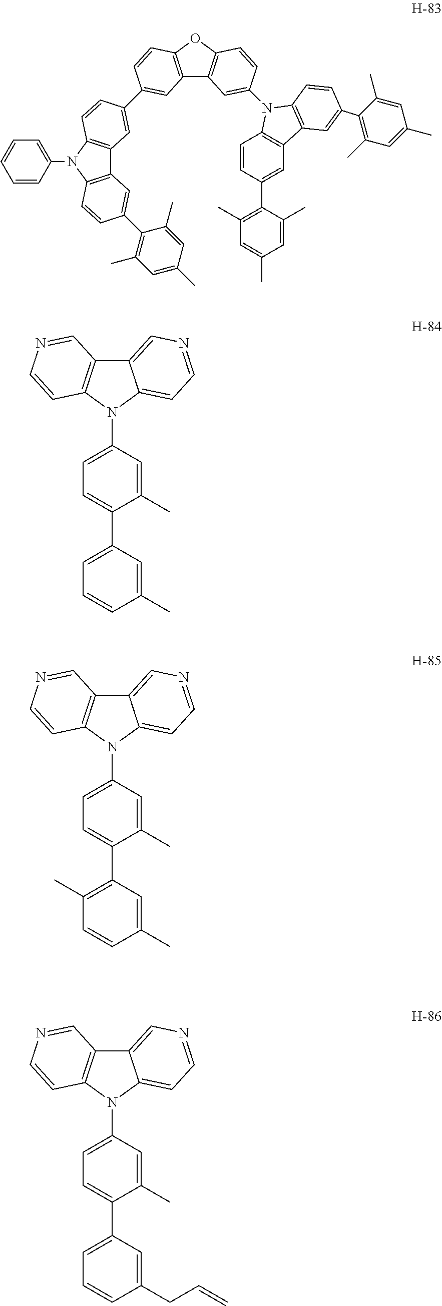 [SMILES: Cc1cc(C)c(-c2ccc3c(c2)c2cc(-c4ccc5oc6ccc(-n7c8ccc(-c9c(C)cc(C)cc9C)cc8c8cc(-c9c(C)cc(C)cc9C)ccc87)cc6c5c4)ccc2n3-c2ccccc2)c(C)c1 ; Cc1cccc(-c2ccc(-n3c4ccncc4c4cnccc43)cc2C)c1 ; Cc1ccc(C)c(-c2ccc(-n3c4ccncc4c4cnccc43)cc2C)c1 ; C=CCc1cccc(-c2ccc(-n3c4ccncc4c4cnccc43)cc2C)c1]

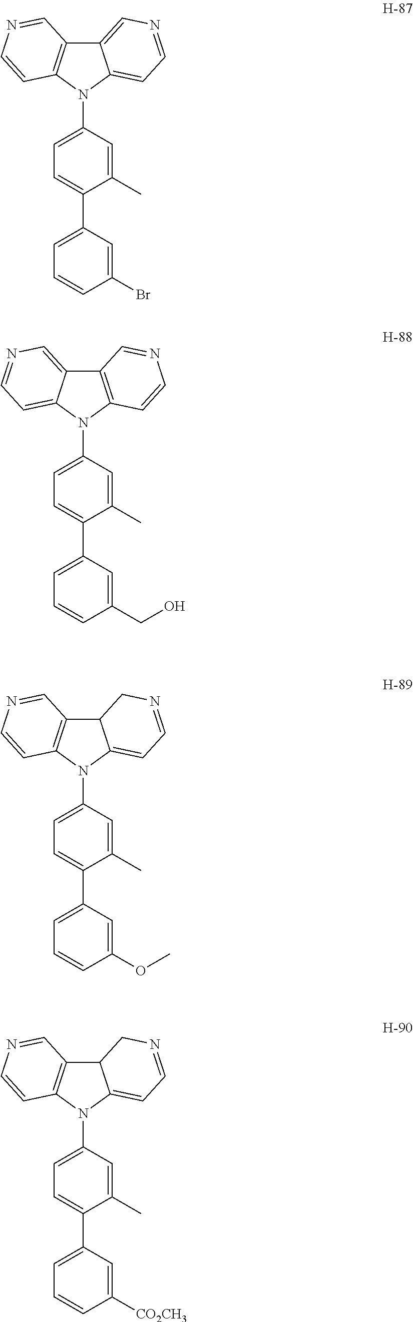 [SMILES: Cc1cc(-n2c3ccncc3c3cnccc32)ccc1-c1cccc(Br)c1 ; Cc1cc(-n2c3ccncc3c3cnccc32)ccc1-c1cccc(CO)c1 ; COc1cccc(-c2ccc(N3C4=CC=NCC4c4cnccc43)cc2C)c1 ; COC(=O)c1cccc(-c2ccc(N3C4=CC=NCC4c4cnccc43)cc2C)c1]

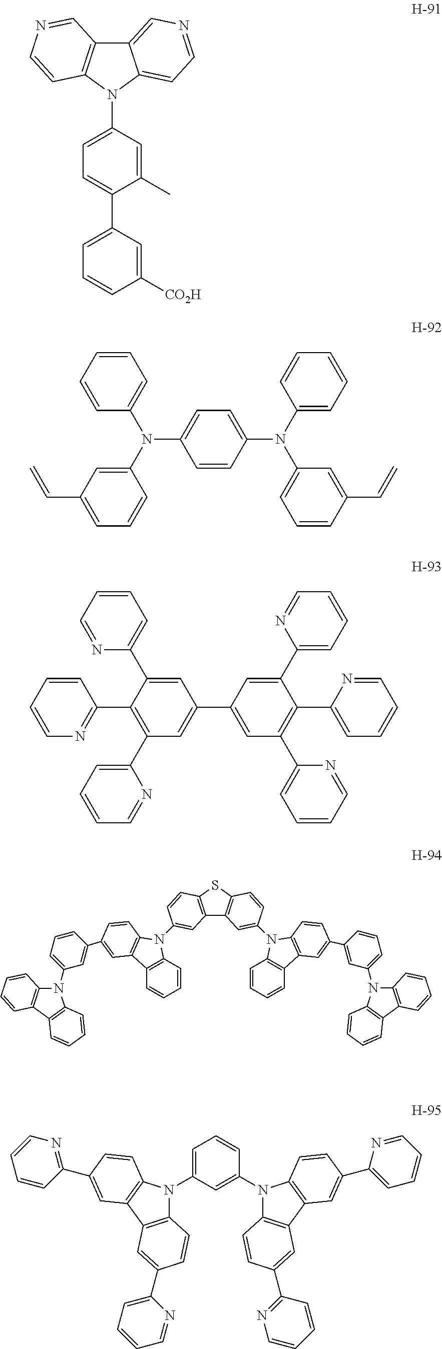 [SMILES: Cc1cc(-n2c3ccncc3c3cnccc32)ccc1-c1cccc(C(=O)O)c1 ; C=Cc1cccc(N(c2ccccc2)c2ccc(N(c3ccccc3)c3cccc(C=C)c3)cc2)c1 ; c1ccc(-c2cc(-c3cc(-c4ccccn4)c(-c4ccccn4)c(-c4ccccn4)c3)cc(-c3ccccn3)c2-c2ccccn2)nc1 ; c1cc(-c2ccc3c(c2)c2ccccc2n3-c2ccc3sc4ccc(-n5c6ccccc6c6cc(-c7cccc(-n8c9ccccc9c9ccccc98)c7)ccc65)cc4c3c2)cc(-n2c3ccccc3c3ccccc32)c1 ; c1ccc(-c2ccc3c(c2)c2cc(-c4ccccn4)ccc2n3-c2cccc(-n3c4ccc(-c5ccccn5)cc4c4cc(-c5ccccn5)ccc43)c2)nc1]

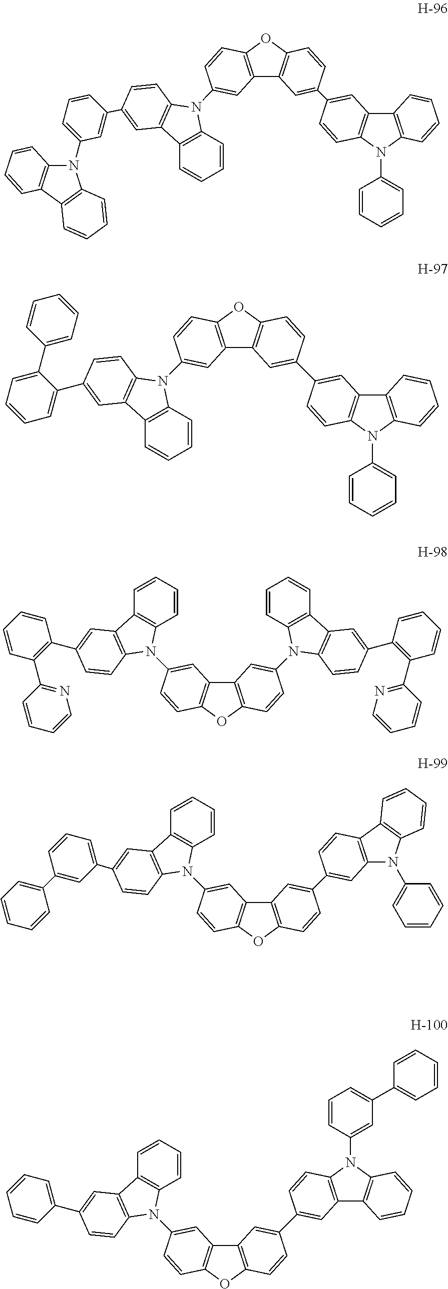

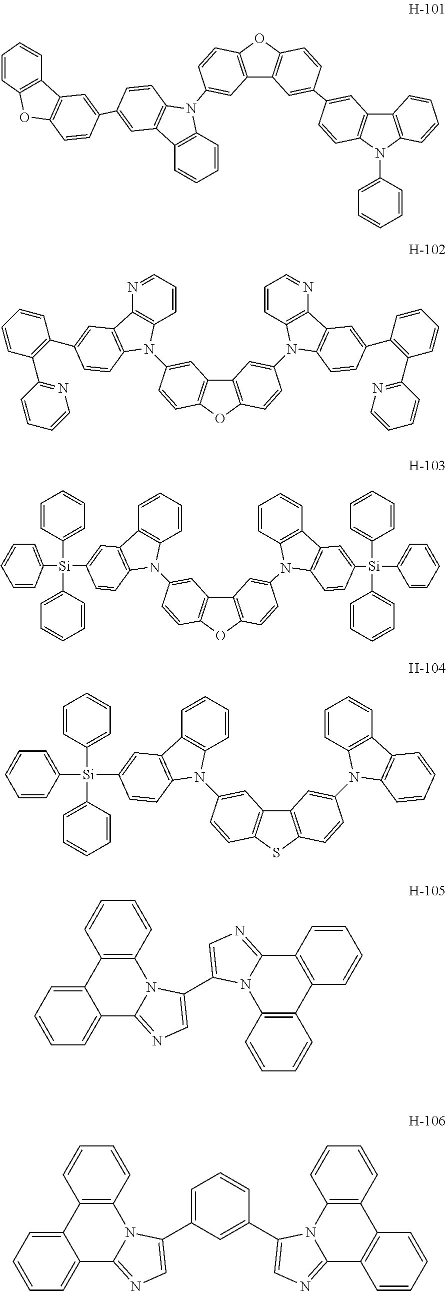

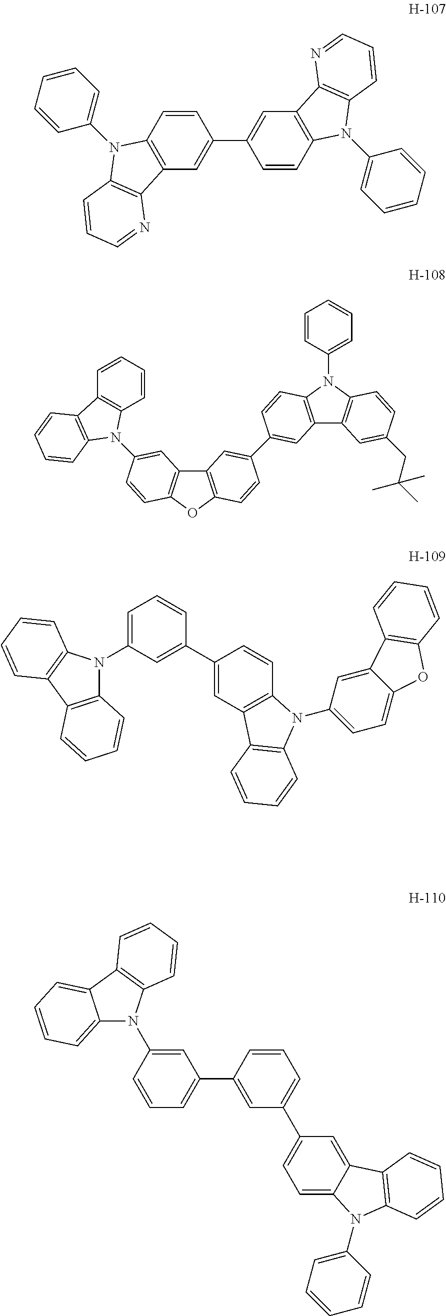 [SMILES: c1ccc(-n2c3ccc(-c4ccc5c(c4)c4ncccc4n5-c4ccccc4)cc3c3ncccc32)cc1 ; CC(C)(C)Cc1ccc2c(c1)c1cc(-c3ccc4oc5ccc(-n6c7ccccc7c7ccccc76)cc5c4c3)ccc1n2-c1ccccc1 ; c1cc(-c2ccc3c(c2)c2ccccc2n3-c2ccc3oc4ccccc4c3c2)cc(-n2c3ccccc3c3ccccc32)c1 ; c1ccc(-n2c3ccccc3c3cc(-c4cccc(-c5cccc(-n6c7ccccc7c7ccccc76)c5)c4)ccc32)cc1]

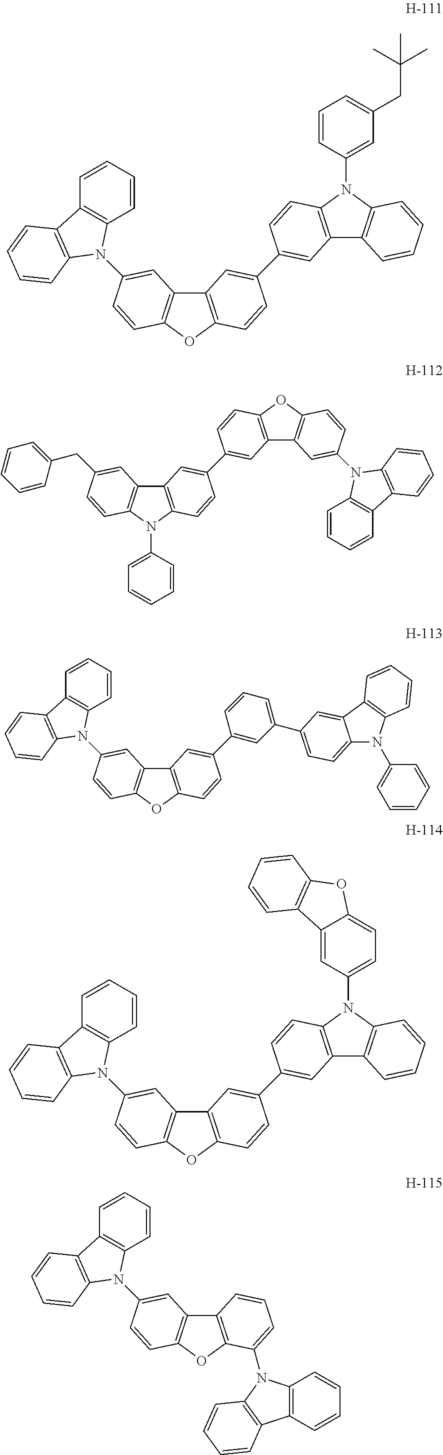 [SMILES: CC(C)(C)Cc1cccc(-n2c3ccccc3c3cc(-c4ccc5oc6ccc(-n7c8ccccc8c8ccccc87)cc6c5c4)ccc32)c1 ; c1ccc(Cc2ccc3c(c2)c2cc(-c4ccc5oc6ccc(-n7c8ccccc8c8ccccc87)cc6c5c4)ccc2n3-c2ccccc2)cc1 ; c1ccc(-n2c3ccccc3c3cc(-c4cccc(-c5ccc6oc7ccc(-n8c9ccccc9c9ccccc98)cc7c6c5)c4)ccc32)cc1 ; c1ccc2c(c1)oc1ccc(-n3c4ccccc4c4cc(-c5ccc6oc7ccc(-n8c9ccccc9c9ccccc98)cc7c6c5)ccc43)cc12 ; c1cc(-n2c3ccccc3c3ccccc32)c2oc3ccc(-n4c5ccccc5c5ccccc54)cc3c2c1]

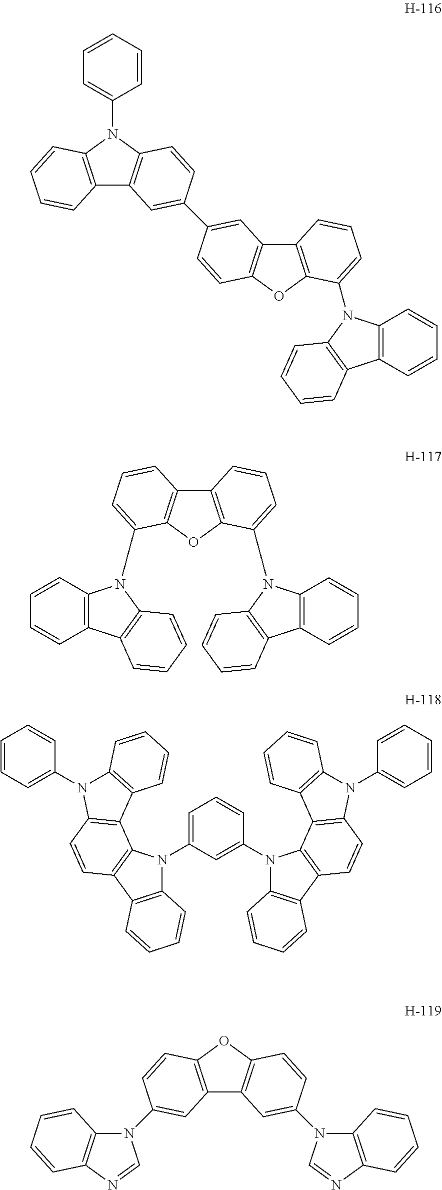 [SMILES: c1ccc(-n2c3ccccc3c3cc(-c4ccc5oc6c(-n7c8ccccc8c8ccccc87)cccc6c5c4)ccc32)cc1 ; c1cc(-n2c3ccccc3c3ccccc32)c2oc3c(-n4c5ccccc5c5ccccc54)cccc3c2c1 ; c1ccc(-n2c3ccccc3c3c2ccc2c4ccccc4n(-c4cccc(-n5c6ccccc6c6ccc7c(c8ccccc8n7-c7ccccc7)c65)c4)c23)cc1 ; c1ccc2c(c1)ncn2-c1ccc2oc3ccc(-n4cnc5ccccc54)cc3c2c1]

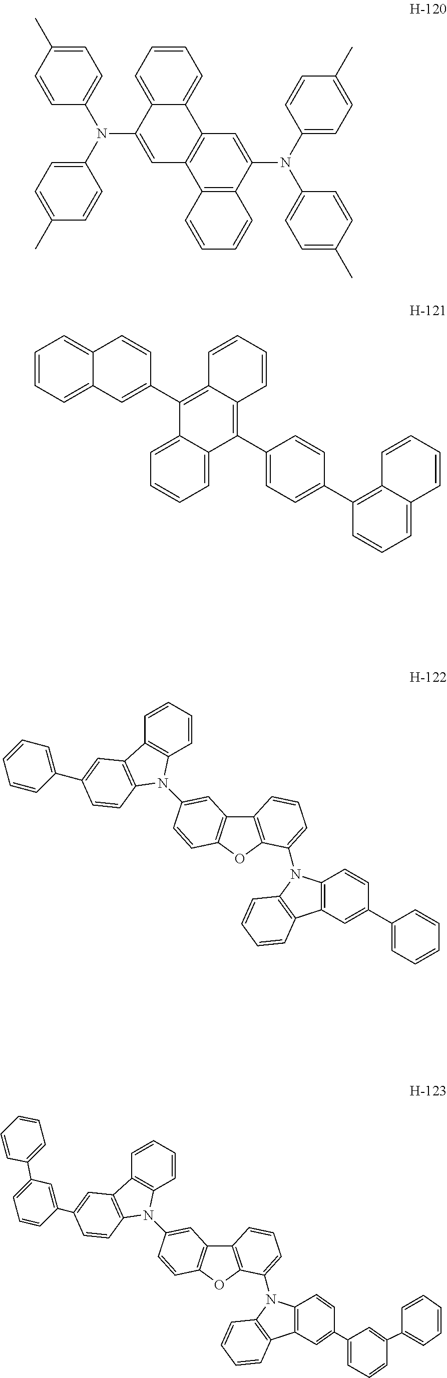

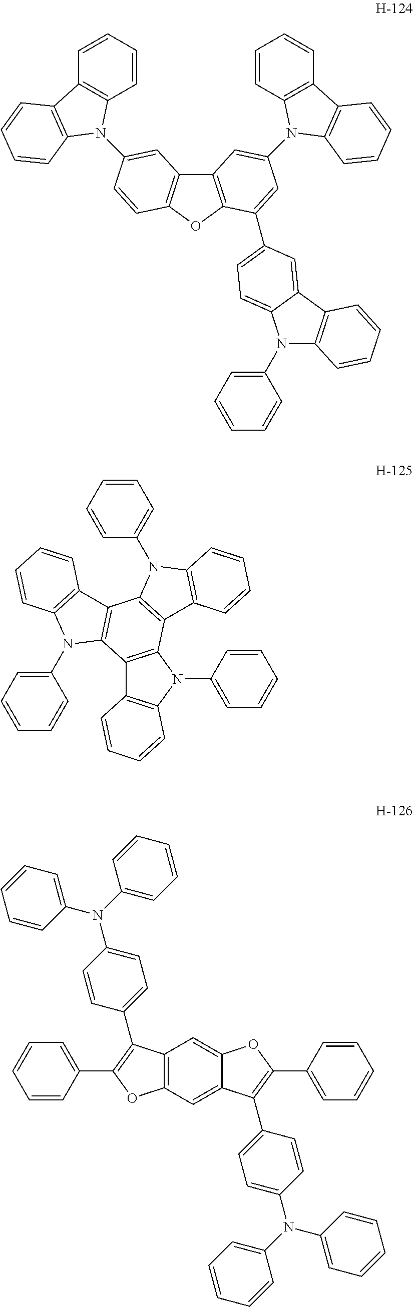 [SMILES: c1ccc(-n2c3ccccc3c3cc(-c4cc(-n5c6ccccc6c6ccccc65)cc5c4oc4ccc(-n6c7ccccc7c7ccccc76)cc45)ccc32)cc1 ; c1ccc(-n2c3ccccc3c3c2c2c4ccccc4n(-c4ccccc4)c2c2c4ccccc4n(-c4ccccc4)c32)cc1 ; c1ccc(-c2oc3cc4c(-c5ccc(N(c6ccccc6)c6ccccc6)cc5)c(-c5ccccc5)oc4cc3c2-c2ccc(N(c3ccccc3)c3ccccc3)cc2)cc1]

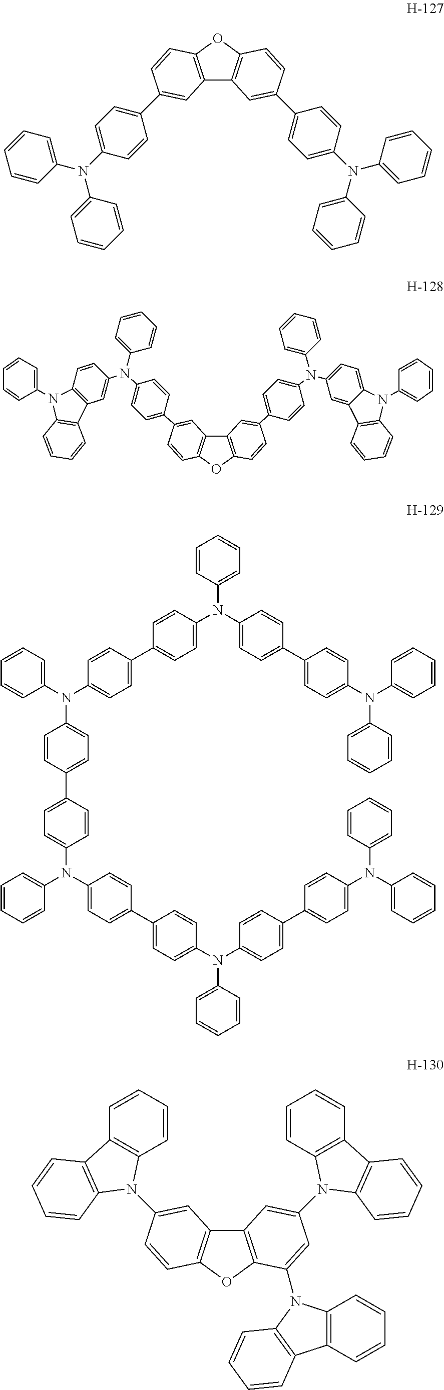

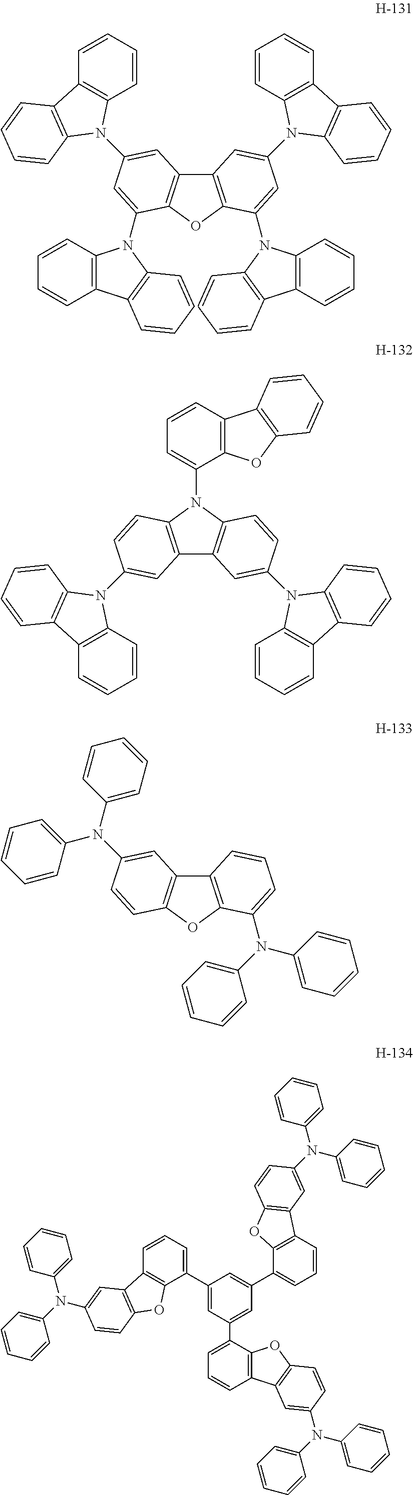

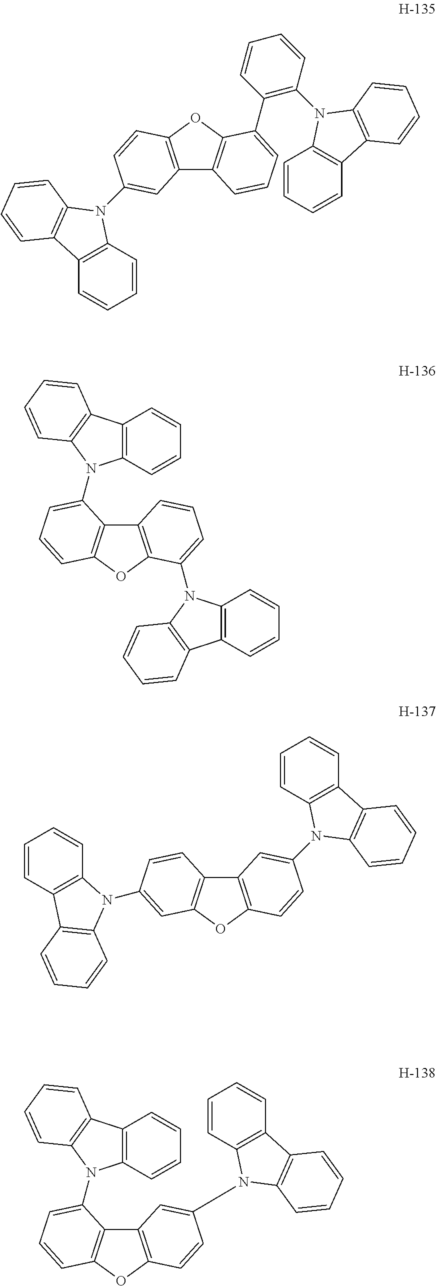 [SMILES: c1ccc(-n2c3ccccc3c3ccccc32)c(-c2cccc3c2oc2ccc(-n4c5ccccc5c5ccccc54)cc23)c1 ; c1cc(-n2c3ccccc3c3ccccc32)c2c(c1)oc1c(-n3c4ccccc4c4ccccc43)cccc12 ; c1ccc2c(c1)c1ccccc1n2-c1ccc2c(c1)oc1ccc(-n3c4ccccc4c4ccccc43)cc12 ; c1cc(-n2c3ccccc3c3ccccc32)c2c(c1)oc1ccc(-n3c4ccccc4c4ccccc43)cc12]

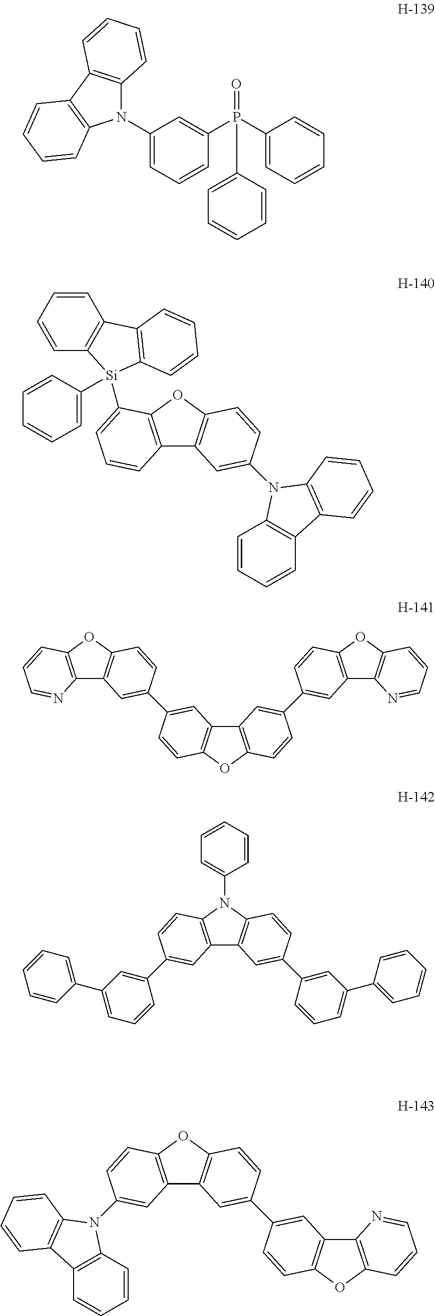 [SMILES: O=P(c1ccccc1)(c1ccccc1)c1cccc(-n2c3ccccc3c3ccccc32)c1 ; c1ccc([Si]2(c3cccc4c3oc3ccc(-n5c6ccccc6c6ccccc65)cc34)c3ccccc3-c3ccccc32)cc1 ; c1cnc2c(c1)oc1ccc(-c3ccc4oc5ccc(-c6ccc7oc8cccnc8c7c6)cc5c4c3)cc12 ; c1ccc(-c2cccc(-c3ccc4c(c3)c3cc(-c5cccc(-c6ccccc6)c5)ccc3n4-c3ccccc3)c2)cc1 ; c1cnc2c(c1)oc1ccc(-c3ccc4oc5ccc(-n6c7ccccc7c7ccccc76)cc5c4c3)cc12]

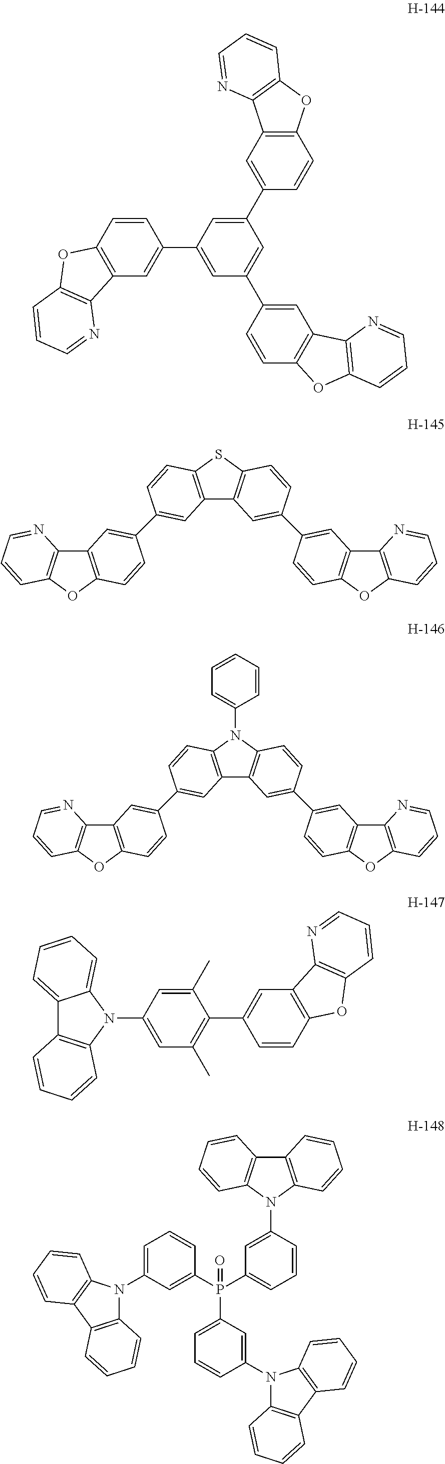 [SMILES: c1cnc2c(c1)oc1ccc(-c3cc(-c4ccc5oc6cccnc6c5c4)cc(-c4ccc5oc6cccnc6c5c4)c3)cc12 ; c1cnc2c(c1)oc1ccc(-c3ccc4sc5ccc(-c6ccc7oc8cccnc8c7c6)cc5c4c3)cc12 ; c1ccc(-n2c3ccc(-c4ccc5oc6cccnc6c5c4)cc3c3cc(-c4ccc5oc6cccnc6c5c4)ccc32)cc1 ; Cc1cc(-n2c3ccccc3c3ccccc32)cc(C)c1-c1ccc2oc3cccnc3c2c1 ; O=P(c1cccc(-n2c3ccccc3c3ccccc32)c1)(c1cccc(-n2c3ccccc3c3ccccc32)c1)c1cccc(-n2c3ccccc3c3ccccc32)c1]

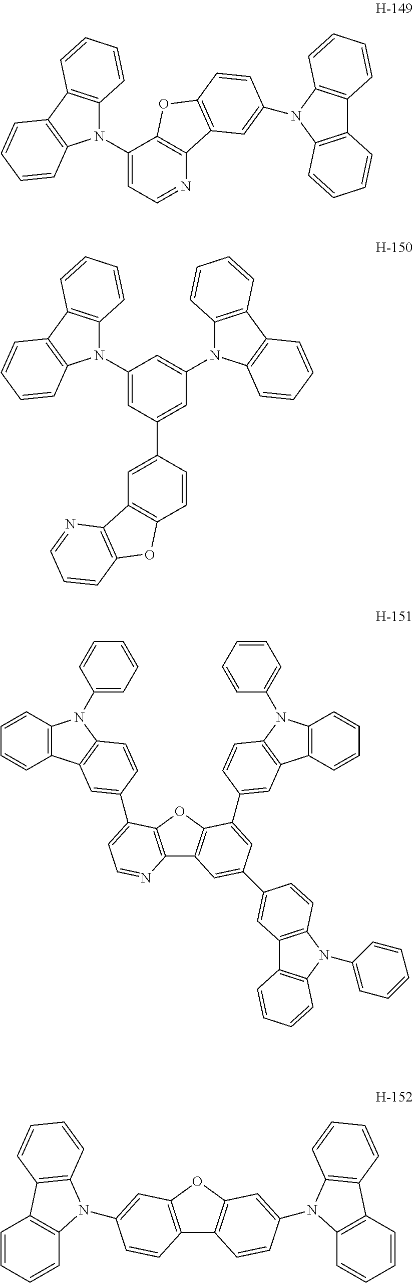 [SMILES: c1ccc2c(c1)c1ccccc1n2-c1ccc2oc3c(-n4c5ccccc5c5ccccc54)ccnc3c2c1 ; c1cnc2c(c1)oc1ccc(-c3cc(-n4c5ccccc5c5ccccc54)cc(-n4c5ccccc5c5ccccc54)c3)cc12 ; c1ccc(-n2c3ccccc3c3cc(-c4cc(-c5ccc6c(c5)c5ccccc5n6-c5ccccc5)c5oc6c(-c7ccc8c(c7)c7ccccc7n8-c7ccccc7)ccnc6c5c4)ccc32)cc1 ; c1ccc2c(c1)c1ccccc1n2-c1ccc2c(c1)oc1cc(-n3c4ccccc4c4ccccc43)ccc12]

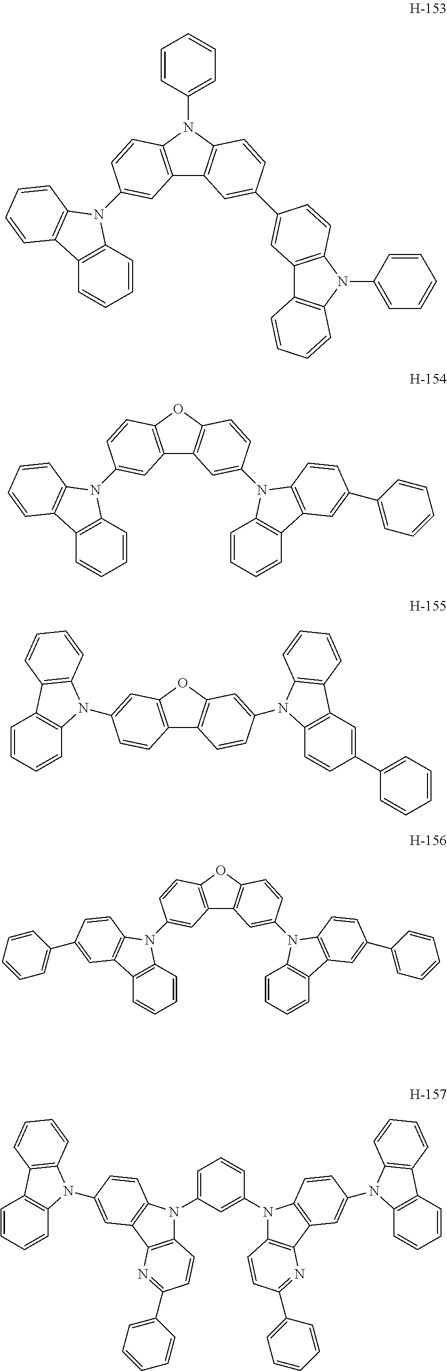 [SMILES: c1ccc(-n2c3ccccc3c3cc(-c4ccc5c(c4)c4cc(-n6c7ccccc7c7ccccc76)ccc4n5-c4ccccc4)ccc32)cc1 ; c1ccc(-c2ccc3c(c2)c2ccccc2n3-c2ccc3oc4ccc(-n5c6ccccc6c6ccccc65)cc4c3c2)cc1 ; c1ccc(-c2ccc3c(c2)c2ccccc2n3-c2ccc3c(c2)oc2cc(-n4c5ccccc5c5ccccc54)ccc23)cc1 ; c1ccc(-c2ccc3c(c2)c2ccccc2n3-c2ccc3oc4ccc(-n5c6ccccc6c6cc(-c7ccccc7)ccc65)cc4c3c2)cc1 ; c1ccc(-c2ccc3c(n2)c2cc(-n4c5ccccc5c5ccccc54)ccc2n3-c2cccc(-n3c4ccc(-n5c6ccccc6c6ccccc65)cc4c4nc(-c5ccccc5)ccc43)c2)cc1]

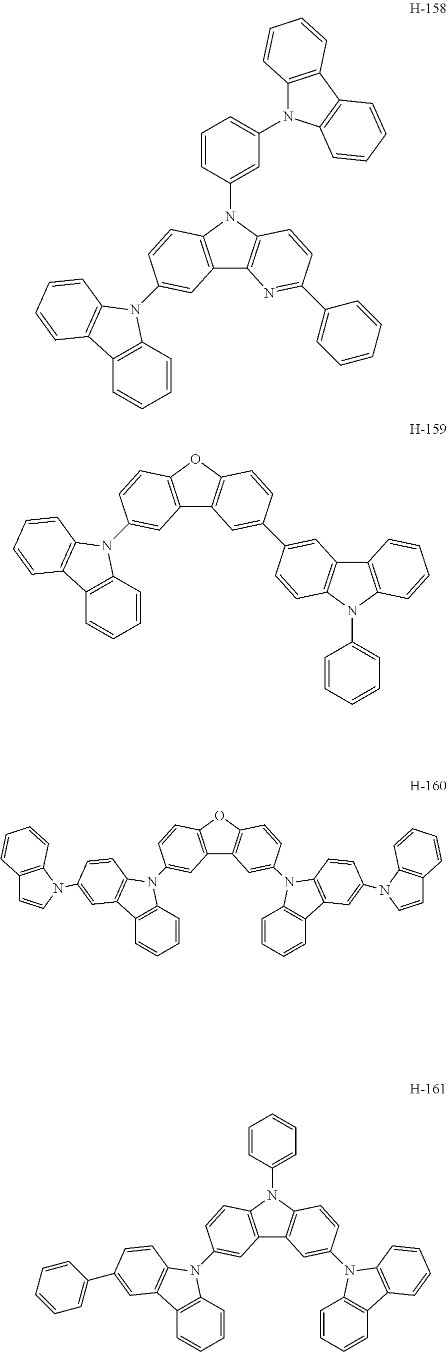 [SMILES: c1ccc(-c2ccc3c(n2)c2cc(-n4c5ccccc5c5ccccc54)ccc2n3-c2cccc(-n3c4ccccc4c4ccccc43)c2)cc1 ; c1ccc(-n2c3ccccc3c3cc(-c4ccc5oc6ccc(-n7c8ccccc8c8ccccc87)cc6c5c4)ccc32)cc1 ; c1ccc2c(c1)ccn2-c1ccc2c(c1)c1ccccc1n2-c1ccc2oc3ccc(-n4c5ccccc5c5cc(-n6ccc7ccccc76)ccc54)cc3c2c1 ; c1ccc(-c2ccc3c(c2)c2ccccc2n3-c2ccc3c(c2)c2cc(-n4c5ccccc5c5ccccc54)ccc2n3-c2ccccc2)cc1]

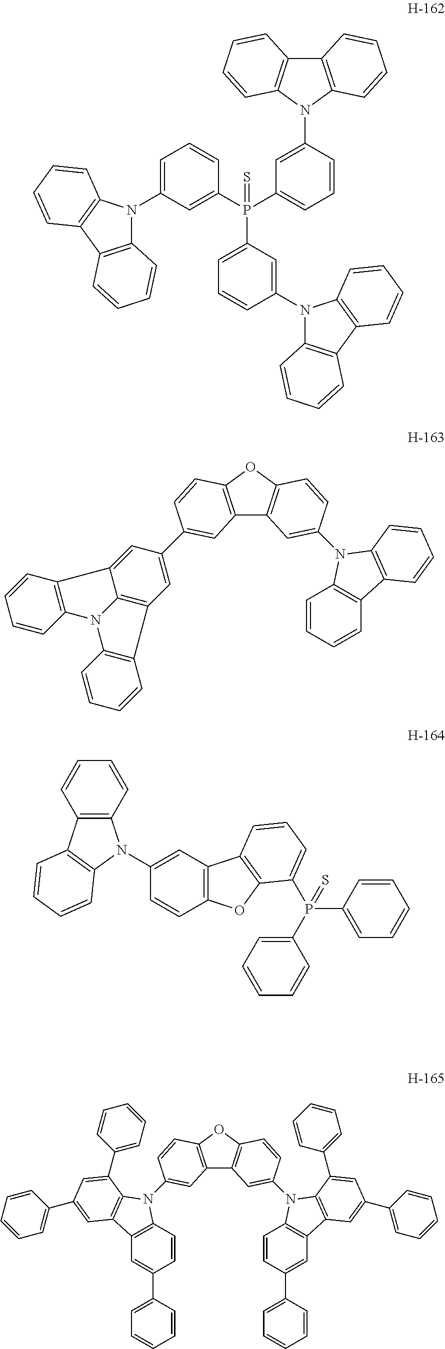 [SMILES: S=P(c1cccc(-n2c3ccccc3c3ccccc32)c1)(c1cccc(-n2c3ccccc3c3ccccc32)c1)c1cccc(-n2c3ccccc3c3ccccc32)c1 ; c1ccc2c(c1)c1ccccc1n2-c1ccc2oc3ccc(-c4cc5c6ccccc6n6c7ccccc7c(c4)c56)cc3c2c1 ; S=P(c1ccccc1)(c1ccccc1)c1cccc2c1oc1ccc(-n3c4ccccc4c4ccccc43)cc12 ; c1ccc(-c2ccc3c(c2)c2cc(-c4ccccc4)cc(-c4ccccc4)c2n3-c2ccc3oc4ccc(-n5c6ccc(-c7ccccc7)cc6c6cc(-c7ccccc7)cc(-c7ccccc7)c65)cc4c3c2)cc1]

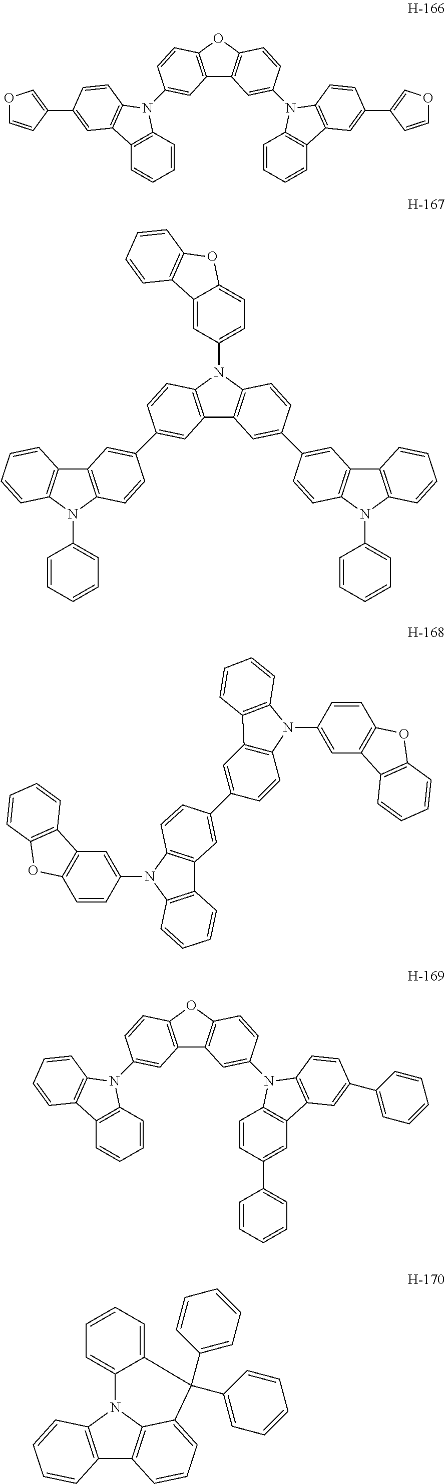 [SMILES: c1ccc2c(c1)c1cc(-c3ccoc3)ccc1n2-c1ccc2oc3ccc(-n4c5ccccc5c5cc(-c6ccoc6)ccc54)cc3c2c1 ; c1ccc(-n2c3ccccc3c3cc(-c4ccc5c(c4)c4cc(-c6ccc7c(c6)c6ccccc6n7-c6ccccc6)ccc4n5-c4ccc5oc6ccccc6c5c4)ccc32)cc1 ; c1ccc2c(c1)oc1ccc(-n3c4ccccc4c4cc(-c5ccc6c(c5)c5ccccc5n6-c5ccc6oc7ccccc7c6c5)ccc43)cc12 ; c1ccc(-c2ccc3c(c2)c2cc(-c4ccccc4)ccc2n3-c2ccc3oc4ccc(-n5c6ccccc6c6ccccc65)cc4c3c2)cc1 ; c1ccc(C2(c3ccccc3)c3ccccc3-n3c4ccccc4c4cccc2c43)cc1]

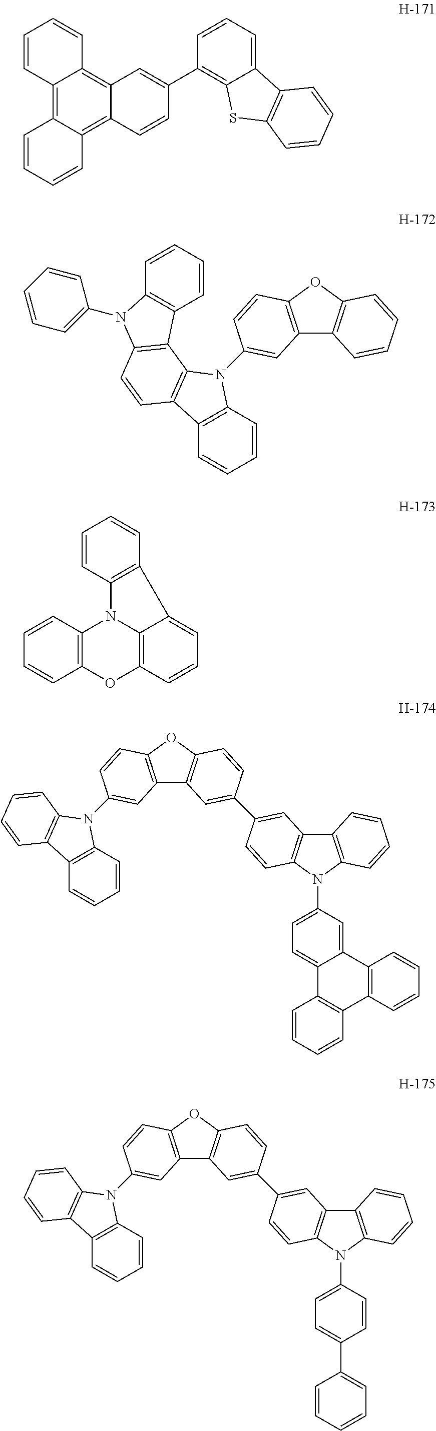 [SMILES: c1ccc2c(c1)sc1c(-c3ccc4c5ccccc5c5ccccc5c4c3)cccc12 ; c1ccc(-n2c3ccccc3c3c2ccc2c4ccccc4n(-c4ccc5oc6ccccc6c5c4)c23)cc1 ; c1ccc2c(c1)Oc1cccc3c4ccccc4n-2c13 ; c1ccc2c(c1)c1ccccc1c1cc(-n3c4ccccc4c4cc(-c5ccc6oc7ccc(-n8c9ccccc9c9ccccc98)cc7c6c5)ccc43)ccc21 ; c1ccc(-c2ccc(-n3c4ccccc4c4cc(-c5ccc6oc7ccc(-n8c9ccccc9c9ccccc98)cc7c6c5)ccc43)cc2)cc1]

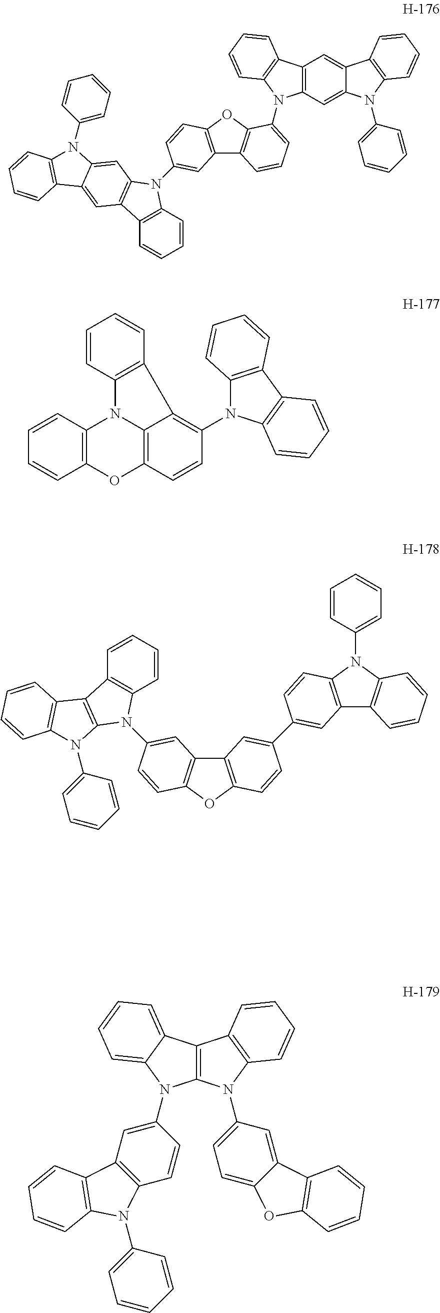 [SMILES: c1ccc(-n2c3ccccc3c3cc4c5ccccc5n(-c5ccc6oc7c(-n8c9ccccc9c9cc%10c%11ccccc%11n(-c%11ccccc%11)c%10cc98)cccc7c6c5)c4cc32)cc1 ; c1ccc2c(c1)Oc1ccc(-n3c4ccccc4c4ccccc43)c3c4ccccc4n-2c13 ; c1ccc(-n2c3ccccc3c3cc(-c4ccc5oc6ccc(-n7c8ccccc8c8c9ccccc9n(-c9ccccc9)c87)cc6c5c4)ccc32)cc1 ; c1ccc(-n2c3ccccc3c3cc(-n4c5ccccc5c5c6ccccc6n(-c6ccc7oc8ccccc8c7c6)c54)ccc32)cc1]

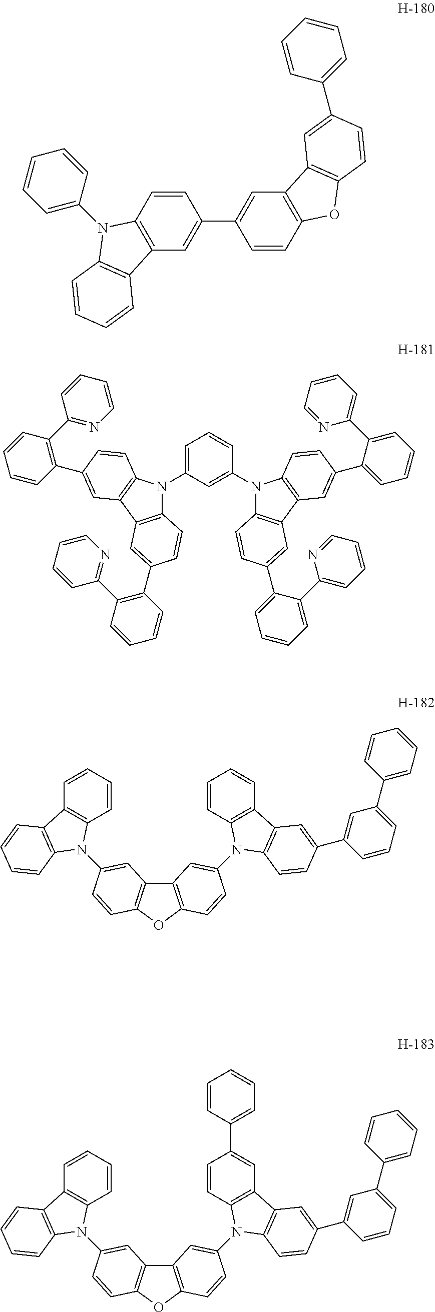 [SMILES: c1ccc(-c2ccc3oc4ccc(-c5ccc6c(c5)c5ccccc5n6-c5ccccc5)cc4c3c2)cc1 ; c1ccc(-c2ccccc2-c2ccc3c(c2)c2cc(-c4ccccc4-c4ccccn4)ccc2n3-c2cccc(-n3c4ccc(-c5ccccc5-c5ccccn5)cc4c4cc(-c5ccccc5-c5ccccn5)ccc43)c2)nc1 ; c1ccc(-c2cccc(-c3ccc4c(c3)c3ccccc3n4-c3ccc4oc5ccc(-n6c7ccccc7c7ccccc76)cc5c4c3)c2)cc1 ; c1ccc(-c2cccc(-c3ccc4c(c3)c3cc(-c5ccccc5)ccc3n4-c3ccc4oc5ccc(-n6c7ccccc7c7ccccc76)cc5c4c3)c2)cc1]

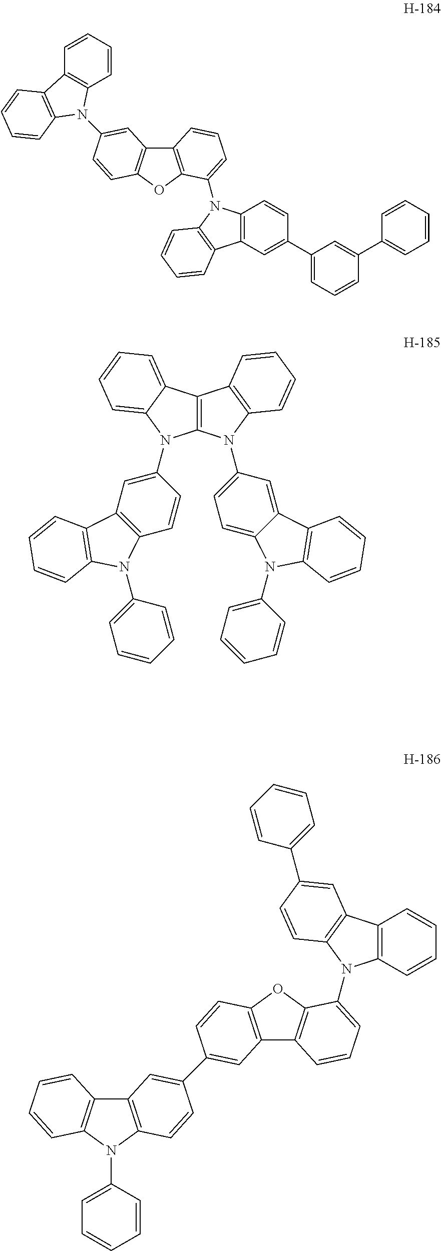 [SMILES: c1ccc(-c2cccc(-c3ccc4c(c3)c3ccccc3n4-c3cccc4c3oc3ccc(-n5c6ccccc6c6ccccc65)cc34)c2)cc1 ; c1ccc(-n2c3ccccc3c3cc(-n4c5ccccc5c5c6ccccc6n(-c6ccc7c(c6)c6ccccc6n7-c6ccccc6)c54)ccc32)cc1 ; c1ccc(-c2ccc3c(c2)c2ccccc2n3-c2cccc3c2oc2ccc(-c4ccc5c(c4)c4ccccc4n5-c4ccccc4)cc23)cc1]

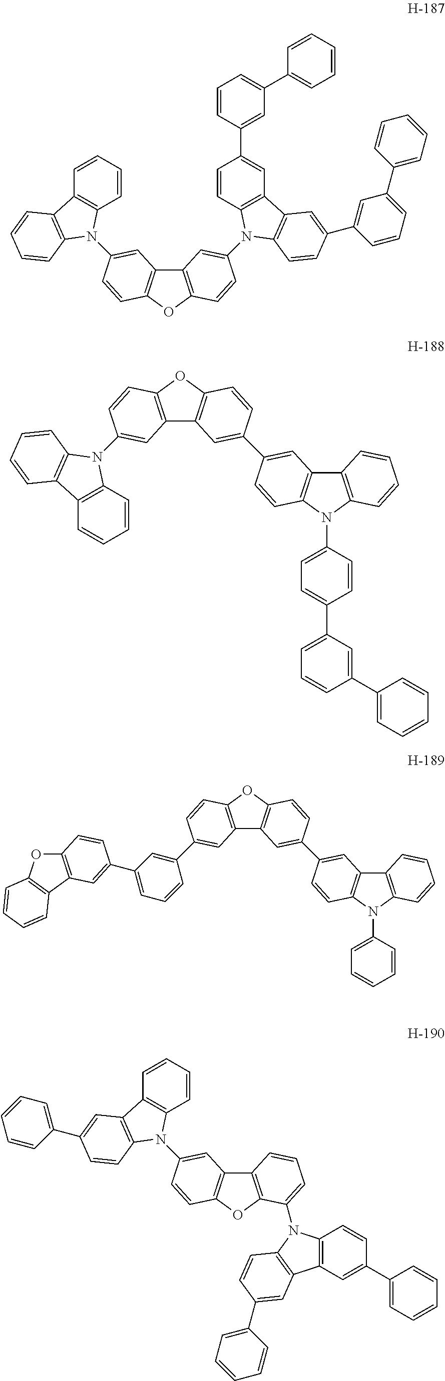 [SMILES: c1ccc(-c2cccc(-c3ccc4c(c3)c3cc(-c5cccc(-c6ccccc6)c5)ccc3n4-c3ccc4oc5ccc(-n6c7ccccc7c7ccccc76)cc5c4c3)c2)cc1 ; c1ccc(-c2cccc(-c3ccc(-n4c5ccccc5c5cc(-c6ccc7oc8ccc(-n9c%10ccccc%10c%10ccccc%109)cc8c7c6)ccc54)cc3)c2)cc1 ; c1ccc(-n2c3ccccc3c3cc(-c4ccc5oc6ccc(-c7cccc(-c8ccc9oc%10ccccc%10c9c8)c7)cc6c5c4)ccc32)cc1 ; c1ccc(-c2ccc3c(c2)c2ccccc2n3-c2ccc3oc4c(-n5c6ccc(-c7ccccc7)cc6c6cc(-c7ccccc7)ccc65)cccc4c3c2)cc1]

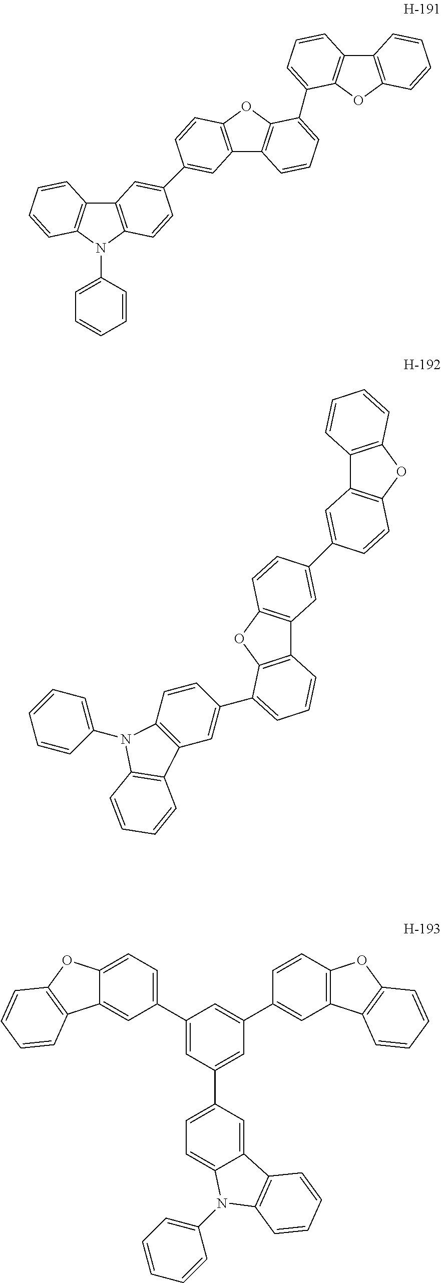 [SMILES: c1ccc(-n2c3ccccc3c3cc(-c4ccc5oc6c(-c7cccc8c7oc7ccccc78)cccc6c5c4)ccc32)cc1 ; c1ccc(-n2c3ccccc3c3cc(-c4cccc5c4oc4ccc(-c6ccc7oc8ccccc8c7c6)cc45)ccc32)cc1 ; c1ccc(-n2c3ccccc3c3cc(-c4cc(-c5ccc6oc7ccccc7c6c5)cc(-c5ccc6oc7ccccc7c6c5)c4)ccc32)cc1]

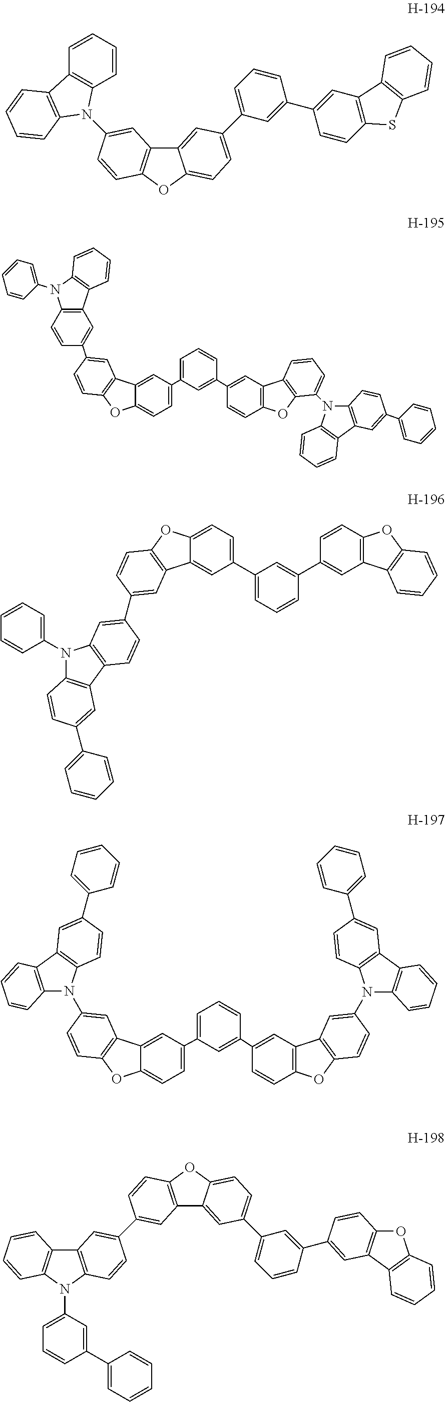

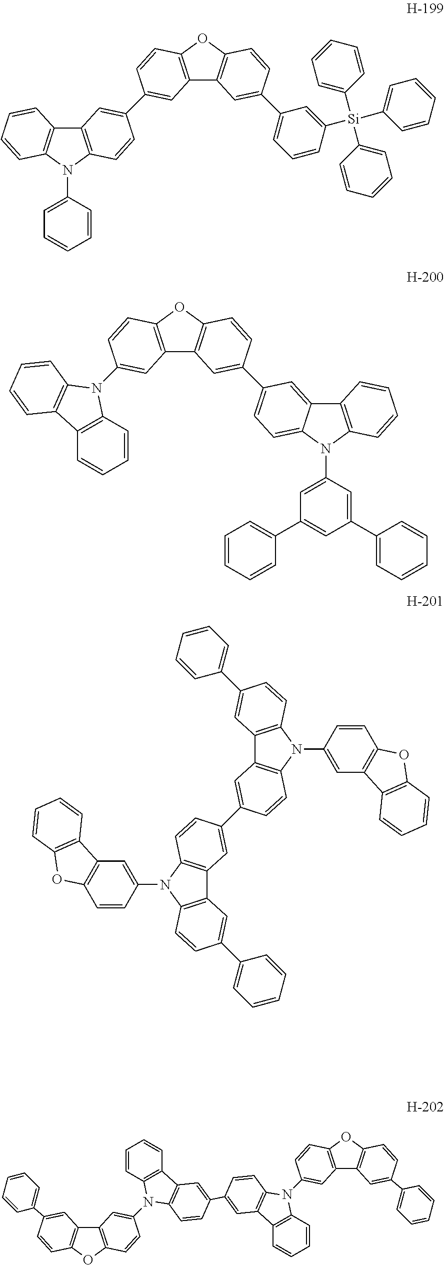 [SMILES: c1ccc(-n2c3ccccc3c3cc(-c4ccc5oc6ccc(-c7cccc([Si](c8ccccc8)(c8ccccc8)c8ccccc8)c7)cc6c5c4)ccc32)cc1 ; c1ccc(-c2cc(-c3ccccc3)cc(-n3c4ccccc4c4cc(-c5ccc6oc7ccc(-n8c9ccccc9c9ccccc98)cc7c6c5)ccc43)c2)cc1 ; c1ccc(-c2ccc3c(c2)c2cc(-c4ccc5c(c4)c4cc(-c6ccccc6)ccc4n5-c4ccc5oc6ccccc6c5c4)ccc2n3-c2ccc3oc4ccccc4c3c2)cc1 ; c1ccc(-c2ccc3oc4ccc(-n5c6ccccc6c6cc(-c7ccc8c(c7)c7ccccc7n8-c7ccc8oc9ccc(-c%10ccccc%10)cc9c8c7)ccc65)cc4c3c2)cc1]

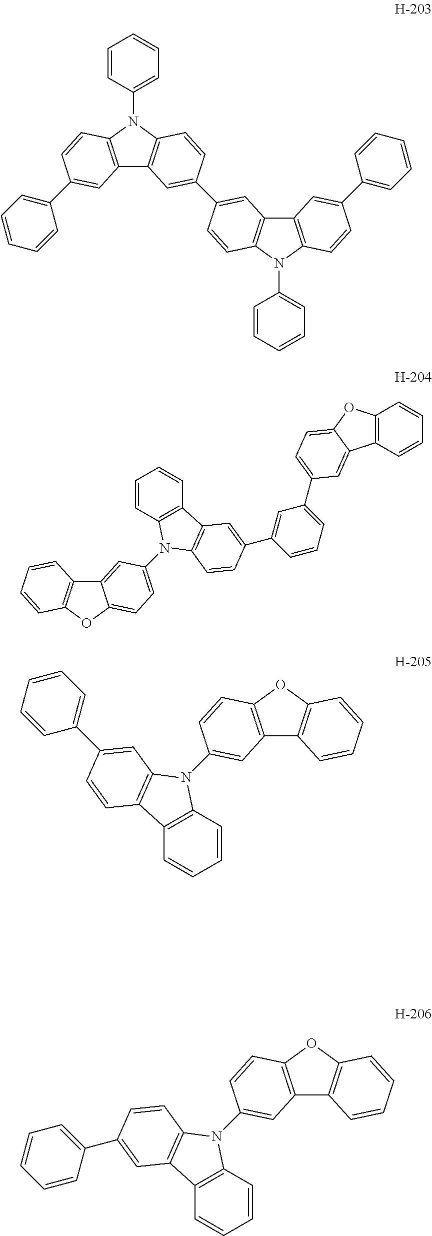 [SMILES: c1ccc(-c2ccc3c(c2)c2cc(-c4ccc5c(c4)c4cc(-c6ccccc6)ccc4n5-c4ccccc4)ccc2n3-c2ccccc2)cc1 ; c1cc(-c2ccc3oc4ccccc4c3c2)cc(-c2ccc3c(c2)c2ccccc2n3-c2ccc3oc4ccccc4c3c2)c1 ; c1ccc(-c2ccc3c4ccccc4n(-c4ccc5oc6ccccc6c5c4)c3c2)cc1 ; c1ccc(-c2ccc3c(c2)c2ccccc2n3-c2ccc3oc4ccccc4c3c2)cc1]

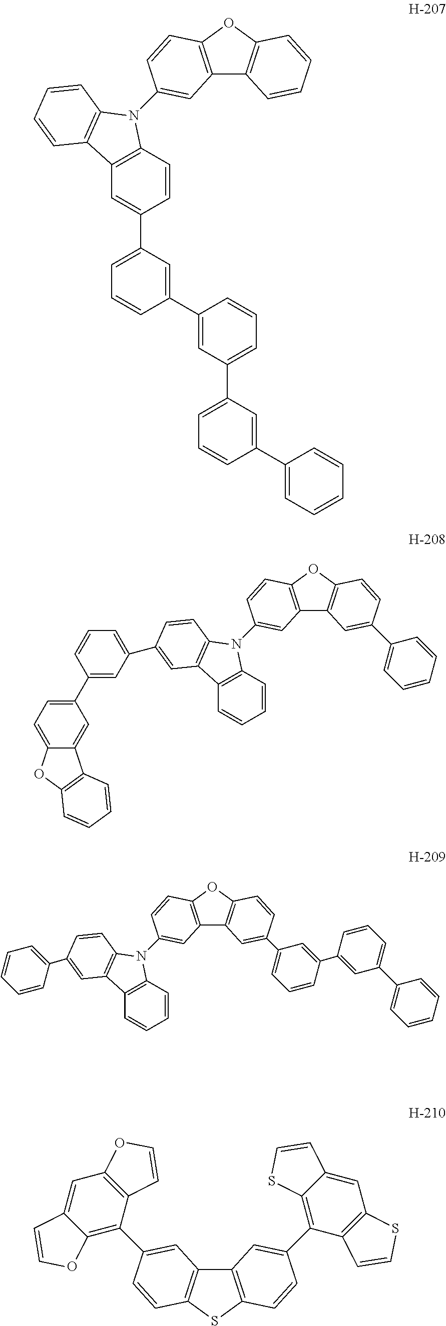 [SMILES: c1ccc(-c2cccc(-c3cccc(-c4cccc(-c5ccc6c(c5)c5ccccc5n6-c5ccc6oc7ccccc7c6c5)c4)c3)c2)cc1 ; c1ccc(-c2ccc3oc4ccc(-n5c6ccccc6c6cc(-c7cccc(-c8ccc9oc%10ccccc%10c9c8)c7)ccc65)cc4c3c2)cc1 ; c1ccc(-c2cccc(-c3cccc(-c4ccc5oc6ccc(-n7c8ccccc8c8cc(-c9ccccc9)ccc87)cc6c5c4)c3)c2)cc1 ; c1cc2c(-c3ccc4sc5ccc(-c6c7ccsc7cc7ccsc67)cc5c4c3)c3occc3cc2o1]

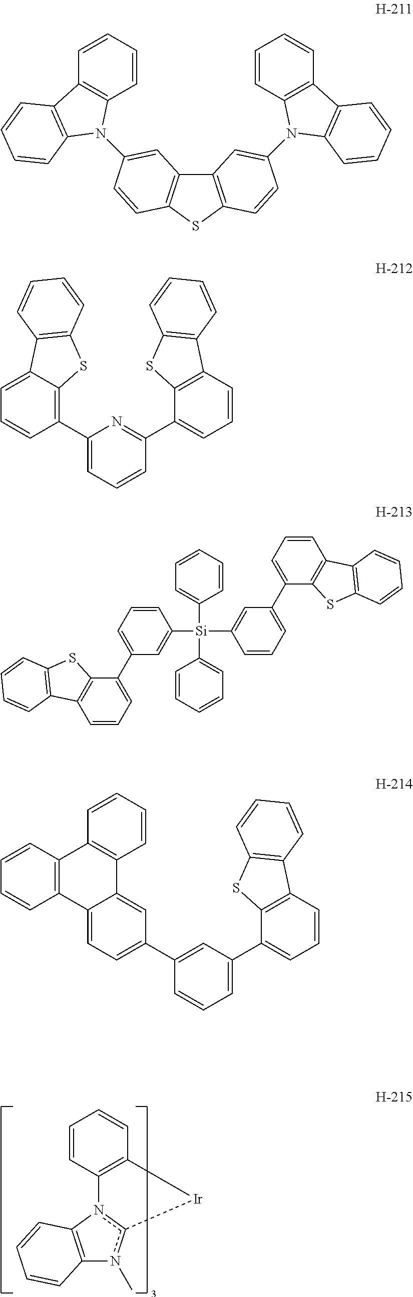

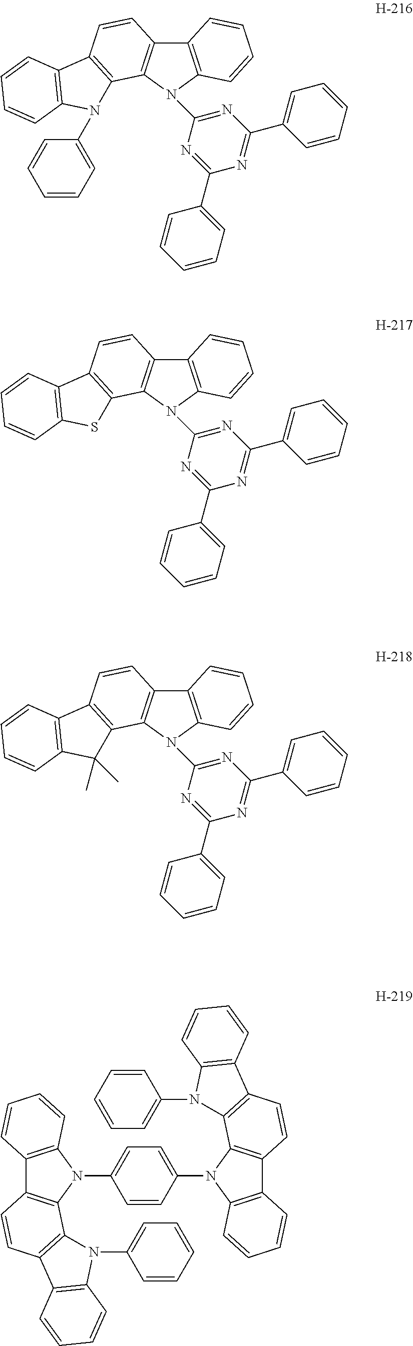 [SMILES: c1ccc(-c2nc(-c3ccccc3)nc(-n3c4ccccc4c4ccc5c6ccccc6n(-c6ccccc6)c5c43)n2)cc1 ; c1ccc(-c2nc(-c3ccccc3)nc(-n3c4ccccc4c4ccc5c6ccccc6sc5c43)n2)cc1 ; CC1(C)c2ccccc2-c2ccc3c4ccccc4n(-c4nc(-c5ccccc5)nc(-c5ccccc5)n4)c3c21 ; c1ccc(-n2c3ccccc3c3ccc4c5ccccc5n(-c5ccc(-n6c7ccccc7c7ccc8c9ccccc9n(-c9ccccc9)c8c76)cc5)c4c32)cc1]

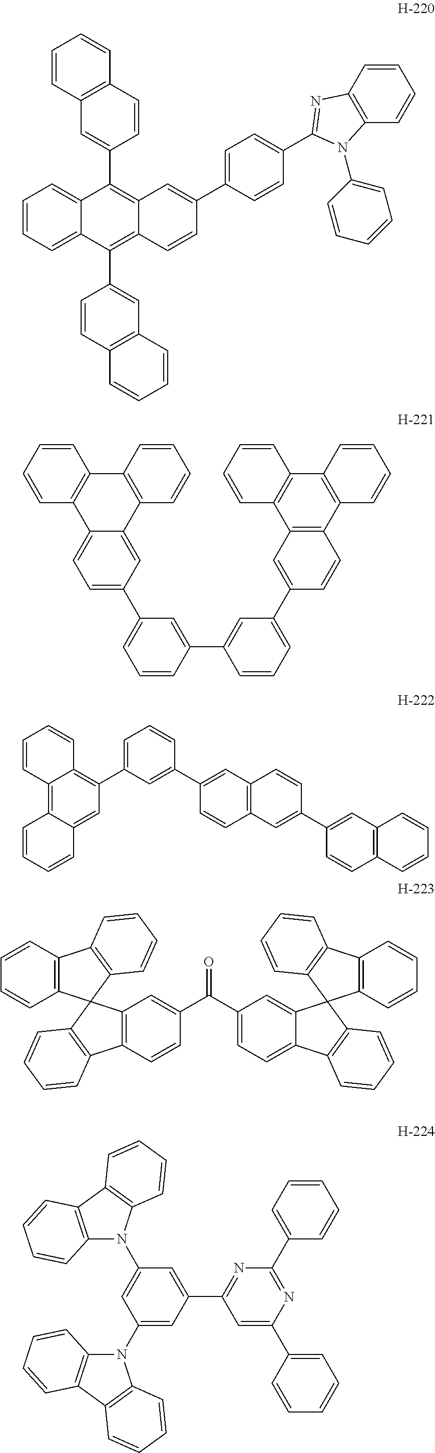

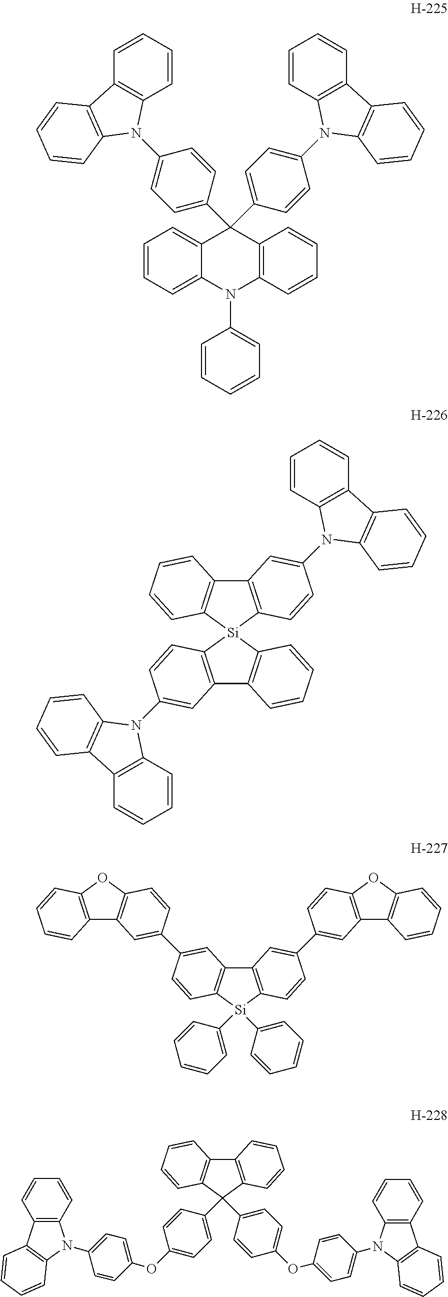 [SMILES: c1ccc(N2c3ccccc3C(c3ccc(-n4c5ccccc5c5ccccc54)cc3)(c3ccc(-n4c5ccccc5c5ccccc54)cc3)c3ccccc32)cc1 ; c1ccc2c(c1)-c1cc(-n3c4ccccc4c4ccccc43)ccc1[Si]21c2ccccc2-c2cc(-n3c4ccccc4c4ccccc43)ccc21 ; c1ccc([Si]2(c3ccccc3)c3ccc(-c4ccc5oc6ccccc6c5c4)cc3-c3cc(-c4ccc5oc6ccccc6c5c4)ccc32)cc1 ; c1ccc2c(c1)-c1ccccc1C2(c1ccc(Oc2ccc(-n3c4ccccc4c4ccccc43)cc2)cc1)c1ccc(Oc2ccc(-n3c4ccccc4c4ccccc43)cc2)cc1]

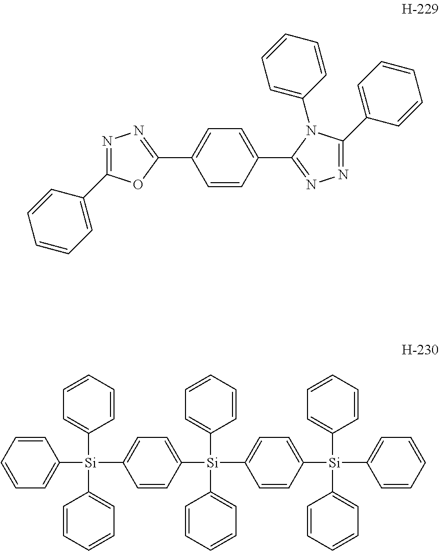 [SMILES: c1ccc(-c2nnc(-c3ccc(-c4nnc(-c5ccccc5)n4-c4ccccc4)cc3)o2)cc1 ; c1ccc([Si](c2ccccc2)(c2ccccc2)c2ccc([Si](c3ccccc3)(c3ccccc3)c3ccc([Si](c4ccccc4)(c4ccccc4)c4ccccc4)cc3)cc2)cc1]

A preferable host compound used for the present invention may be a low molecular weight compound which has a molecular weight enabling to be purified with sublimation, or it may be a polymer having a repeating unit.

The low molecular weight compound has an advantage of obtaining a highly purified material since it is possible to purify with sublimation. The molecular weight thereof is not specifically limited as long as it is possible to purify with sublimation. A preferable molecular weight is 3,000 or less, and a more preferable molecular weight is 2,000 or less.

A polymer or an oligomer having a repeating unit has an advantage of easily forming a film with a wet process. In addition, since a polymer has generally a high Tg, the polymer is preferable from the viewpoint of heat resistivity. The polymer used for the present invention is not specifically limited as long as a required element property can be achieved. Preferable polymers are compounds having a structure represented by any one of Formulas (I), (II), and (III-1) to (III-3) in the main chain or the side chain of the molecule. The molecular weight thereof is not specifically limited. However, a polymer having a molecular weight of 5,000 is preferable, or a polymer having 10 or more repeating units is preferable.

A host compound has a hole transporting ability and an electron transporting ability, as well as preventing elongation of an emission wavelength. In addition, from the viewpoint of stably driving an organic EL element at high temperature, it is preferable that a host compound has a high glass transition temperature (T) of 90° C. or more, more preferably, has a Tg of 120° C. or more.

Here, a glass transition temperature (Tg) is a value obtained using DSC (Differential Scanning Colorimetry) based on the method in conformity to JIS-K-7121-2012.

### <<Electron Transport Layer>>

An electron transport layer of the present invention is composed of a material having a function of transferring an electron. It is only required to have a function of transporting an injected electron from a cathode to a light emitting layer.

A total layer thickness of the electron transport layer is not specifically limited, however, it is generally in the range of 2 nm to 5 μm, and preferably, it is in the range of 2 to 500 nm, and more preferably, it is in the range of 5 to 200 nm.

In an organic EL element of the present invention, it is known that there occurs interference between the light directly taken from the light emitting layer and the light reflected at the electrode located at the opposite side of the electrode from which the light is taken out at the moment of taking out the light which is produced in the light emitting layer. When the light is reflected at the cathode, it is possible to use effectively this interference effect by suitably adjusting the total thickness of the electron transport layer in the range of several nm to several μm.

On the other hand, the voltage will be increased when the layer thickness of the electron transport layer is made thick. Therefore, especially when the layer thickness is large, it is preferable that the electron mobility in the electron transport layer is 10⁻⁵ cm²/Vs or more.

As a material used for an electron transport layer (hereafter, it is called as an electron transport material), it is only required to have either a property of ejection or transport of electrons, or a barrier to holes. Any of the conventionally known compounds may be selected and they may be employed.

Cited examples include: a nitrogen-containing aromatic heterocyclic derivative (a carbazole derivative, an azacarbazole derivative (a compound in which one or more carbon atoms constituting the carbazole ring are substitute with nitrogen atoms), a pyridine derivative, a pyrimidine derivative, a pyrazine derivative, a pyridazine derivative, a triazine derivative, a quinoline derivative, a quinoxaline derivative, a phenanthroline derivative, an azatriphenylene derivative, an oxazole derivative, a thiazole derivative, an oxadiazole derivative, a thiadiazole derivative, a triazole derivative, a benzimidazole derivative, a benzoxazole derivative, and a benzothiazole derivative); a dibenzofuran derivative, a dibenzothiophene derivative, a silole derivative; and an aromatic hydrocarbon ring derivative (a naphthalene derivative, an anthracene derivative and a triphenylene derivative).

Further, metal complexes having a ligand of a 8-quinolinol structure or dibnenzoquinolinol structure such as tris(8-quinolinol)aluminum (Alq₃), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum and bis(8-quinolinol)zinc (Znq); and metal complexes in which a central metal of the aforesaid metal complexes is substituted by In, Mg, Cu, Ca, Sn, Ga or Pb, may be also utilized as an electron transport material.

Further, a metal-free or metal phthalocyanine, or a compound whose terminal is substituted by an alkyl group or a sulfonic acid group, may be preferably utilized as an electron transport material. A distyryl pyrazine derivative, which is exemplified as a material for a light emitting layer, may be used as an electron transport material. Further, in the same manner as used for a hole injection layer and a hole transport layer, an inorganic semiconductor such as an n-type Si and an n-type SiC may be also utilized as an electron transport material.

It may be used a polymer compound having incorporating any one of these compound in a polymer side chain, or a compound having any one of these compound in a polymer main chain.

In an electron transport layer according to the present invention, it is possible to employ an electron transport layer of a higher n property (electron rich) which is doped with impurities as a guest material. As examples of a dope material, listed are those described in each of JP-A Nos. 4-297076, 10-270172, 2000-196140, 2001-102175, as well as in J. Appl. Phys., 95, 5773 (2004).

Although the present invention is not limited thereto, preferable examples of a known electron transport material used in an organic EL element of the present invention are compounds described in the following publications.

U.S. Pat. No. 6,528,187, U.S. Pat. No. 7,230,107, US 2005/0025993, US 2004/0036077, US 2009/0115316, US 2009/0101870, US 2009/0179554, WO 2003/060956, WO 2008/132085, Appl. Phys. Lett. 75, 4 (1999), Appl. Phys. Lett. 79, 449 (2001), Appl. Phys. Lett. 81, 162 (2002), Appl. Phys. Lett. 81, 162 (2002), Appl. Phys. Lett. 79, 156 (2001), U.S. Pat. No. 7,964,293, US 2009/030202, WO 2004/080975, WO 2004/063159, WO 2005/085387, WO 2006/067931, WO 2007/086552, WO 2008/114690, WO 2009/069442, WO 2009/066779, WO 2009/054253, WO 2011/086935, WO 2010/150593, WO 2010/047707, EP 2311826, JP-A 2010-251675, JP-A 2009-209133, JP-A 2009-124114, JP-A 2008-277810, JP-A 2006-156445, JP-A 2005-340122, JP-A 2003-45662, JP-A 2003-31367, JP-A 2003-282270, and WO 2012/115034.

As a preferable electron transport material, it can cite an aromatic heterocyclic ring compound containing at least one nitrogen atom. Examples thereof are: a pyridine derivative, a pyrimidine derivative, a pyrazine derivative, a triazine derivative, a dibenzofuran derivative, a dibenzothiophene derivative, an azadibenzofuran derivative, an azadibenzothiophene derivative, a carbazole derivative, an azacarbazole derivative, and a benzimidazole derivative.

An electron transport material may be used singly, or may be used in combination of plural kinds of compounds.

### <<Hole Blocking Layer>>

A hole blocking layer is a layer provided with a function of an electron transport layer in a broad meaning. Preferably, it contains a material having a function of transporting an electron, and having very small ability of transporting a hole. It can improve the recombination probability of an electron and a hole by blocking a hole while transporting an electron.

Further, a composition of an electron transport layer described above may be appropriately utilized as a hole blocking layer of the present invention when needed.

A hole blocking layer placed in an organic EL element of the present invention is preferably arranged at a location in the light emitting layer adjacent to the cathode side.

A thickness of a hole blocking layer according to the present invention is preferably in the range of 3 to 100 nm, and more preferably, in the range of 5 to 30 nm.

With respect to a material used for a hole blocking layer, the material used in the aforesaid electron transport layer is suitably used, and further, the material used as the aforesaid host compound is also suitably used for a hole blocking layer.

### <<Electron Injection Layer>>

An electron injection layer (it is also called as “a cathode buffer layer”) according to the present invention is a layer which is arranged between a cathode and a light emitting layer to decrease an operating voltage and to improve an emission luminance. An example of an electron injection layer is detailed in volume 2, chapter 2 “Electrode materials” (pp. 123-166) of “Organic EL Elements and Industrialization Front thereof (Nov. 30, 1998, published by N.T.S. Co. Ltd.)”.

In the present invention, an electron injection layer is provided according to necessity, and as described above, it is placed between a cathode and a light emitting layer, or between a cathode and an electron transport layer.

An electron injection layer is preferably a very thin layer. The layer thickness thereof is preferably in the range of 0.1 to 5 nm depending on the materials used.

An election injection layer is detailed in JP-A Nos. 6-325871, 9-17574, and 10-74586. Examples of a material preferably used in an election injection layer include: a metal such as strontium and aluminum; an alkaline metal compound such as lithium fluoride, sodium fluoride, or potassium fluoride; an alkaline earth metal compound such as magnesium fluoride; a metal oxide such as aluminum oxide; and a metal complex such as lithium 8-hydroxyquinolate (Liq). It is possible to use the aforesaid electron transport materials.

The above-described materials may be used singly or plural kinds may be used in an election injection layer.

### <<Hole Transport Layer>>

In the present invention, a hole transport layer contains a material having a function of transporting a hole. A hole transport layer is only required to have a function of transporting a hole injected from an anode to a light emitting layer.

The total layer thickness of a hole transport layer of the present invention is not specifically limited, however, it is generally in the range of 5 nm to 5 μm, preferably in the range of 2 to 500 nm, and more preferably in the range of 5 to 200 nm.

A material used in a hole transport layer (hereafter, it is called as a hole transport material) is only required to have any one of properties of injecting and transporting a hole, and a barrier property to an electron. A hole transport material may be suitably selected from the conventionally known compounds. A hole transport material may be used singly, or plural kinds may be used.

Examples of a hole transport material include: a porphyrin derivative, a phthalocyanine derivative, an oxazole derivative, an oxadiazole derivative, a triazole derivative, an imidazole derivative, a pyrazoline derivative, a pyrazolone derivative, a phenylenediamine derivative, a hydrazone derivative, a stilbene derivative, a polyarylalkane derivative, a triarylamine derivative, a carbazole derivative, an indolocarbazole derivative, an isoindole derivative, an acene derivative of anthracene or naphthalene, a fluorene derivative, a fluorenone derivative, polyvinyl carbazole, a polymer or an oligomer containing an aromatic amine in a side chain or a main chain, polysilane, and a conductive polymer or oligomer (e.g., PEDOT:PSS, aniline type copolymer, polyaniline and polythiophene).

Examples of a triarylamine derivative include: a benzidine type represented by α-NPD (4,4′-bis[N-(1-naphthyl)-N-phenyamino]biphenyl), a star burst type represented by MTDATA (4,4′,4″-tris(N-(3-methylphenyl)-N-phenylamino)triphenylamine), a compound having fluorenone or anthracene in a triarylamine bonding core.

A hexaazatriphenylene derivative described in JP-A Nos. 2003-519432 and 2006-135145 may be also used as a hole transport material.

In addition, it is possible to employ an electron transport layer of a higher p property which is doped with impurities. As its example, listed are those described in each of JP-A Nos. 4-297076, 2000-196140, and 2001-102175, as well as in J. Appl. Phys., 95, 5773 (2004).

Further, it is possible to employ so-called p-type hole transport materials, and inorganic compounds such as p-type Si and p-type SiC, as described in JP-A No. 11-251067, and J. Huang et al. reference (Applied Physics Letters 80 (2002), p. 139). Moreover, an orthometal compounds having Ir or Pt as a center metal represented by Ir(ppy)₃ are also preferably used.

Although the above-described compounds may be used as a hole transport material, preferably used are: a triarylamine derivative, a carbazole derivative, an indolocarbazole derivative, an azatriphenylene derivative, an organic metal complex, a polymer or an oligomer incorporated an aromatic amine in a main chain or in a side chain.

Specific examples of a known hole transport material used in an organic EL element of the present invention are compounds in the aforesaid publications and in the following publications. However, the present invention is not limited to them.

Appl. Phys. Lett. 69, 2160 (1996), J. Lumin. 72-74, 985 (1997), Appl. Phys. Lett. 78, 673 (2001), Appl. Phys. Lett. 90, 183503 (2007), Appl. Phys. Lett. 51, 913 (1987), Synth. Met. 87, 171 (1997), Synth. Met. 91, 209 (1997), Synth. Met. 111, 421 (2000), SID Symposium Digest, 37, 923 (2006), J. Mater. Chem. 3, 319 (1993), Adv. Mater. 6, 677 (1994), Chem. Mater. 15, 3148 (2003), US 2003/0162053, US 2002/0158242, US 2006/0240279, US 2008/0220265, U.S. Pat. No. 5,061,569, WO 2007/002683, WO 2009/018009, EP 650955, US 2008/0124572, US 2007/0278938, US 2008/0106190, US 2008/0018221, WO 2012/115034, JP-A 2003-519432, JP-A 2006-135145, and U.S. patent application Ser. No. 13/585,981.

A hole transport material may be used singly or may be used in combination of plural kinds of compounds.

### <<Electron Blocking Layer>>

An electron blocking layer is a layer provided with a function of a hole transport layer in a broad meaning. Preferably, it contains a material having a function of transporting a hole, and having very small ability of transporting an electron. It can improve the recombination probability of an electron and a hole by blocking an electron while transporting a hole. Further, a composition of a hole transport layer described above may be appropriately utilized as an electron blocking layer of an organic EL element of the present invention when needed.

An electron blocking layer placed in an organic EL element of the present invention is preferably arranged at a location in the light emitting layer adjacent to the anode side.

A thickness of an electron blocking layer is preferably in the range of 3 to 100 nm, and more preferably, in the range of 5 to 30 nm.

With respect to a material used for an electron blocking layer, the material used in the aforesaid hole transport layer is suitably used, and further, the material used as the aforesaid host compound is also suitably used for an electron blocking layer.

### <<Hole Injection Layer>>

A hole injection layer (it is also called as “an anode buffer layer”) is a layer which is arranged between an electrode and a light emitting layer to decrease an operating voltage and to improve an emission luminance. An example of a hole injection layer is detailed in volume 2, chapter 2 “Electrode materials” (pp. 123-166) of “Organic EL Elements and Industrialization Front thereof (Nov. 30, 1998, published by N.T.S. Co. Ltd.)”.

A hole injection layer is provided according to necessity, and as described above, it is placed between an anode and a light emitting layer, or between an anode and a hole transport layer.

A hole injection layer is also detailed in JP-A Nos. 9-45479, 9-260062 and 8-288069. Materials used in the hole injection layer are the same materials used in the aforesaid hole transport layer.

Among them, preferable materials are: a phthalocyanine derivative represented by copper phthalocyanine; a hexaazatriphenylene derivative described in JP-A Nos. 2003-519432 and 2006-135145; a metal oxide represented by vanadium oxide; a conductive polymer such as amorphous carbon, polyaniline (or called as emeraldine) and polythiophene; an orthometalated complex represented by tris(2-phenylpyridine)iridium complex; and a triarylamine derivative.

The above-described materials used in a hole injection layer may be used singly or plural kinds may be used.

### <<Additive>>

The above-described organic layer of the present invention may further contain other additive.

Examples of an additive are: halogen elements such as bromine, iodine and chlorine, and a halide compound; and a compound, a complex and a salt of an alkali metal, an alkaline earth metal and a transition metal such as Pd, Ca and Na.

Although a content of an additive may be arbitrarily decided, preferably, it is 1,000 ppm or less based on the total mass of the layer containing the additive, more preferably, it is 500 ppm or less, and still more preferably, it is 50 ppm or less.

In order to improve a transporting ability of an electron or a hole, or to facilitate energy transport of an exciton, the content of the additive is not necessarily within these range, and other range of content may be used.

### <<Forming Method of Organic Layers>>

It will be described forming methods of organic layers according to the present invention (hole injection layer, hole transport layer, light emitting layer, hole blocking layer, electron transport layer, and electron injection layer).

Forming methods of organic layers according to the present invention are not specifically limited. They may be formed by using a known method such as a vacuum vapor deposition method and a wet method (wet process).

Examples of a wet process include: a spin coating method, a cast method, an inkjet method, a printing method, a die coating method, a blade coating method, a roll coating method, a spray coating method, a curtain coating method, and a LB method (Langmuir Blodgett method). From the viewpoint of getting a uniform thin layer with high productivity, preferable are method highly appropriate to a roll-to-roll method such as a die coating method, a roll coating method, an inkjet method, and a spray coating method.

Examples of a liquid medium to dissolve or to disperse a material for organic layers according to the present invention include: ketones such as methyl ethyl ketone and cyclohexanone; aliphatic esters such as ethyl acetate; halogenated hydrocarbons such as dichlorobenzene; aromatic hydrocarbons such as toluene, xylene, mesitylene, and cyclohexylbenzene; aliphatic hydrocarbons such as cyclohexane, decalin, and dodecane; organic solvents such as DMF and DMSO.

These will be dispersed with a dispersion method such as an ultrasonic dispersion method, a high shearing dispersion method and a media dispersion method.

A different film forming method may be applied to every organic layer. When a vapor deposition method is adopted for forming each layer, the vapor deposition conditions will change depending on the compounds used. Generally, the following ranges are suitably selected for the conditions, heating temperature of boat: 50 to 450° C., level of vacuum: 10⁻⁶ to 10⁻² Pa, vapor deposition rate: 0.01 to 50 nm/sec, temperature of substrate: −50 to 300° C., and layer thickness: 0.1 nm to 5 μm, preferably 5 to 200 nm.

Formation of organic layers of the present invention is preferably continuously carried out from a hole injection layer to a cathode with one time vacuuming. It may be taken out on the way, and a different layer forming method may be employed. In that case, the operation is preferably done under a dry inert gas atmosphere.

### <<Anode>>

As an anode of an organic EL element, a metal having a large work function (4 eV or more, preferably, 4.5 eV or more), an alloy, and a conductive compound and a mixture thereof are utilized as an electrode substance.

Specific examples of an electrode substance are: metals such as Au, and an alloy thereof; transparent conductive materials such as CuI, indium tin oxide (ITO), SnO₂, and ZnO. Further, a material such as IDIXO (In₂O₃—ZnO), which can form an amorphous and transparent electrode, may also be used.

As for an anode, these electrode substances may be made into a thin layer by a method such as a vapor deposition method or a sputtering method; followed by making a pattern of a desired form by a photolithography method. Otherwise, in the case of requirement of pattern precision is not so severe (about 100 μm or more), a pattern may be formed through a mask of a desired form at the time of layer formation with a vapor deposition method or a sputtering method using the above-described material.

Alternatively, when a coatable substance such as an organic conductive compound is employed, it is possible to employ a wet film forming method such as a printing method or a coating method. When emitted light is taken out from the anode, the transmittance is preferably set to be 10% or more. A sheet resistance of a first electrode is preferably a few hundred Ω/sq or less.

Further, although a layer thickness of the anode depends on a material, it is generally selected in the range of 10 nm to 1 μm, and preferably in the range of 10 to 200 nm.

### <<Cathode>>

As a cathode, a metal having a small work function (4 eV or less) (it is called as an electron injective metal), an alloy, a conductive compound and a mixture thereof are utilized as an electrode substance. Specific examples of the aforesaid electrode substance includes: sodium, sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, aluminum, and a rare earth metal. Among them, with respect to an electron injection property and durability against oxidation, preferable are: a mixture of election injecting metal with a second metal which is stable metal having a work function larger than the electron injecting metal. Examples thereof are: a magnesium/silver mixture, a magnesium/aluminum mixture, a magnesium/indium mixture, an aluminum/aluminum oxide (Al₂O₃) mixture, a lithium/aluminum mixture and aluminum.

A cathode may be made by using these electrode substances with a method such as a vapor deposition method or a sputtering method to form a thin film. A sheet resistance of the a cathode is preferably a few hundred Ω/sq or less. A layer thickness of the cathode is generally selected in the range of 10 nm to 5 μm, and preferably in the range of 50 to 200 nm.

In order to transmit emitted light, it is preferable that one of an anode and a cathode of an organic EL element is transparent or translucent for achieving an improved luminescence.

Further, after forming a layer of the aforesaid metal having a thickness of 1 to 20 nm on the cathode, it is possible to prepare a transparent or translucent cathode by providing with a conductive transparent material described in the description for the anode thereon. By applying this process, it is possible to produce an element in which both an anode and a cathode are transparent.

### [Support Substrate]

A support substrate which may be used for an organic EL element of the present invention is not specifically limited with respect to types of such as glass and plastics. Hereafter, the support substrate may be also called as substrate body, substrate, substrate substance, or support. They may be transparent or opaque. However, a transparent support substrate is preferable when the emitting light is taken from the side of the support substrate. Support substrates preferably utilized includes such as glass, quartz and transparent resin film. A specifically preferable support substrate is a resin film capable of providing an organic EL element with a flexible property.

Examples of a resin film include: polyesters such as polyethylene terephthalate (PET) and polyethylene naphthalate (PEN), polyethylene, polypropylene, cellophane, cellulose esters and their derivatives such as cellulose diacetate, cellulose triacetate (TAC), cellulose acetate butyrate, cellulose acetate propionate (CAP), cellulose acetate phthalate, and cellulose nitrate, polyvinylidene chloride, polyvinyl alcohol, polyethylene vinyl alcohol, syndiotactic polystyrene, polycarbonate, norbornene resin, polymethyl pentene, polyether ketone, polyimide, polyether sulfone (PES), polyphenylene sulfide, polysulfones, polyether imide, polyether ketone imide, polyamide, fluororesin, Nylon, polymethyl methacrylate, acrylic resin, polyarylates and cycloolefin resins such as ARTON (trade name, made by JSR Co. Ltd.) and APEL (trade name, made by Mitsui Chemicals, Inc.).

On the surface of a resin film, it may be formed a film incorporating an inorganic or an organic compound or a hybrid film incorporating both compounds. Barrier films are preferred at a water vapor permeability of 0.01 g/m²·24 h or less (at 25±0.5° C., and 90±2% RH) determined based on JIS K 7129-1992. Further, high barrier films are preferred to have an oxygen permeability of 1×10⁻³ ml/m²·24 h·atm or less determined based on JIS K 7126-1987, and a water vapor permeability1 of 1×10⁻⁵ g/m²·24 h or less.

As materials forming a barrier film, employed may be those which retard penetration of moisture and oxygen, which deteriorate the element. For example, it is possible to employ silicon oxide, silicon dioxide, and silicon nitride. Further, in order to improve the brittleness of the aforesaid film, it is more preferable to achieve a laminated layer structure of inorganic layers and organic layers. The laminating order of the inorganic layer and the organic layer is not particularly limited, but it is preferable that both are alternatively laminated a plurality of times.

Barrier film forming methods are not particularly limited, and examples of employable methods include a vacuum deposition method, a sputtering method, a reactive sputtering method, a molecular beam epitaxy method, a cluster ion beam method, an ion plating method, a plasma polymerization method, a plasma CVD method, a laser CVD method, a thermal CVD method, and a coating method. Of these, specifically preferred is a method employing an atmospheric pressure plasma polymerization method, described in JP-A No. 2004-68143.

Examples of opaque support substrates include metal plates such aluminum or stainless steel films, opaque resin substrates, and ceramic substrates.

The external taking out quantum efficiency of light emitted by the organic EL element of the present invention is preferably at least 1% at a room temperature, but is more preferably at least 5%.

External taking out quantum efficiency (%)=(Number of photons emitted by the organic EL element to the exterior/Number of electrons fed to organic EL element)×100.

Further, it may be used simultaneously a color hue improving filter such as a color filter, or it may be used simultaneously a color conversion filter which convert emitted light color from the organic EL element to multicolor by employing fluorescent materials.

### <<Sealing>>

As sealing means employed in the present invention, listed may be, for example, a method in which sealing members, electrodes, and a supporting substrate are subjected to adhesion via adhesives. The sealing members may be arranged to cover the display region of an organic EL element, and may be a concave plate or a flat plate. Neither transparency nor electrical insulation is limited.

Specifically listed are glass plates, polymer plate-films, metal plate-films. Specifically, it is possible to list, as glass plates, soda-lime glass, barium-strontium containing glass, lead glass, aluminosilicate glass, borosilicate glass, barium borosilicate glass, and quartz. Further, listed as polymer plates maybe polycarbonate, acryl, polyethylene terephthalate, polyether sulfide, and polysulfone. As a metal plate, listed are those composed of at least one metal selected from the group consisting of stainless steel, iron, copper, aluminum magnesium, nickel, zinc, chromium, titanium, molybdenum, silicon, germanium, and tantalum, or alloys thereof.

In the present invention, since it is possible to achieve a thin organic EL element, it is preferable to employ a polymer film or a metal film. Further, it is preferable that the polymer film has an oxygen permeability of 1×10⁻³ ml/m²·24 h or less determined by the method based on JIS K 7126-1987, and a water vapor permeability of 1×10⁻³ g/m²·24 h or less (at 25±0.5° C., and 90±2% RH) or less determined by the method based on JIS K 7129-1992.

Conversion of the sealing member into concave is carried out employing a sand blast process or a chemical etching process.

In practice, as adhesives, listed may be photo-curing and heat-curing types having a reactive vinyl group of acrylic acid based oligomers and methacrylic acid, as well as moisture curing types such as 2-cyanoacrylates. Further listed may be thermal and chemical curing types (mixtures of two liquids) such as epoxy based ones. Still further listed may be hot-melt type polyamides, polyesters, and polyolefins. Yet further listed may be cationically curable type UV curable epoxy resin adhesives.

In addition, since an organic EL element is occasionally deteriorated via a thermal process, those are preferred which enable adhesion and curing between a room temperature and 80° C. Further, desiccating agents may be dispersed into the aforesaid adhesives. Adhesives may be applied onto sealing portions via a commercial dispenser or printed on the same in the same manner as screen printing.

Further, it is appropriate that on the outside of the aforesaid electrode which interposes the organic layer and faces the support substrate, the aforesaid electrode and organic layer are covered, and in the form of contact with the support substrate, inorganic and organic material layers are formed as a sealing film. In this case, as materials forming the aforesaid film may be those which exhibit functions to retard penetration of moisture or oxygen which results in deterioration. For example, it is possible to employ silicon oxide, silicon dioxide, and silicon nitride.

Still further, in order to improve brittleness of the aforesaid film, it is preferable that a laminated layer structure is formed, which is composed of these inorganic layers and layers composed of organic materials. Methods to form these films are not particularly limited. It is possible to employ, for example, a vacuum deposition method, a sputtering method, a reactive sputtering method, a molecular beam epitaxy method, a cluster ion beam method, an ion plating method, a plasma polymerization method, an atmospheric pressure plasma polymerization method, a plasma CVD method, a thermal CVD method, and a coating method.

It is preferable to inject a gas phase and a liquid phase material of inert gases such as nitrogen or argon, and inactive liquids such as fluorinated hydrocarbon or silicone oil into the space between the space formed with the sealing member and the display region of the organic EL element. Further, it is possible to form vacuum in the space. Still further, it is possible to enclose hygroscopic compounds in the interior of the space.

Examples of hygroscopic compounds include: metal oxides (for example, sodium oxide, potassium oxide, calcium oxide, barium oxide, magnesium oxide, and aluminum oxide); sulfates (for example, sodium sulfate, calcium sulfate, magnesium sulfate, and cobalt sulfate); metal halides (for example, calcium chloride, magnesium chloride, cesium fluoride, tantalum fluoride, cerium bromide, magnesium bromide, barium iodide, and magnesium iodide); perchlorates (for example, barium perchlorate and magnesium perchlorate). In sulfates, metal halides, and perchlorates, suitably employed are anhydrides. For sulfate salts, metal halides and perchlorates, suitably used are anhydrous salts.

### [Protective Film and Protective Plate]

On the aforesaid sealing film which interposes the organic layer and faces the support substrate or on the outside of the aforesaid sealing film, a protective or a protective plate may be arranged to enhance the mechanical strength of the element. Specifically, when sealing is achieved via the aforesaid sealing film, the resulting mechanical strength is not always high enough, whereby it is preferable to arrange the protective film or the protective plate described above. Usable materials for these include glass plates, polymer plate-films, and metal plate-films which are similar to those employed for the aforesaid sealing. However, in terms of light weight and decrease in thickness, it is preferable to employ a polymer film.

### [Improving Method of Light Extraction]

It is generally known that an organic EL element emits light in the interior of the layer exhibiting the refractive index (being about 1.6 to 2.1) which is greater than that of air, whereby only about 15% to 20% of light generated in the light emitting layer is extracted. This is due to the fact that light incident to an interface (being an interlace of a transparent substrate to air) at an angle of θ which is at least critical angle is not extracted to the exterior of the element due to the resulting total reflection, or light is totally reflected between the transparent electrode or the light emitting layer and the transparent substrate, and light is guided via the transparent electrode or the light emitting layer, whereby light escapes in the direction, of the element side surface.

Means to enhance the efficiency of the aforesaid light extraction include, for example: a method in which roughness is formed on the surface of a transparent substrate, whereby total reflection is minimized at the interface of the transparent substrate to air (U.S. Pat. No. 4,774,435), a method in which efficiency is enhanced in such a manner that a substrate results in light collection (JP-A No. 63-314795), a method in which a reflection surface is formed on the side of the element (JP-A No. 1-220394), a method in which a flat layer of a middle refractive index is introduced between the substrate and the light emitting body and an antireflection film is formed (JP-A No. 62-172691), a method in which a flat layer of a refractive index which is equal to or less than the substrate is introduced between the substrate and the light emitting body (JP-A No. 2001-202827), and a method in which a diffraction grating is formed between the substrate and any of the layers such as the transparent electrode layer or the light emitting layer (including between the substrate and the outside) (JP-A No. 11-283751).

In the present invention, it is possible to employ these methods while combined with the organic EL element of the present invention. Of these, it is possible to appropriately employ the method in which a flat layer of a refractive index which is equal to or less than the substrate is introduced between the substrate and the light emitting body and the method in which a diffraction grating is formed between any layers of a substrate, and a transparent electrode layer and a light emitting layer (including between the substrate and the outside space).

By combining these means, the present invention enables the production of elements which exhibit higher luminance or excel in durability.

When a low refractive index medium having a thickness, greater than the wavelength of light is formed between the transparent electrode and the transparent substrate, the extraction efficiency of light emitted from the transparent electrode to the exterior increases as the refractive index of the medium decreases.

As materials of the low refractive index layer, listed are, for example, aerogel, porous silica, magnesium fluoride, and fluorine based polymers. Since the refractive index of the transparent substrate is commonly about 1.5 to 1.7, the refractive index of the low refractive index layer is preferably approximately 1.5 or less. More preferably, it is 1.35 or less.

Further, thickness of the low refractive index medium is preferably at least two times of the wavelength in the medium. The reason is that, when the thickness of the low refractive index medium reaches nearly the wavelength of light so that electromagnetic waves escaped via evanescent enter into the substrate, effects of the low refractive index layer are lowered.

The method in which the interface which results in total reflection or a diffraction grating is introduced in any of the media is characterized, in that light extraction efficiency is significantly enhanced. The above method works as follows. By utilizing properties of the diffraction grating capable of changing the light direction to the specific direction different from diffraction via so-called Bragg diffraction such as primary diffraction or secondary diffraction of the diffraction grating, of light emitted from the light entitling layer, light, which is not emitted to the exterior due to total reflection between layers, is diffracted via introduction of a diffraction grating between any layers or in a medium (in the transparent substrate and the transparent electrode) so that light is extracted to the exterior.

It is preferable that the introduced diffraction grating exhibits a two-dimensional periodic refractive, index. The reason is as follows. Since light emitted in the light emitting layer is randomly generated to all directions, in a common one-dimensional diffraction grating exhibiting a periodic refractive index distribution only in a certain direction, light which travels to the specific direction is only diffracted, whereby light extraction efficiency is not sufficiently enhanced.

However, by changing the refractive index distribution to a two-dimensional one, light, which travels to all directions, is diffracted, whereby the light extraction efficiency is enhanced.

A position to introduce a diffraction grating may be between any layers or in a medium (in a transparent substrate or a transparent electrode). However, a position near the organic light emitting layer, where light is generated, is preferable. In this case, the cycle of the diffraction grating is preferably from about ½ to 3 times of the wavelength of light in the medium. The preferable arrangement of the diffraction grating is such that the arrangement is two-dimensionally repeated in the form of a square lattice, a triangular lattice, or a honeycomb lattice.

### [Light Collection Sheet]

Via a process to arrange a structure such as a micro-lens array shape on the light extraction side of the organic EL element of the present invention or via combination with a so-called light collection sheet, light is collected in the specific direction such as the front direction with respect to the light emitting element surface, whereby it is possible to enhance luminance in the specific direction.

In an example of the micro-lens array, square pyramids to realize a side length of 30 μm and an apex angle of 90 degrees are two-dimensionally arranged on the light extraction side of the substrate. The side length is preferably 10 to 100 μm. When it is less than the lower limit, coloration occurs due to generation of diffraction effects, while when it exceeds the upper limit, the thickness increases undesirably.

It is possible to employ, as a light collection sheet, for example, one which is put into practical use in the LED backlight of liquid crystal display devices. It is possible to employ, as such a sheet, for example, the luminance enhancing film (BEF), produced by Sumitomo 3M Limited. As shapes of a prism sheet employed may be, for example, Δ shaped stripes of an apex angle of 90 degrees and a pitch of 50 μm formed on a base material, a shape in which the apex angle is rounded, a shape in which the pitch is randomly changed, and other shapes.

Further, in order to control the light radiation angle from the light emitting element, simultaneously employed may be a light diffusion plate-film. For example, it is possible to employ the diffusion film (LIGHT-UP), produced by Kimoto Co., Ltd.

### [Applications]

It is possible to employ the organic EL element of the present invention as display devices, displays, and various types of light emitting sources.

Examples of light emitting sources include: lighting apparatuses (home lighting and car lighting), clocks, backlights for liquid crystals, sign advertisements, signals, light sources of light memory media, light sources of electrophotographic copiers, light sources of light communication processors, and light sources of light sensors. The present invention is not limited to them. It is especially effectively employed as a backlight of a liquid crystal display device and a lighting source.

If needed, the organic EL element of the present, invention may undergo patterning via a metal mask or an ink-jet printing method during film formation. When the patterning is carried out, only an electrode may undergo patterning, an electrode and a light emitting layer may undergo patterning, or all element layers may undergo patterning. During preparation of the element, it is possible to employ conventional methods.

Color of light emitted by an organic EL element or a compound of the present invention is specified as follows. In FIG. 4.16 on page 108 of “Shinpen Shikisai Kagaku Handbook (New Edition Color Science Handbook)” (edited by The Color Science Association of Japan, Tokyo Daigaku Shuppan Kai, 1985), values determined via a spectroradiometric luminance meter CS-1000 (produced by Konica Minolta, Inc.) are applied to the CIE chromaticity coordinate, whereby the color is specified.

It is preferable that “white” in the organic EL element of the present invention shows chromaticity in the CIE 1931 Color Specification System at 1,000 cd/m² in the region of x=0.39±0.09 and y=0.38±0.08, when measurement is done to 2-degree viewing angle front luminance via the aforesaid method.

### <Display Device>

A display device provided with an organic EL element of the present invention may emit a single color or multiple colors. Here, it will be described a multiple color display device.

In case of a multiple color display device, a shadow mask is placed during the formation of a light emitting layer, and a layer is formed as a whole with a vapor deposition method, a cast method, a spin coating method, an inkjet method, and a printing method.

When patterning is done only to the light emitting layer, although the coating method is not limited in particular, preferable methods are a vapor deposition method, an inkjet method, a spin coating method, and a printing method.

A constitution of an organic EL element provided for a display device is selected from the above-described examples of an organic EL element according to the necessity.

The production method of an organic EL element is described as an embodiment of a production method of the above-described organic EL element.

When a direct-current voltage is applied to the produced multiple color display device, light emission can be observed by applying voltage of 2 o 40 V by setting the anode to have a plus (+) polarity, and the cathode to have a minus (−) polarity. When the voltage is applied to the device with reverse polarities, an electric current does not pass and light emission does not occur. Further, when an alternating-current voltage is applied to the device, light emission occurs only when the anode has a plus (+) polarity and the cathode has a minus (−) polarity. In addition, an arbitrary wave shape may be used for applying alternating-current.

The multiple color display device may be used for a display device, a display, and a variety of light emitting sources. In a display device or a display, a full color display is possible by using 3 kinds of organic EL elements emitting blue, red and green.

Examples of a display device or a display are: a television set, a personal computer, a mobile device, an AV device, a character broadcast display, and an information display in a car. Specifically, it may be used for a display device reproducing a still image or a moving image. When it is used for a display device reproducing a moving image, the driving mode may be any one of a passive-matrix mode and an active-matrix mode.

Examples of light emitting sources include: home lighting, car lighting, backlights for clocks and liquid crystals, sign advertisements, signals, light sources of light memory media, light sources of electrophotographic copiers, light sources of light communication processors, and light sources of light sensors. The present invention is not limited to them.

In the following, an example of a display device provided with an organic EL element of the present invention will be described by referring to drawings.

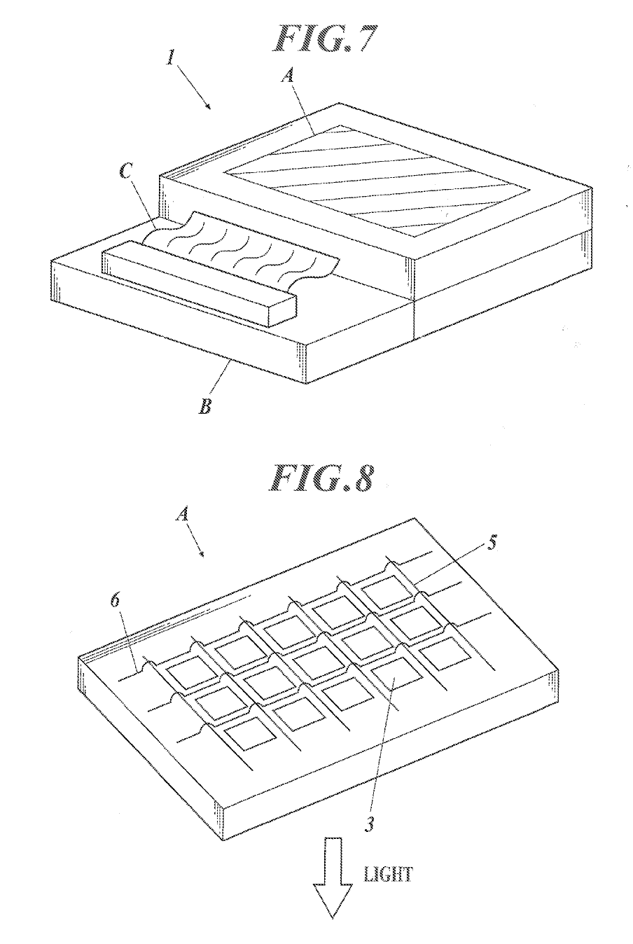

FIG. 7 is a schematic drawing illustrating an example of a display device composed of an organic EL element. Display of image information is carried out by light emission of an organic EL element. For example, it is a schematic drawing of a display of a cell-phone.

A display 1 is constituted of a display section A having plural number of pixels, a control section B which performs image scanning of the display section A based on image information, and a wiring section C electrically connecting the display section A and the control section B.

The control section B, which is electrically connected to the display section A via the wiring section C, sends a scanning signal and an image data signal to plural number of pixels based on image information from the outside and pixels of each scanning line successively emit depending on the image data signal by a scanning signal to perform image scanning, whereby image information is displayed on the display section A.

FIG. 8 is a schematic drawing of the display section A based on an active matrix mode.

The display section A is provided with the wiring section C, which contains plural scanning lines 5 and data lines 6, and plural pixels 3 on a substrate. Primary part materials of the display section A will be explained in the following.

In FIG. 8, shown is the case that light emitted by the pixel 3 is taken out along the white allow (downward).

The scanning lines 5 and the plural data lines 6 each are comprised of a conductive material, and the scanning lines 5 and the data lines 6 are perpendicular in a grid form and are connected to pixels 3 at the right-angled crossing points (details are not shown in the drawing).

The pixel 3 receives an image data from the data line 6 when a scanning signal is applied from the scanning line 5 and emits according to the received image data.

Full-color display is possible by appropriately arranging pixels having an emission color in a red region, pixels in a green region and pixels in a blue region, side by side on the same substrate.

Next, an emission process of a pixel will be explained. FIG. 9 is a schematic drawing of a pixel.

A pixel is equipped with an organic EL element 10, a switching transistor 11, an operating transistor 12 and a capacitor 13. Red, green and blue emitting organic EL elements are utilized as the organic EL element 10 for plural pixels, and full-color display device is possible by arranging these side by side on the same substrate.

In FIG. 9, an image data signal is applied on the drain of the switching transistor 11 via the data line 6 from the control section B. Then when a scanning signal is applied on the gate of the switching transistor 11 via the scanning line 5 from control section B, operation of switching transistor is on to transmit the image data signal applied on the drain to the gates of the capacitor 13 and the operating transistor 12.

The operating transistor 12 is on, simultaneously with the capacitor 13 being charged depending on the potential of an image data signal, by transmission of an image data signal. In the operating transistor 12, the drain is connected to an electric source line 7 and the source is connected to the electrode of the organic EL element 10, and an electric current is supplied from the electric source line 7 to the organic EL element 10 depending on the potential of an image data applied on the gate.

When a scanning signal is transferred to the next scanning line 5 by successive scanning of the control section B, operation of the switching transistor 11 is off.

However, since the condenser 13 keeps the charged potential of an image data signal even when operation of the switching transistor 11 is off, operation of the operating transistor 12 is kept on to continue emission of the organic EL element 10 until the next scanning signal is applied.

When the next scanning signal is applied by successive scanning, the operating transistor 12 operates depending on the potential of an image data signal synchronized to the scanning signal and the organic EL element 10 emits light.

That is, emission of each organic EL element 10 of the plural pixels 3 is performed by providing the switching transistor 11 and the operating transistor 12 against each organic EL element 10 of plural pixels 3. Such an emission method is called as an active matrix mode.

Herein, emission of the organic EL element 10 may be either emission of plural gradations based on a multiple-valued image data signal having plural number of gradation potentials or on and off of a predetermined emission quantity based on a binary image data signal. Further, potential hold of the capacitor 13 may be either continuously maintained until the next scanning signal application or discharged immediately before the next scanning signal application.

In the present invention, emission operation is not necessarily limited to the above-described active matrix mode but may be a passive matrix mode in which organic EL element is emitted based on a data signal only when a scanning signal is scanned.

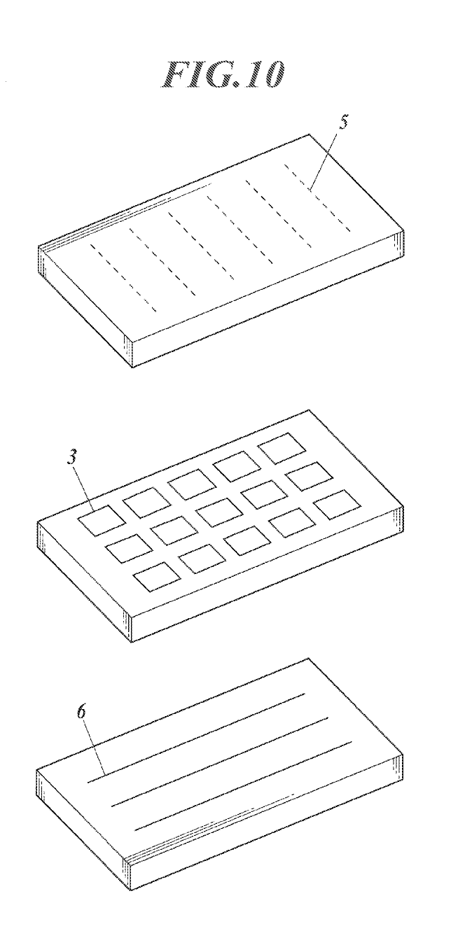

FIG. 10 is a schematic drawing of a display device based on a passive matrix mode. In FIG. 10, plural number of scanning lines 5 and plural number of image data lines 6 are arranged grid-wise, opposing to each other and sandwiching the pixels 3.

When a scanning signal of the scanning line 5 is applied by successive scanning, the pixel 3 connected to the scanning line 5 applied with the signal emits depending on an image data signal.

Since the pixel 3 is provided with no active element in a passive matrix mode, decrease of manufacturing cost is possible.

By employing the organic EL element of the present invention, it was possible to obtain a display device having improved emission efficiency.

### <Light Emitting Device>

An organic EL element of the present invention may be used for a light emitting device.

An organic EL element of the present invention may be provided with a rasonator structure. The intended uses of the organic EL element provided with a rasonator structure are: a light source of a light memory media, a light source of an electrophotographic copier, a light source of a light communication processor, and a light sources of a light sensor, however, it is not limited to them. It may be used for the above-described purposes by making to emit a laser.

Further, an organic EL element of the present invention may be used for a kind of lamp such as for illumination or exposure. It may be used for a projection device for projecting an image, or may be used for a display device to directly observe a still image or a moving image thereon.

The driving mode used for a display device of a moving image reproduction may be any one of a passive matrix mode and an active matrix mode. By employing two or more kinds of organic EL elements of the present invention emitting a different emission color, it can produce a full color display device.

In addition, a fluorescent compound of the present invention may be applicable to an organic EL element substantially emitting white light as a light emitting device. For example, when a plurality of light emitting materials are employed, white light can be obtained by mixing colors of a plurality of emission colors. As a combination of the plurality of emission colors, it may be a combination of red, green and blue having emission maximum wavelength of three primary colors, or it may be a combination of colors having two emission maximum wavelength making use of the relationship of two complementary colors of blue and yellow, or blue-green and orange.

A production method of an organic EL element of the present invention is done by placing a mask only during formation of a light emitting layer, a hole transport layer and an electron transport layer. It can be produced by coating with a mask to make simple arrangement. Since other layers are common, there is no need of pattering with a mask. For example, it can produce an electrode uniformly with a vapor deposition method, a cast method, a spin coating method, an inkjet method, and a printing method. The production yield will be improved.

By using these methods, it can produce a white organic EL device in which a plurality of light emitting elements are arranged in parallel to form an array state. The element itself emits white light.

### [One Embodiment of Light Emitting Device of the Present Invention]

One embodiment of light emitting devices of the present Invention provided with an organic EL element of the present invention will be described.

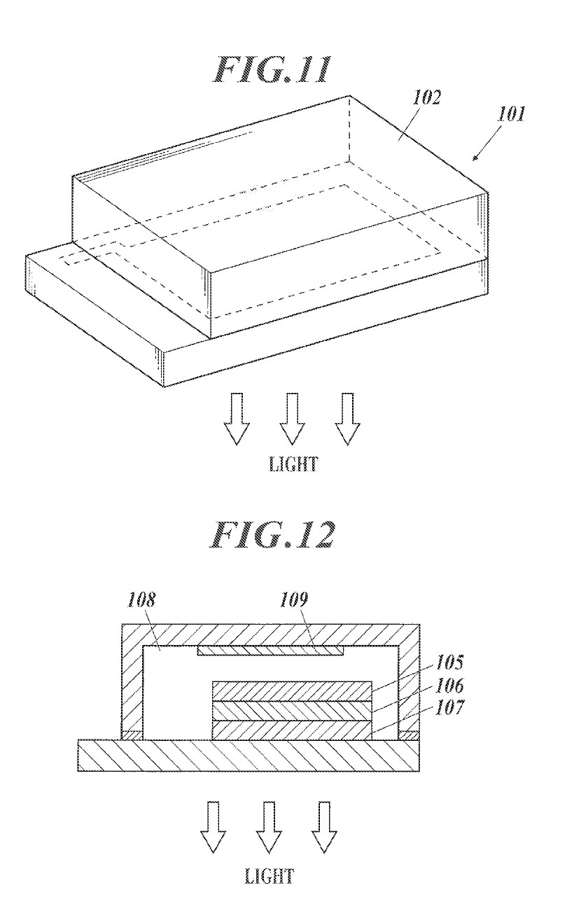

The non-light emitting surface of the organic EL element of the present invention was covered with a glass case, and a 300 μm thick glass substrate was employed as a sealing substrate. An epoxy based light curable type adhesive (LUXTRACK LC0629B produced by Toagosei Co., Ltd.) was employed in the periphery as a sealing material. The resulting one was superimposed on the aforesaid cathode to be brought into close contact with the aforesaid transparent support substrate, and curing and sealing were carried out via exposure of UV radiation onto the glass substrate side, whereby the light emitting device shown in FIG. 11 and FIG. 12, was formed.

FIG. 11 is a schematic view of a light emitting device, and an organic EL element of the present invention (Organic EL element 101 in a light emitting device) is covered with glass cover 102 (incidentally, sealing by the glass cover was carried out in a globe box under nitrogen ambience (under an ambience of high purity nitrogen gas at a purity of at least 99.999%) so that Organic EL Element 101 was not brought into contact with atmosphere).

FIG. 12 is a cross-sectional view of a light emitting device. In FIG. 6, 105 represents a cathode, 106 represents an organic EL layer, and 107 represents a glass substrate fitted with a transparent electrode. Further, the interior of glass cover 102 is filled with nitrogen gas 108 and water catching agent 109 is provided.

By employing an organic EL element of the present invention, it was possible to obtain a light emitting having improved emission efficiency.

A fluorescent compound and a host compound applicable to an organic EL element of the present invention may be also used for a light emitting material.

That is, the light emitting material contains a fluorescent compound and a host compound, and the light emitting material is characterized in that the fluorescent compound has an internal quantum efficiency of 50% or more by electrical excitation; the fluorescent compound has a half bandwidth of 100 nm or less in an emission band of an emission maximum wavelength in an emission spectrum of the fluorescent compound at a room temperature; and

the host compound contains a structure represented by Formula (I).

By being provided with these features, it can be obtained a light emitting material of high efficiency with a long lifetime.

A host compound having a structure represented by the aforesaid Formula (I) is preferably has a structure represented by the aforesaid Formula (II) from the viewpoint of obtaining further distinguished effects of the present invention.

### EXAMPLES

Hereafter, the present invention will be described specifically by referring to Examples, however, the present invention is not limited to them. In Examples, the term “parts” or “%” is used. Unless particularly mentioned, it represents “mass parts” or “mass %”.

In addition, a volume % of a compound in each example is obtained from a specific gravity by measuring a produced layer thickness with a quartz oscillator microbalance method and by calculating a mass.

### <<Preparation of Organic EL Element 1-1>>

An anode was prepared by making patterning to a glass substrate of 100 mm×100 mm×1.1 mm (NA45, produced by NH Techno Glass Corp.) on which ITO (indium tin oxide) was formed with a thickness of 100 nm. Thereafter, the above transparent support substrate provided with the ITO transparent electrode was subjected to ultrasonic washing with isopropyl alcohol, followed by drying with desiccated nitrogen gas, and was subjected to UV ozone washing for 5 minutes.

On the transparent support substrate thus prepared was applied a 70% solution of poly(3,4-ethylenedioxythiphene)-polystyrene sulfonate (PEDOT/PSS, Baytron P AI4083, made by Bayer AG.) diluted with water by using a spin coating method at 3,000 rpm for 30 seconds to form a film and then it was dried at 200° C. for one hour. A first hole injection layer having a thickness of 20 nm was prepared.

The resulting transparent support substrate was fixed to a substrate holder of a commercial vacuum deposition apparatus. Separately, 200 mg of α-NPD was placed in a molybdenum resistance heating boat, 200 mg of H-159 was placed in another molybdenum resistance heating boat, 200 mg of Comparative compound (4CzIPN) was placed in another molybdenum resistance heating boat, and 200 mg of BCP (2,9-dimethyl-4,7-diphenyl-1,10-phenanthroline) was placed in another molybdenum resistance heating boat. The resulting boats were fitted in the vacuum deposition apparatus.

Comparative Compound

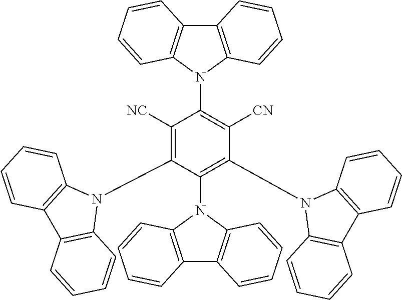 [SMILES: N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21]

Subsequently, after reducing the pressure of a vacuum tank to 4×10⁻⁴ Pa, the aforesaid heating boat containing α-NPD was heated via application of electric current and deposition was made onto the aforesaid hole injection layer at a deposition rate of 0.1 nm/second, whereby it was produced a hole transport layer having a thickness of 30 nm.

Further, the aforesaid heating boats each respectively containing H-159 and Comparative compound were heated via application of electric current and co-deposition was carried out onto the aforesaid hole transport layer at a respective deposition rate of 0.1 nm/second and 0.010 nm/second, whereby it was produced a light emitting layer having a thickness of 40 nm.

Further, the aforesaid heating boat containing BCP was heated via application of electric current and deposition was carried out onto the aforesaid hole blocking layer at a deposition rate of 0.1 nm/second, whereby it was produced an electron transport layer having a thickness of 30 nm.

Subsequently, 0.5 nm thick lithium fluoride was vapor deposited as a cathode buffer layer, and then, 110 nm thick aluminum was vapor deposited to form a cathode, whereby Organic EL element 1-1 was prepared.

### <<Preparation of Organic EL Elements 1-2 to 1-217>>

Organic EL elements 1-2 to 1-217 were prepared in the same manner as preparation of Organic EL element 1-1 except that H-159 and Comparative compound were changed with the compounds described in Tables 2-1 to 2-5.

### <<Evaluation of Organic EL Elements 1-1 to 1-217>>

When the prepared organic EL elements were evaluated, the light emitting device as illustrated in FIG. 11 and FIG. 12 was formed. A half bandwidth in an emission band of an emission maximum wavelength, an internal quantum efficiency and the change rate of resistance value of the light emitting layer were measured.

FIG. 11 is a schematic view of a light emitting device, and an organic EL element of the present invention (Organic EL element 101 in a light emitting device) is covered with glass cover 102 (incidentally, sealing by the glass cover was carried out in a globe box under nitrogen ambience (under an ambience of high purity nitrogen gas at a purity of at least 99.999%) so that Organic EL Element 101 was not brought into contact with atmosphere). Specifically, an epoxy based light curable adhesive (LUXTRACK LC0629B, produced by Toagosei Co., Ltd.) was employed as a sealing material in the periphery of a glass cover contacting with the glass substrate on which the organic EL element was formed. The resulting one was superimposed on the aforesaid cathode to be brought into close contact with the aforesaid transparent support substrate, and curing and sealing were carried out via exposure of UV rays onto the glass substrate side.

FIG. 12 is a cross-sectional view of a light emitting device. In FIG. 6, 105 represents a cathode, 106 represents an organic EL layer, and 107 represents a glass substrate fitted with a transparent electrode. Further, the interior of glass cover 102 is filled with nitrogen gas 108 and water catching agent 109 is provided.

### (1) Measurement of a Half Bandwidth of an Emission Spectrum of a Fluorescent Compound

Measurement of an emission spectrum of a fluorescent compound (dopant) is done with Hitachi spectrofluorometer F-4000 to a fluorescent compound solution prepared by dissolving in dichloromethane. The measurement is done at a room temperature, and it can be obtained a half bandwidth of an emission band of an emission maximum wavelength in an emission spectrum.

### (2) Calculation of Internal Quantum Efficiency (IQE) of Fluorescent Compound

The calculation of an internal quantum efficiency (%) of a fluorescent compound (dopant) was done to a prepared organic electroluminescent element containing a fluorescent compound with the following method.

Specifically, an external quantum efficiency (EQE) was measured when the organic EL element 1-1 was driven at 5 V at a room temperature using an integrated sphere with an external quantum efficiency measuring apparatus (C9920-12, made by Hamamatsu Photonics K.K.).

Then, a mode analysis was done with an analysis software Setfos (made by Cybanet Systems CO. Ltd.) using thickness information and optical constant of the organic EL element 1-1. The ratio of the emitting light from the inside to the outside of the organic EL element, that is, the light extraction efficiency (OC) was calculated.

An external quantum efficiency (EQE) is represented by a product of an internal quantum efficiency (IQE) and a light extraction efficiency (OC) (refer to Scheme (A)).

EQE=IQE×OC Scheme (A):

In the present invention, by applying EQE and OC, being obtained by the measurement and analysis, to Scheme (A), an internal quantum efficiency of a fluorescent compound in the organic EL element 1-1 was calculated. In the same manner as described above, internal quantum efficiencies of organic EL elements 1-2 to 1-217 were calculated.

### (3) Change Rate of Resistance Before and After Driving Organic EL Element

By referring to the description in pp. 423 to 425 of “Handbook of Thin film evaluation” published by Techno System, Co. Ltd, and by using a 1260 type impedance analyzer with a 1296 type dielectric interface (made by Solartronanalytical Co.), the resistance value of the light emitting layer of the prepared organic EL element at a bias voltage of 1 V was measured.

Each organic EL element was driven with a constant electric current of 2.5 mA/cm² at a room temperature (25° C.) for 1,000 hours. The resistance values of the light emitting layer of each Organic EL element were measured at the moment of before and after driving. The change rate of resistance was obtained according to the following calculating formula. In Tables 2-1 to 2-5, the results were described as a relative value when the change rate of resistance for Organic EL element 1-1 was set to be 100.

Change rate of resistance before and after driving=[(Resistance after driving/Resistance before driving)−1]×100

The case showing nearer to zero indicates that the change rate of before and after driving is smaller.

TABLE 2-1

| | Fluores- | | | | | |
|---|---|---|---|---|---|---|
| Element | cent | Host | | | | |
| No. | compound | compound | *1 | *2 | *3 | Remarks |
| 1-1 | Comparative | H-159 | 106 | 74 | 100 | Comparative |
| | compound | | | | | example |
| 1-2 | F-1 | H-159 | 82 | 91 | 12 | Present invention |
| 1-3 | F-2 | H-159 | 91 | 86 | 9 | Present invention |
| 1-4 | F-3 | H-159 | 65 | 90 | 11 | Present invention |
| 1-5 | F-4 | H-159 | 69 | 82 | 12 | Present invention |
| 1-6 | F-5 | H-159 | 58 | 88 | 11 | Present invention |
| 1-7 | F-6 | H-159 | 80 | 53 | 18 | Present invention |
| 1-8 | F-7 | H-159 | 73 | 86 | 14 | Present invention |
| 1-9 | F-8 | H-159 | 93 | 56 | 9 | Present invention |
| 1-10 | F-9 | H-159 | 88 | 89 | 9 | Present invention |
| 1-11 | F-10 | H-159 | 82 | 81 | 12 | Present invention |
| 1-12 | F-11 | H-159 | 76 | 87 | 13 | Present invention |
| 1-13 | F-12 | H-159 | 81 | 72 | 10 | Present invention |
| 1-14 | F-13 | H-159 | 90 | 78 | 9 | Present invention |
| 1-15 | F-14 | H-159 | 72 | 68 | 12 | Present invention |
| 1-16 | F-15 | H-159 | 89 | 62 | 15 | Present invention |
| 1-17 | F-16 | H-159 | 94 | 71 | 11 | Present invention |
| 1-18 | F-17 | H-159 | 63 | 65 | 9 | Present invention |
| 1-19 | F-18 | H-159 | 56 | 72 | 12 | Present invention |
| 1-20 | F-19 | H-159 | 55 | 68 | 11 | Present invention |
| 1-21 | F-20 | H-159 | 43 | 66 | 10 | Present invention |
| 1-22 | F-1 | H-4 | 82 | 91 | 7 | Present invention |
| 1-23 | F-1 | H-6 | 82 | 91 | 7 | Present invention |
| 1-24 | F-1 | H-7 | 82 | 91 | 10 | Present invention |
| 1-25 | F-1 | H-10 | 82 | 91 | 13 | Present invention |
| 1-26 | F-1 | H-11 | 82 | 91 | 10 | Present invention |
| 1-27 | F-1 | H-12 | 82 | 91 | 11 | Present invention |
| 1-28 | F-1 | H-13 | 82 | 91 | 14 | Present invention |
| 1-29 | F-1 | H-17 | 82 | 91 | 13 | Present invention |
| 1-30 | F-1 | H-18 | 82 | 91 | 8 | Present invention |
| 1-31 | F-1 | H-19 | 82 | 91 | 5 | Present invention |
| 1-32 | F-1 | H-21 | 82 | 91 | 10 | Present invention |
| 1-33 | F-1 | H-22 | 82 | 91 | 13 | Present invention |
| 1-34 | F-1 | H-23 | 82 | 91 | 8 | Present invention |
| 1-35 | F-1 | H-24 | 82 | 91 | 10 | Present invention |
| 1-36 | F-1 | H-25 | 82 | 91 | 7 | Present invention |
| 1-37 | F-1 | H-26 | 82 | 91 | 5 | Present invention |
| 1-38 | F-1 | H-27 | 82 | 91 | 6 | Present invention |
| 1-39 | F-1 | H-28 | 82 | 91 | 14 | Present invention |
| 1-40 | F-1 | H-30 | 82 | 91 | 9 | Present invention |
| 1-41 | F-1 | H-31 | 82 | 91 | 14 | Present invention |
| 1-42 | F-1 | H-32 | 82 | 91 | 14 | Present invention |
| 1-43 | F-1 | H-33 | 82 | 91 | 5 | Present invention |
| 1-44 | F-1 | H-34 | 82 | 91 | 5 | Present invention |
| 1-45 | F-1 | H-35 | 82 | 91 | 5 | Present invention |

*1: Half bandwidth of emission band of fluorescent compound (nm)
*2: Internal quantum efficiency of fluorescent compound (%)
*3: Change rate of resistance of light emitting layer (%)

TABLE 2-2

| | Fluores- | | | | | |
|---|---|---|---|---|---|---|
| Element | cent | Host | | | | |
| No. | compound | compound | *1 | *2 | *3 | Remarks |
| 1-46 | F-1 | H-36 | 82 | 91 | 12 | Present invention |
| 1-47 | F-1 | H-37 | 82 | 91 | 9 | Present invention |
| 1-48 | F-1 | H-38 | 82 | 91 | 8 | Present invention |
| 1-49 | F-1 | H-39 | 82 | 91 | 6 | Present invention |
| 1-50 | F-1 | H-40 | 82 | 91 | 10 | Present invention |
| 1-51 | F-1 | H-41 | 82 | 91 | 6 | Present invention |
| 1-52 | F-1 | H-42 | 82 | 91 | 14 | Present invention |
| 1-53 | F-1 | H-43 | 82 | 91 | 12 | Present invention |
| 1-54 | F-1 | H-44 | 82 | 91 | 13 | Present invention |
| 1-55 | F-1 | H-45 | 82 | 91 | 12 | Present invention |
| 1-56 | F-1 | H-46 | 82 | 91 | 6 | Present invention |
| 1-57 | F-1 | H-47 | 82 | 91 | 5 | Present invention |
| 1-58 | F-1 | H-48 | 82 | 91 | 13 | Present invention |
| 1-59 | F-1 | H-50 | 82 | 91 | 13 | Present invention |
| 1-60 | F-1 | H-51 | 82 | 91 | 12 | Present invention |
| 1-61 | F-1 | H-52 | 82 | 91 | 9 | Present invention |
| 1-62 | F-1 | H-53 | 82 | 91 | 10 | Present invention |
| 1-63 | F-1 | H-54 | 82 | 91 | 9 | Present invention |
| 1-64 | F-1 | H-55 | 82 | 91 | 5 | Present invention |
| 1-65 | F-1 | H-56 | 82 | 91 | 10 | Present invention |
| 1-66 | F-1 | H-57 | 82 | 91 | 5 | Present invention |
| 1-67 | F-1 | H-60 | 82 | 91 | 10 | Present invention |
| 1-68 | F-1 | H-64 | 82 | 91 | 8 | Present invention |
| 1-69 | F-1 | H-65 | 82 | 91 | 8 | Present invention |
| 1-70 | F-1 | H-66 | 82 | 91 | 10 | Present invention |
| 1-71 | F-1 | H-67 | 82 | 91 | 7 | Present invention |
| 1-72 | F-1 | H-68 | 82 | 91 | 6 | Present invention |
| 1-73 | F-1 | H-69 | 82 | 91 | 14 | Present invention |
| 1-74 | F-1 | H-70 | 82 | 91 | 8 | Present invention |
| 1-75 | F-1 | H-71 | 82 | 91 | 9 | Present invention |
| 1-76 | F-1 | H-72 | 82 | 91 | 6 | Present invention |
| 1-77 | F-1 | H-73 | 82 | 91 | 7 | Present invention |
| 1-78 | F-1 | H-75 | 82 | 91 | 9 | Present invention |
| 1-79 | F-1 | H-76 | 82 | 91 | 8 | Present invention |
| 1-80 | F-1 | H-77 | 82 | 91 | 12 | Present invention |
| 1-81 | F-1 | H-78 | 82 | 91 | 8 | Present invention |
| 1-82 | F-1 | H-79 | 82 | 91 | 13 | Present invention |
| 1-83 | F-1 | H-80 | 82 | 91 | 9 | Present invention |
| 1-84 | F-1 | H-81 | 82 | 91 | 10 | Present invention |
| 1-85 | F-1 | H-83 | 82 | 91 | 6 | Present invention |
| 1-86 | F-1 | H-84 | 82 | 91 | 14 | Present invention |
| 1-87 | F-1 | H-85 | 82 | 91 | 7 | Present invention |
| 1-88 | F-1 | H-86 | 82 | 91 | 8 | Present invention |
| 1-89 | F-1 | H-87 | 82 | 91 | 13 | Present invention |
| 1-90 | F-1 | H-88 | 82 | 91 | 6 | Present invention |

*1: Half bandwidth of emission band of fluorescent compound (nm)
*2: Internal quantum efficiency of fluorescent compound (%)
*3: Change rate of resistance of light emitting layer (%)

TABLE 2-3

| | Fluores- | | | | | |
|---|---|---|---|---|---|---|
| Element | cent | Host | | | | |
| No. | compound | compound | *1 | *2 | *3 | Remarks |
| 1-91 | F-1 | H-89 | 82 | 91 | 7 | Present invention |
| 1-92 | F-1 | H-90 | 82 | 91 | 5 | Present invention |
| 1-93 | F-1 | H-91 | 82 | 91 | 7 | Present invention |
| 1-94 | F-1 | H-94 | 82 | 91 | 6 | Present invention |
| 1-95 | F-1 | H-95 | 82 | 91 | 6 | Present invention |
| 1-96 | F-1 | H-96 | 82 | 91 | 8 | Present invention |
| 1-97 | F-1 | H-97 | 82 | 91 | 6 | Present invention |
| 1-98 | F-1 | H-98 | 82 | 91 | 12 | Present invention |
| 1-99 | F-1 | H-99 | 82 | 91 | 14 | Present invention |
| 1-100 | F-1 | H-100 | 82 | 91 | 7 | Present invention |
| 1-101 | F-1 | H-101 | 82 | 91 | 10 | Present invention |
| 1-102 | F-1 | H-102 | 82 | 91 | 13 | Present invention |
| 1-103 | F-1 | H-103 | 82 | 91 | 9 | Present invention |
| 1-104 | F-1 | H-104 | 82 | 91 | 11 | Present invention |
| 1-105 | F-1 | H-107 | 82 | 91 | 12 | Present invention |
| 1-106 | F-1 | H-108 | 82 | 91 | 8 | Present invention |
| 1-107 | F-1 | H-109 | 82 | 91 | 6 | Present invention |
| 1-108 | F-1 | H-110 | 82 | 91 | 12 | Present invention |
| 1-109 | F-1 | H-111 | 82 | 91 | 13 | Present invention |
| 1-110 | F-1 | H-112 | 82 | 91 | 5 | Present invention |
| 1-111 | F-1 | H-113 | 82 | 91 | 7 | Present invention |
| 1-112 | F-1 | H-114 | 82 | 91 | 11 | Present invention |
| 1-113 | F-1 | H-115 | 82 | 91 | 8 | Present invention |
| 1-114 | F-1 | H-116 | 82 | 91 | 13 | Present invention |
| 1-115 | F-1 | H-117 | 82 | 91 | 7 | Present invention |
| 1-116 | F-1 | H-118 | 82 | 91 | 12 | Present invention |
| 1-117 | F-1 | H-119 | 82 | 91 | 11 | Present invention |
| 1-118 | F-1 | H-122 | 82 | 91 | 5 | Present invention |
| 1-119 | F-1 | H-123 | 82 | 91 | 6 | Present invention |
| 1-120 | F-1 | H-124 | 82 | 91 | 7 | Present invention |
| 1-121 | F-1 | H-125 | 82 | 91 | 6 | Present invention |
| 1-122 | F-1 | H-127 | 82 | 91 | 14 | Present invention |
| 1-123 | F-1 | H-128 | 82 | 91 | 5 | Present invention |
| 1-124 | F-1 | H-130 | 82 | 91 | 6 | Present invention |
| 1-125 | F-1 | H-131 | 82 | 91 | 9 | Present invention |
| 1-126 | F-1 | H-132 | 82 | 91 | 10 | Present invention |
| 1-127 | F-1 | H-133 | 82 | 91 | 10 | Present invention |
| 1-128 | F-1 | H-134 | 82 | 91 | 9 | Present invention |
| 1-129 | F-1 | H-135 | 82 | 91 | 5 | Present invention |
| 1-130 | F-1 | H-136 | 82 | 91 | 12 | Present invention |
| 1-131 | F-1 | H-137 | 82 | 91 | 9 | Present invention |
| 1-132 | F-1 | H-138 | 82 | 91 | 8 | Present invention |
| 1-133 | F-1 | H-139 | 82 | 91 | 13 | Present invention |
| 1-134 | F-1 | H-140 | 82 | 91 | 5 | Present invention |
| 1-135 | F-1 | H-141 | 82 | 91 | 10 | Present invention |

*1: Half bandwidth of emission band of fluorescent compound (nm)
*2: Internal quantum efficiency of fluorescent compound (%)
*3: Change rate of resistance of light emitting layer (%)

TABLE 2-4

| | Fluores- | | | | | |
|---|---|---|---|---|---|---|
| Element | cent | Host | | | | |
| No. | compound | compound | *1 | *2 | *3 | Remarks |
| 1-136 | F-1 | H-142 | 82 | 91 | 9 | Present invention |
| 1-137 | F-1 | H-143 | 82 | 91 | 5 | Present invention |
| 1-138 | F-1 | H-144 | 82 | 91 | 9 | Present invention |
| 1-139 | F-1 | H-145 | 82 | 91 | 11 | Present invention |
| 1-140 | F-1 | H-146 | 82 | 91 | 5 | Present invention |
| 1-141 | F-1 | H-147 | 82 | 91 | 13 | Present invention |
| 1-142 | F-1 | H-148 | 82 | 91 | 11 | Present invention |
| 1-143 | F-1 | H-149 | 82 | 81 | 7 | Present invention |
| 1-144 | F-1 | H-150 | 82 | 91 | 5 | Present invention |
| 1-145 | F-1 | H-151 | 82 | 91 | 13 | Present invention |
| 1-146 | F-1 | H-152 | 82 | 91 | 13 | Present invention |
| 1-147 | F-1 | H-153 | 82 | 91 | 6 | Present invention |
| 1-148 | F-1 | H-154 | 82 | 91 | 13 | Present invention |
| 1-149 | F-1 | H-155 | 82 | 91 | 6 | Present invention |
| 1-150 | F-1 | H-156 | 82 | 91 | 13 | Present invention |
| 1-151 | F-1 | H-157 | 82 | 91 | 7 | Present invention |
| 1-152 | F-1 | H-158 | 82 | 91 | 10 | Present invention |
| 1-153 | F-1 | H-160 | 82 | 91 | 13 | Present invention |
| 1-154 | F-1 | H-161 | 82 | 91 | 11 | Present invention |
| 1-155 | F-1 | H-162 | 82 | 91 | 5 | Present invention |
| 1-156 | F-1 | H-163 | 82 | 91 | 11 | Present invention |
| 1-157 | F-1 | H-164 | 82 | 91 | 14 | Present invention |
| 1-158 | F-1 | H-165 | 82 | 91 | 5 | Present invention |
| 1-159 | F-1 | H-166 | 82 | 91 | 11 | Present invention |
| 1-160 | F-1 | H-167 | 82 | 91 | 10 | Present invention |
| 1-161 | F-1 | H-168 | 82 | 91 | 10 | Present invention |
| 1-162 | F-1 | H-169 | 82 | 91 | 11 | Present invention |
| 1-163 | F-1 | H-170 | 82 | 91 | 6 | Present invention |
| 1-164 | F-1 | H-171 | 82 | 91 | 13 | Present invention |
| 1-165 | F-1 | H-172 | 82 | 91 | 5 | Present invention |
| 1-166 | F-1 | H-173 | 82 | 91 | 9 | Present invention |
| 1-167 | F-1 | H-174 | 82 | 91 | 5 | Present invention |
| 1-168 | F-1 | H-175 | 82 | 91 | 6 | Present invention |
| 1-169 | F-1 | H-176 | 82 | 91 | 7 | Present invention |
| 1-170 | F-1 | H-177 | 82 | 91 | 9 | Present invention |
| 1-171 | F-1 | H-178 | 82 | 91 | 7 | Present invention |
| 1-172 | F-1 | H-179 | 82 | 91 | 12 | Present invention |
| 1-173 | F-1 | H-180 | 82 | 91 | 11 | Present invention |
| 1-174 | F-1 | H-181 | 82 | 91 | 14 | Present invention |
| 1-175 | F-1 | H-182 | 82 | 91 | 9 | Present invention |
| 1-176 | F-1 | H-183 | 82 | 91 | 8 | Present invention |
| 1-177 | F-1 | H-184 | 82 | 91 | 7 | Present invention |
| 1-178 | F-1 | H-185 | 82 | 91 | 7 | Present invention |
| 1-179 | F-1 | H-186 | 82 | 91 | 8 | Present invention |
| 1-180 | F-1 | H-187 | 82 | 91 | 13 | Present invention |

*1: Half bandwidth of emission band of fluorescent compound (nm)
*2: Internal quantum efficiency of fluorescent compound (%)
*3: Change rate of resistance of light emitting layer (%)

TABLE 2-5

| | Fluores- | | | | | |
|---|---|---|---|---|---|---|
| Element | cent | Host | | | | |
| No. | compound | compound | *1 | *2 | *3 | Remarks |
| 1-181 | F-1 | H-188 | 82 | 91 | 10 | Present invention |
| 1-182 | F-1 | H-189 | 82 | 91 | 13 | Present invention |
| 1-183 | F-1 | H-190 | 82 | 91 | 8 | Present invention |
| 1-184 | F-1 | H-191 | 82 | 91 | 11 | Present invention |
| 1-185 | F-1 | H-192 | 82 | 91 | 13 | Present invention |
| 1-186 | F-1 | H-193 | 82 | 91 | 8 | Present invention |
| 1-187 | F-1 | H-194 | 82 | 91 | 13 | Present invention |
| 1-188 | F-1 | H-195 | 82 | 91 | 7 | Present invention |
| 1-189 | F-1 | H-196 | 82 | 91 | 5 | Present invention |
| 1-190 | F-1 | H-197 | 82 | 91 | 13 | Present invention |
| 1-191 | F-1 | H-198 | 82 | 91 | 13 | Present invention |
| 1-192 | F-1 | H-199 | 82 | 91 | 10 | Present invention |
| 1-193 | F-1 | H-200 | 82 | 91 | 13 | Present invention |
| 1-194 | F-1 | H-201 | 82 | 91 | 11 | Present invention |
| 1-195 | F-1 | H-202 | 82 | 91 | 10 | Present invention |
| 1-196 | F-1 | H-203 | 82 | 91 | 8 | Present invention |
| 1-197 | F-1 | H-204 | 82 | 91 | 12 | Present invention |
| 1-198 | F-1 | H-205 | 82 | 91 | 9 | Present invention |
| 1-199 | F-1 | H-206 | 82 | 91 | 13 | Present invention |
| 1-200 | F-1 | H-207 | 82 | 91 | 6 | Present invention |
| 1-201 | F-1 | H-208 | 82 | 91 | 14 | Present invention |
| 1-202 | F-1 | H-209 | 82 | 91 | 11 | Present invention |
| 1-203 | F-1 | H-210 | 82 | 91 | 10 | Present invention |
| 1-204 | F-1 | H-211 | 82 | 91 | 8 | Present invention |
| 1-205 | F-1 | H-212 | 82 | 91 | 14 | Present invention |
| 1-206 | F-1 | H-213 | 82 | 91 | 14 | Present invention |
| 1-207 | F-1 | H-214 | 82 | 91 | 7 | Present invention |
| 1-208 | F-1 | H-215 | 82 | 91 | 14 | Present invention |
| 1-209 | F-1 | H-217 | 82 | 91 | 9 | Present invention |
| 1-210 | F-1 | H-218 | 82 | 91 | 6 | Present invention |
| 1-211 | F-1 | H-219 | 82 | 91 | 12 | Present invention |
| 1-212 | F-1 | H-223 | 82 | 91 | 11 | Present invention |
| 1-213 | F-1 | H-224 | 82 | 91 | 7 | Present invention |
| 1-214 | F-1 | H-225 | 82 | 91 | 11 | Present invention |
| 1-215 | F-1 | H-226 | 82 | 91 | 7 | Present invention |
| 1-216 | F-1 | H-227 | 82 | 91 | 10 | Present invention |
| 1-217 | F-1 | H-228 | 82 | 91 | 9 | Present invention |

*1: Half bandwidth of emission band of fluorescent compound (nm)
*2: Internal quantum efficiency of fluorescent compound (%)
*3: Change rate of resistance of light emitting layer (%)

From the results in Tables 2-1 to 2-5, the organic EL elements 1-2 to 1-217 of the present invention exhibited small change rate of resistance of the light emitting layer compared with a comparative organic EL element 1-1. It was shown that it can be obtained a stable organic EL element having a small change of physical property of the light emitting layer.

That is, it was found that it can be obtained a highly stable organic EL element having a small change of physical property by suitably selecting a host compound, by making a half band width of an emission spectrum of a fluorescent compound to be 100 nm or less, and by making an internal quantum efficiency of a fluorescent compound to be 50% or more.

### INDUSTRIAL APPLICABILITY

The present invention enables to provide an organic electroluminescent element exhibiting high efficiency and a long lifetime. This organic electroluminescent element can be suitably used for a display device, a display, a home lighting, a car lighting, a backlight for a clock and a liquid crystal, a sign advertisement, a signal, a light source of a light memory media, a light source of an electrophotographic copier, a light source of a light communication processor, a light sources of a light sensor, and a light emitting source for a variety of home use electric apparatuses which require a display device.

### DESCRIPTION OF SYMBOLS

1: Display
3: Pixel
5: Scanning line
6: Data line
7: Electric source line
10: Organic EL element
11: Switching transistor
12: Operating transistor
13: Capacitor
101: Organic EL element in a light emitting device
102: Glass cover
105: Cathode
106: Organic EL layer
107: Glass substrate having a transparent electrode
108: Nitrogen gas
109: Water catching agent
A: Display section
B: Control section
C: Wiring section

1. An organic electroluminescent element comprising at least one organic layer interposed between an anode and a cathode,
wherein the at least one organic layer contains a fluorescent compound and a host compound;
the fluorescent compound has an internal quantum efficiency of 50% or more by electrical excitation;
the fluorescent compound has a half bandwidth of 100 nm or less in an emission band of an emission maximum wavelength in an emission spectrum of the fluorescent compound at a room temperature; and
the host compound contains a structure represented by Formula (I), 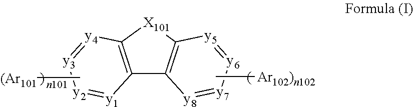
in Formula (I), X₁₀₁ represents NR₁₀₁, an oxygen atom, a sulfur atom, CR₁₀₂R₁₀₃, or SiR₁₀₂R₁₀₃; y₁ to y₈ each represent CR₁₀₄ or a nitrogen atom; R₁₀₁ to R₁₀₄ each represent a hydrogen atom or a substituent, provided that R₁₀₁ to R₁₀₄ each may be bonded together to form a ring; Ar₁₀₁ and to Ar₁₀₂ each represent an aromatic ring, provided that each may be the same or different with each other; and n101 and n102 each represent an integer of 0 to 4, provided that when R₁₀₁ represents a hydrogen atom, n101 represents an integer of 1 to 4.

2. An organic electroluminescent element described in claim 1,
wherein the host compound containing a structure represented by Formula (I) contains a structure represented by Formula (II), 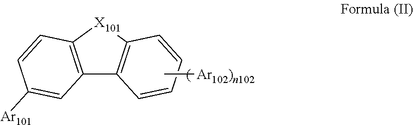
in Formula (II), X₁₀₁ represents NR₁₀₁, an oxygen atom, a sulfur atom, CR₁₀₂R₁₀₃, or SiR₁₀₂R₁₀₃; R₁₀₁ to R₁₀₃ each represent a hydrogen atom or a substituent, provided that R₁₀₁ to R₁₀₃ each may be bonded together to form a ring; Ar₁₀₁ and Ar₁₀₂ each represent an aromatic ring, provided that each may be the same or different with each other; and n101 and n102 each represent an integer of 0 to 4.

3. An organic electroluminescent element described in claim 1,
wherein the host compound contains a carbazole structure.

4. An organic electroluminescent element described in claim 1,
the at least one organic layer is a light emitting layer.

5. An electronic device provided with an organic electroluminescent element described in claim 1.

6. A light emitting device provided with an organic electroluminescent element described in claim 1.

7. A light emitting material comprising a fluorescent compound and a host compound,
wherein the fluorescent compound has an internal quantum efficiency of 50% or more by electrical excitation;
the fluorescent compound has a half bandwidth of 100 nm or less in an emission band of an emission maximum wavelength in an emission spectrum of the fluorescent compound at a room temperature; and
the host compound contains a structure represented by Formula (I), 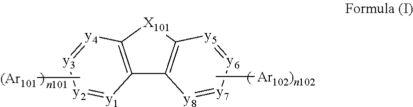
in Formula (I), X₁₀₁ represents NR₁₀₁, an oxygen atom, a sulfur atom, CR₁₀₂R₁₀₃, or SiR₁₀₂R₁₀₃; y₁ to y₈ each represent CR₁₀₄ or a nitrogen atom; R₁₀₁ to R₁₀₄ each represent a hydrogen atom or a substituent, provided that R₁₀₁ to R₁₀₄ each may be bonded together to form a ring; Ar₁₀₁ and to Ar₁₀₂ each represent an aromatic ring, provided that each may be the same or different with each other; and n101 and n102 each represent an integer of 0 to 4, provided that when R₁₀₁ represents a hydrogen atom, n101 represents an integer of 1 to 4.

8. A light emitting material described in claim 7,
wherein the host compound containing a structure represented by Formula (I) contains a structure represented by Formula (II), 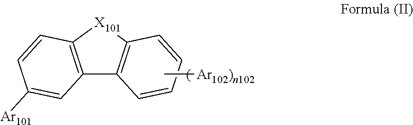
in Formula (II), X₁₀₁ represents NR₁₀₁, an oxygen atom, a sulfur atom, CR₁₀₂R₁₀₃, or SiR₁₀₂R₁₀₃; R₁₀₁ to R₁₀₃ each represent a hydrogen atom or a substituent, provided that R₁₀₁ to R₁₀₃ each may be bonded together to form a ring; Ar₁₀₁ and Ar₁₀₂ each represent an aromatic ring, provided that each may be the same or different with each other; and n101 and n102 each represent an integer of 0 to 4.
